(19) United States
(12) Patent Application Publication
(10) Pub. No.: US 2026/0123272 A1
(43) Pub. Date: Apr. 30, 2026

(54) OPTOELECTRONIC DEVICE, AND ELECTRONIC APPARATUS AND ELECTRONIC EQUIPMENT INCLUDING THE OPTOELECTRONIC DEVICE

(71) Applicants: Samsung Display Co., Ltd., Yongin-si (KR); Postech Research And Business Development Foundation, Pohang-si (KR)

(72) Inventors: Kiwoong Kim, Yongin-si (KR); Seokgyu Yoon, Yongin-si (KR); Syed Zahid Hassan, Pohang-si (KR); Seyeon Baek, Pohang-si (KR); Daesung Chung, Pohang-si (KR); Mingyun Kang, Pohang-si (KR)

(21) Appl. No.: 19/348,139

(22) Filed: Oct. 2, 2025

(30) Foreign Application Priority Data
Oct. 29, 2024 (KR) 10-2024-0149923

(51) Int. Cl. H10K 85/60; H10K 30/40; H10K 39/34

(52) U.S. Cl. CPC H10K 85/60; H10K 30/40; H10K 39/34

(57) ABSTRACT

An optoelectronic device and an electronic apparatus and electronic equipment including the optoelectronic device are disclosed. The optoelectronic device may include a first electrode, a second electrode opposite to (e.g., facing) the first electrode, a photoactive layer between the first electrode and the second electrode, and a fluorine-based compound represented by Formula F:

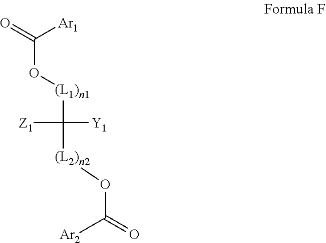

wherein, in Formula F,
Y₁, Z₁, L₁, L₂, n1, n2, Ar₁, and Ar₂ are each as described in one or more embodiments.

### CROSS-REFERENCE TO RELATED APPLICATION

The present application claims priority to and the benefit of Korean Patent Application No. 10-2024-0149923, filed on Oct. 29, 2024, in the Korean Intellectual Property Office, the entire disclosure of which is incorporated herein by reference.

### BACKGROUND

### 1. Field

One or more embodiments of the present disclosure relate to an optoelectronic device and an electronic apparatus and electronic equipment that include the optoelectronic device.

### 2. Description of the Related Art

Optoelectronic devices are devices that convert optical energy and/or optical signals into electrical energy or electrical signals. Examples of an optoelectronic device include an optical cell or a solar cell, which converts optical energy into electrical energy, an optical detector or an optical sensor, which detects and converts optical energy into electrical signals, and/or the like.

Electronic apparatuses including optoelectronic devices and light-emitting devices have been developed. Light emitted from a light-emitting device may be reflected from an object (e.g., a finger of a user) in contact with an electronic apparatus, and then be incident on an optoelectronic device. As the optoelectronic device detects incident light energy and converts it into electrical signals, the contact of the object with the electronic apparatus may be recognized.

The magnitude of a voltage applied to an optoelectronic device (e.g., a reverse voltage) may be less than the magnitude of a voltage applied to a light-emitting device. For reasons, such as process costs, one or more suitable components (e.g., a hole transport region and/or an electron transport region) applied to a light-emitting device may also be applied as common layers to an optoelectronic device. It is desirable to develop an optoelectronic device in which the amount of charge that reaches an electrode through a thick common layer is increased even under a low voltage.

### SUMMARY

One or more aspects of embodiments of the present disclosure are directed toward an optoelectronic device having improved or enhanced exciton separation efficiency and improved or enhanced external quantum efficiency, and an electronic apparatus and electronic equipment that have an improved or enhanced optical recognition or detection function by including the optoelectronic device.

Additional aspects of embodiments will be set forth in part in the description which follows and, in part, will be apparent from the description or may be learned by practice of the presented embodiments of the disclosure.

According to one or more embodiments, an optoelectronic device includes a first electrode, a second electrode opposite to (e.g., facing) the first electrode, a photoactive layer between the first electrode and the second electrode, and a fluorine-based compound represented by Formula F:

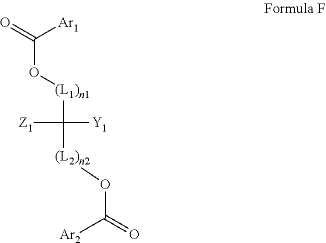

wherein, in Formula F,
Y₁ may be selected from among a group represented by Formula F-Y, hydrogen, deuterium, —F, a C₁-C₆₀ alkyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, and a C₁-C₆₀ heterocyclic group unsubstituted or substituted with at least one R₁₀ₐ, and
Z₁ may be selected from among a group represented by Formula F-Z, hydrogen, deuterium, —F, a C₁-C₆₀ alkyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, and a C₁-C₆₀ heterocyclic group unsubstituted or substituted with at least one R₁₀ₐ,

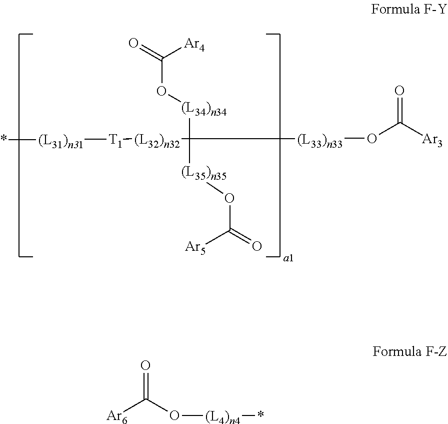

wherein, in Formulae F, F-Y, and F-Z,
Ar₁ to Ar₆ may each independently be selected from among a C₆-C₆₀ aryl group substituted with at least two-F and a C₂-C₆₀ heteroarylalkyl group substituted with at least two —F,
L₁, L₂, L₃₁ to L₃₅, and L₄ may each independently be a C₁-C₂₀ alkylene group unsubstituted or substituted with at least one R₁₀ₐ,
n1, n2, n31 to n35, and n4 may each independently be 0 or 1,
T₁ may be O or S,
a1 may be an integer of 0 to 10,
R₁₀ₐ may be
deuterium, —F, —Cl, —Br, —I, a hydroxyl group, a cyano group, or a nitro group,
a C₁-C₆₀ alkyl group, a C₂-C₆₀ alkenyl group, a C₂-C₆₀ alkynyl group, or a C₁-C₆₀ alkoxy group, each being unsubstituted or substituted with deuterium, —F, —Cl, —Br, —I, a hydroxyl group, a cyano group, a nitro group, a C₃-C₆₀ carbocyclic group, a C₁-C₆₀ group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof,
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each being unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof, or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁₁ to Q₁₃, Q₂₁ to Q₂₃, and Q₃₁ to Q₃₃ may each independently be
hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, or a C₁-C₆₀ alkoxy group, or
a C₃-C₆₀ carbocyclic group, a C₁-C₆₀ heterocyclic group, a C₇-C₆₀ arylalkyl group, or a C₂-C₆₀ heteroarylalkyl group, each being unsubstituted or substituted with deuterium, —F, a cyano group, a C₁-C₆₀ alkyl group, a C₁-C₆₀ alkoxy group, a phenyl group, a biphenyl group, or any combination thereof, and
* indicates a binding site to a neighboring atom.

In one or more embodiments, the photoactive layer may include the fluorine-based compound. In one or more embodiments, the optoelectronic device may further include a first compound that is different from the fluorine-based compound and absorbs light having a wavelength in a range of about 400 nm to about 1,000 nm.

In one or more embodiments, the photoactive layer may include a fluorine layer and a first layer between the first electrode and the fluorine layer. The fluorine layer may include the fluorine-based compound. The first layer may include the first compound.

In one or more embodiments, a thickness of the fluorine layer may be less than a thickness of the first layer. The thickness of the fluorine layer may be about 10 nm or less.

In one or more embodiments, the optoelectronic device may further include a second compound that is different from the fluorine-based compound and is not a fullerene-based compound.

In one or more embodiments, the photoactive layer may include a second layer and a fluorine layer between the first electrode and the second layer. The fluorine layer may include the fluorine-based compound. The second layer may include the second compound.

In one or more embodiments, a thickness of the fluorine layer may be less than a thickness of the second layer.

In one or more embodiments, the fluorine-based compound may not include any one selected from among —Cl, —Br, —I, and a cyano group.

In one or more embodiments, in Formulae F, F-Y, and F-Z, Ar₁ to Ar₆ may each independently be selected from among a C₆-C₆₀ aryl group substituted with at least five —F and a C₂-C₆₀ heteroarylalkyl group substituted with at least five —F.

In one or more embodiments, in Formulae F, F-Y, and F-Z, Ar₁ to Ar₆ may each independently be a phenyl group, a naphthyl group, an anthracenyl group, a phenanthrenyl group, a tetracenyl group, a chrysenyl group, a pyrenyl group, a pyridinyl group, a pyrimidinyl group, a triazinyl group, a pyrazinyl group, a quinolinyl group, an isoquinolinyl group, a quinazolinyl group, or a quinoxalinyl group, each being substituted with at least two-F.

In one or more embodiments, in Formulae F, F-Y, and F-Z, n1, n2, n31 to n35, and n4 may each be 1.

In one or more embodiments, in Formula F-Y, T₁ may be O.

In one or more embodiments, in Formula F-Y, a1 may be an integer of 0 to 3.

In one or more embodiments, the fluorine-based compound may be one selected from among Compounds F1 to F4 as described in one or more embodiments.

According to one or more embodiments, an electronic apparatus may include the optoelectronic device as described in one or more embodiments.

In one or more embodiments, the electronic apparatus may further include a light-emitting device including an emission layer that is between the first electrode and the second electrode and that does not overlap the photoactive layer.

In one or more embodiments, the optoelectronic device may further include a first hole transport region between the first electrode and the photoactive layer and a first electron transport region between the photoactive layer and the second electrode.

The light-emitting device may further include a second hole transport region between the first electrode and the emission layer and a second electron transport region between the emission layer and the second electrode.

In one or more embodiments, the first hole transport region and the second hole transport region may each be a common layer. The first electron transport region and the second electron transport region may each be another common layer.

According to one or more embodiments, electronic equipment may include the electronic apparatus, wherein the electronic equipment may be one selected from among a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality display, an augmented reality display, a vehicle, a video wall including a plurality of displays tiled together, a theater screen, a stadium screen, a phototherapy device, a signboard, a sensor for vehicles, a sensor for home, and a solar cell.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a schematic view of an optoelectronic device according to one or more embodiments;

FIG. 2 is a schematic view of an optoelectronic device according to one or

more embodiments;

FIG. 3 is a schematic view of an optoelectronic device according to one or more embodiments;

FIG. 4 is a schematic view of a light-emitting device included in an electronic apparatus according to one or more embodiments;

FIG. 5 is a cross-sectional view of an electronic apparatus according to one or more embodiments;

FIG. 6 is a cross-sectional view of an electronic apparatus according to one or more embodiments;

FIG. 7 is a schematic perspective view of electronic equipment including an optoelectronic device according to one or more embodiments;

FIG. 8 is a schematic view of the exterior of a vehicle as electronic equipment including an optoelectronic device according to one or more embodiments;

FIGS. 9A-9C are each a schematic view of the interior of a vehicle according to one or more embodiments; and

FIGS. 10A-10C are graphs of the results according to Evaluation Example 1.

### DETAILED DESCRIPTION

Reference will be made in more detail to one or more embodiments, examples of which are illustrated in the accompanying drawings, wherein like reference numerals refer to like elements throughout the attached drawings and the written description, and duplicative descriptions thereof may not be provided in the specification. In this regard, the subject matter of the present disclosure may be embodied in different forms and should not be construed as being limited to one or more embodiments set forth herein. Rather, these embodiments are provided as examples, by referring to the figures, to explain the aspects and features of the present disclosure to those skilled in the art.

The singular forms as used herein are intended to include the plural forms as well unless the context clearly indicates otherwise.

As used herein, the term “and/or” includes any and all combinations of one or more of the associated listed items.

Throughout the disclosure, the expression “at least one of a, b, or c” or “at least one selected from among a, b, and c” indicates only a, only b, only c, both a and b, both a and c, both b and c, all of a, b, and c, or variations thereof.

As used herein, the terms “substantially,” “about,” and similar terms are used as terms of approximation and not as terms of degree and are intended to account for the inherent deviations in measured or calculated values that would be recognized by those of ordinary skill in the art.

The use of “may” if (e.g., when) describing embodiments of the present disclosure refers to “one or more embodiments of the present disclosure.”

As used herein, the terms “use,” “using,” and “used” may be considered synonymous with the terms “utilize,” “utilizing,” and “utilized,” respectively.

It will be further understood that the terms “has,” “having,” “include,” and/or “including” used herein specify the presence of stated features or components, but do not preclude the presence or addition of one or more other features or components. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in the present disclosure is intended to include all higher numerical limitations subsumed therein. Accordingly, Applicant reserves the right to amend this specification, including the claims, to expressly recite any sub-range subsumed within the ranges expressly recited herein.

As utilized herein, the term “about” or similar terms are used as terms of approximation and not as terms of degree and are intended to account for the inherent deviations in measured or calculated values that would be recognized by those of ordinary skill in the art. The term “about” or “approximately,” as used herein, is also inclusive of the stated value and refers to within an acceptable range of deviation for the particular value as determined by one of ordinary skill in the art, considering the measurement in question and the error associated with measurement of the particular quantity (e.g., the limitations of the measurement system). For example, “about” may refer to within one or more standard deviations, or within ±30%, ±20%, ±10%, or ±5% of the stated value.

It will be understood that if (e.g., when) a layer, a region, or a component is referred to as being “on” or “onto” another layer, region, or component, it may be directly or indirectly on the other layer, region, or component. For example, intervening layers, regions, or components may be present therebetween. In contrast, if (e.g., when) a layer, a region, or a component is referred to as being “directly on” another layer, region, or component, there may be no intervening layers, regions, or components present therebetween.

The sizes of elements in the drawings may be exaggerated to effectively or suitably illustrate the technical contents of the present disclosure. For example, because the sizes and thicknesses of components in the drawings may be arbitrarily illustrated for convenience of explanation, the following embodiments are not limited thereto.

The x-axis, the y-axis, and the z-axis are not limited to three axes of the rectangular coordinate system and may be interpreted in a broader sense. For example, the x-axis, the y-axis, and the z-axis may be perpendicular (e.g., substantially perpendicular) to one another or may represent different directions that are not perpendicular to one another.

It will be understood that, although the terms “first,” “second,” “third,” and/or the like may be used herein to describe one or more elements, components, regions, layers, and/or sections, these elements, components, regions, layers, and/or sections should not be limited by these terms. These terms are used to distinguish one element, component, region, layer, or section from another element, component, region, layer, or section. Thus, a first element, a first component, a first region, a first layer, or a first section as described herein may be termed a second element, a second component, a second region, a second layer, or a second section, without departing from the spirit and scope of the present disclosure.

Unless otherwise defined, all terms, including technical terms and scientific terms, used herein have substantially the same meaning as how they are generally understood by those of ordinary skill in the art to which the present disclosure pertains. Any term that is defined in a general dictionary shall be construed to have substantially the same meaning in the context of the relevant art and, unless otherwise defined explicitly, shall not be interpreted to have an idealistic or excessively formalistic meaning.

The expression “an optoelectronic device, a photoactive layer, and/or a fluorine layer includes a fluorine-based compound represented by Formula F” as used herein may be understood as “an optoelectronic device, a photoactive layer, and/or a fluorine layer includes one kind or type of fluorine-based compound represented by Formula F” or “an optoelectronic device, a photoactive layer, and/or a fluorine layer includes two or more different kinds or types of fluorine-based compounds, each represented by Formula F.”

One or more embodiments of the present disclosure provide an optoelectronic device including: a first electrode; a second electrode opposite to (e.g., facing) the first electrode; a photoactive layer between the first electrode and the second electrode; and a fluorine-based compound represented by Formula F:

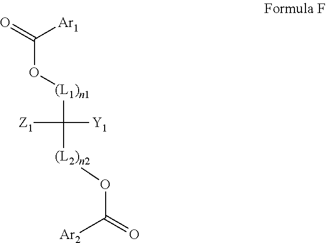

wherein, in Formula F,
Y₁ may be selected from among a group represented by Formula F-Y, hydrogen, deuterium, —F, a C₁-C₆₀ alkyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, and a C₁-C₆₀ heterocyclic group unsubstituted or substituted with at least one R₁₀ₐ, and
Z₁ may be selected from among a group represented by Formula F-Z, hydrogen, deuterium, —F, a C₁-C₆₀ alkyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, and a C₁-C₆₀ heterocyclic group unsubstituted or substituted with at least one R₁₀ₐ,

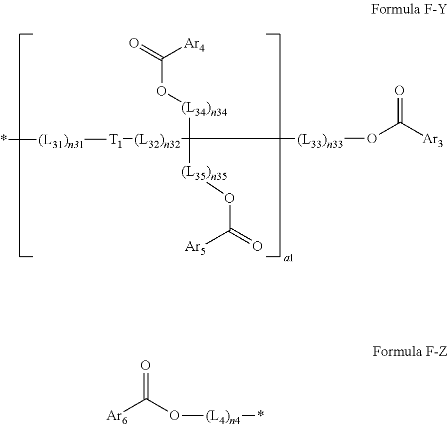

wherein, in Formulae F, F-Y, and F-Z,
Ar₁ to Ar₆ may each independently be selected from among a C₆-C₆₀ aryl group substituted with at least two-F and a C₂-C₆₀ heteroarylalkyl group substituted with at least two —F,
L₁, L₂, L₃₁ to L₃₅, and L₄ may each independently be a C₁-C₂₀ alkylene group unsubstituted or substituted with at least one R₁₀ₐ,
n1, n2, n31 to n35, and n4 may each independently be 0 or 1,
T₁ may be O or S,
a1 may be an integer of 0 to 10,
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each being unsubstituted or substituted with deuterium, —F, —Cl, —Br, —I, a hydroxyl group, a cyano group, a nitro group, a C₃-C₆₀ carbocyclic group, a C₁-C₆₀ group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each being unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ may each independently be:
hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, or a C₁-C₆₀ alkoxy group; or
a C₃-C₆₀ carbocyclic group, a C₁-C₆₀ heterocyclic group, a C₇-C₆₀ arylalkyl group, or a C₂-C₆₀ heteroarylalkyl group, each being unsubstituted or substituted with deuterium, —F, a cyano group, a C₁-C₆₀ alkyl group, a C₁-C₆₀ alkoxy group, a phenyl group, a biphenyl group, or any combination thereof, and
* indicates a binding site to a neighboring atom.

The optoelectronic device may further include a hole transport region between the first electrode and the photoactive layer and an electron transport region between the photoactive layer and the second electrode.

In one or more embodiments, the photoactive layer may absorb light having a wavelength in a range of about 400 nm to about 1,000 nm. For example, the photoactive layer may absorb at least one selected from among blue light, green light, red light, and near-infrared light.

In one or more embodiments, the photoactive layer may include the fluorine-based compound represented by Formula F.

In one or more embodiments, the optoelectronic device may further include a first compound that is different from the fluorine-based compound and absorbs light having a wavelength in a range of about 400 nm to about 1,000 nm. The first compound may be referred to as a donor.

In one or more embodiments, the optoelectronic device may further include a second compound that is different from the fluorine-based compound and is not a fullerene-based compound. The second compound may be referred to as an acceptor.

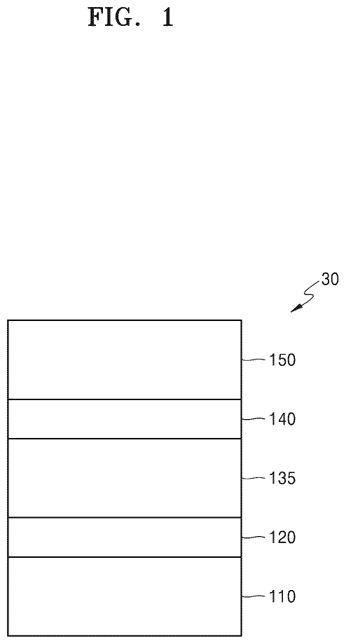

FIG. 1 is a schematic view of an optoelectronic device 30 according to one or more embodiments.

Referring to FIG. 1, the optoelectronic device 30 may include a first electrode 110, a hole transport region 120 on the first electrode 110, a photoactive layer 135 on the hole transport region 120, an electron transport region 140 on the photoactive layer 135, and a second electrode 150 on the electron transport region 140.

In one or more embodiments, the photoactive layer 135 may include at least one selected from among a fluorine-based compound represented by Formula F, a first compound represented by Formula 1, and a second compound represented by Formula 2. The photoactive layer 135 may include each of the fluorine-based compound, the first compound, and the second compound. The fluorine-based compound, the first compound, and the second compound may be mixed with each other.

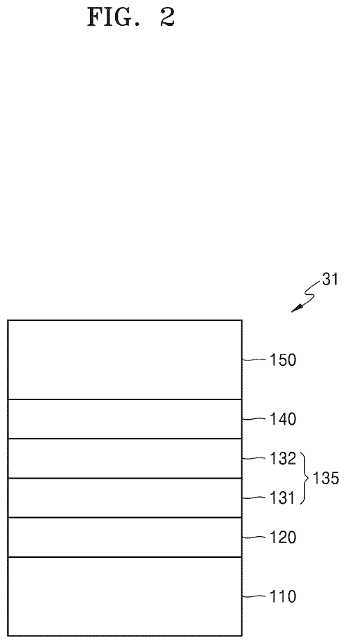

FIG. 2 is a schematic view of an optoelectronic device 31 according to one or more embodiments.

Referring to FIG. 2, the optoelectronic device 31 may include a first electrode 110, a hole transport region 120 on the first electrode 110, a photoactive layer 135 on the hole transport region 120, an electron transport region 140 on the photoactive layer 135 and a second electrode 150 on the electron transport region 140. The photoactive layer 135 may include a first layer 131 and a second layer 132. The first layer 131 may be between the first electrode 110 and the second layer 132. The second layer 132 may be between the first layer 131 and the second electrode 150.

The thickness of the first layer 131 may be less than the thickness of the second layer 132. The thickness of the first layer 131 may be in a range of about 5 nm to about 30 nm or about 10 nm to about 20 nm. The thickness of the second layer 132 may be in a range of about 20 nm to about 50 nm or about 30 nm to about 40 nm.

In one or more embodiments, the photoactive layer 135 may include each of a fluorine-based compound represented by Formula F, a first compound represented by Formula 1, and a second compound represented by Formula 2.

In one or more embodiments, the first layer 131 may include the first compound and the fluorine-based compound, and the second layer 132 may include the second compound and the fluorine-based compound. For example, the fluorine-based compound may be present in both (e.g., simultaneously) the first layer 131 and the second layer 132.

In one or more embodiments, the first layer 131 may include the first compound and the fluorine-based compound, and the second layer 132 may include the second compound. For example, the fluorine-based compound may be present in the first layer 131 and may be mixed with the first compound.

In one or more embodiments, the first layer 131 may include the first compound, and the second layer 132 may include the second compound and the fluorine-based compound. For example, the fluorine-based compound may be present in the second layer 132 and may be mixed with the second compound.

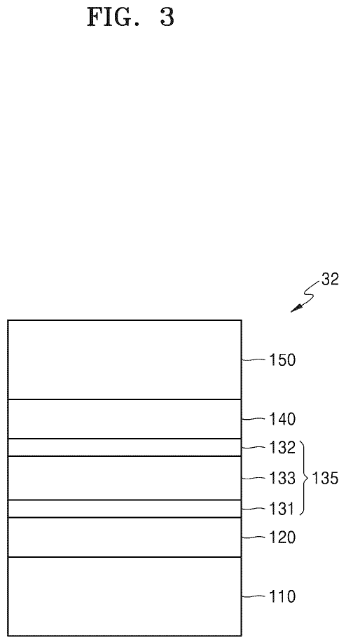

FIG. 3 is a schematic view of an optoelectronic device 32 according to one or more embodiments.

Referring to FIG. 3, the optoelectronic device 32 may include a first electrode 110, a hole transport region 120 on the first electrode 110, a photoactive layer 135 on the hole transport region 120, an electron transport region 140 on the photoactive layer 135, and a second electrode 150 on the electron transport region 140. The photoactive layer 135 may include a first layer 131, a second layer 132, and a fluorine layer 133. The first layer 131 may be between the first electrode 110 and the second layer 132.

The second layer 132 may be between the first layer 131 and the second electrode 150. The fluorine layer 133 may be between the first layer 131 and the second layer 132.

In one or more embodiments, the thickness of the fluorine layer 133 may be less than the thickness of the first layer 131 and/or the thickness of the second layer 132. The thickness of the first layer 131 may be in a range of about 5 nm to about 30 nm or about 10 nm to about 20 nm. The thickness of the second layer 132 may be in a range of about 20 nm to about 50 nm or about 30 nm to about 40 nm. The thickness of the fluorine layer 133 may be in a range of about 0.5 nm to about 10 nm, about 0.6 nm to about 9 nm, about 0.7 nm to about 8 nm, about 0.8 nm to about 7 nm, about 0.9 nm to about 6 nm, or about 1 nm to about 5 nm.

In one or more embodiments, the photoactive layer 135 may include each of a fluorine-based compound represented by Formula F, a first compound represented by Formula 1, and a second compound represented by Formula 2.

In one or more embodiments, the first layer 131 may include the first compound, the second layer 132 may include the second compound, and the fluorine layer 133 may include the fluorine-based compound. For example, the fluorine-based compound may be present between the first layer 131 and the second layer 132.

### Fluorine-Based Compound

The fluorine-based compound may be represented by Formula F. The fluorine-based compound may include fluorine and may not include chlorine (—Cl), bromine (—Br), iodine (—I), and a cyano group (—CN).

The deposition temperature of the fluorine-based compound may be about 350° C. or lower. For example, if (e.g., when) a layer including the fluorine-based compound is formed or provided by vacuum deposition, the layer may be deposited even at 350° C. or lower. If (e.g., when) a layer including the fluorine-based compound is deposited at a temperature higher than about 350° C., the lifespan of a manufactured optoelectronic device may be reduced. In one or more embodiments, a compound having a deposition temperature higher than about 350° C. may be clearly or substantially different from the fluorine-based compound. For example, the deposition temperature of the fluorine-based compound may be in a range of about 100° C. to about 350° C., about 200° C. to about 350° C., about 300° C. to about 350° C., about 100° C. to about 340° C., about 200° C. to about 340° C., or about 300° C. to about 340° C.

In one or more embodiments, in Formulae F, F-Y, and F-Z, Ar₁ to Ar₆ may each independently be selected from among a C₆-C₆₀ aryl group substituted with at least five —F and a C₂-C₆₀ heteroarylalkyl group substituted with at least five —F.

In one or more embodiments, in Formulae F, F-Y, and F-Z, Ar₁ to Ar₆ may each independently be: a phenyl group; a naphthyl group; an anthracenyl group; a phenanthrenyl group; a tetracenyl group; a chrysenyl group; a pyrenyl group; a pyridinyl group; a pyrimidinyl group; a triazinyl group; a pyrazinyl group; a quinolinyl group; an isoquinolinyl group; a quinazolinyl group; or a quinoxalinyl group, each being substituted with at least two-F. For example, Ar₁ to Ar₆ may each independently be a phenyl group substituted with at least two —F, at least three —F, at least four —F, or at least five —F.

In one or more embodiments, L₁, L₂, L₃₁ to L₃₅, and L₄ may each independently be a C₁-C₁₀ alkylene group unsubstituted or substituted with at least one R₁₀ₐ. For example, L₁, L₂, L₃₁ to L₃₅, and L₄ may each independently be a methylene group (—CH₂—), an ethylene group (—CH₂CH₂—), or a propylene group (—CH₂CH₂CH₂— or —CH₂CH(CH₃)—).

If (e.g., when) n1 is 0, (L₁)ₙ₁ may be a single bond (e.g., a single covalent bond). If (e.g., when) n2, n31 to n35, and n4 are each 0, (L₂)ₙ₂, (L₃₁)ₙ₃₁, (L₃₂)ₙ₃₂, (L₃₃)ₙ₃₃, (L₃₄)ₙ₃₄, (L₃₅)ₙ₃₅, and (L₄)ₙ₄ may each be a single bond (e.g., a single covalent bond).

In one or more embodiments, n1, n2, n31 to n35, and n4 may each be 1.

In one or more embodiments, T₁ may be O.

In one or more embodiments, Y₁ in Formula F may be selected from among a group represented by Formula F-Y, hydrogen, deuterium, —F, a C₁-C₆₀ alkyl group unsubstituted or substituted with at least one R₁₀ₐ, and a C₁-C₆₀ alkoxy group unsubstituted or substituted with at least one R₁₀ₐ. Y₁ may be a group represented by Formula F-Y or hydrogen.

If (e.g., when) a1 in Formula F-Y is 0, Formula F-Y may be represented by Formula F-Y0:

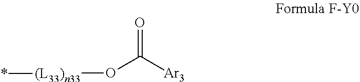

wherein, in Formula F-Y0, Ar₃, L₃₃, n33, and * may each be the same as defined in one or more embodiments.

In one or more embodiments, a1 may be an integer of 0 to 5, may be an integer of 0 to 4, may be an integer of 0 to 3, or may be an integer of 0 to 2.

In one or more embodiments, Z₁ in Formula F may be selected from among a group represented by Formula F-Z, hydrogen, deuterium, —F, a C₁-C₆₀ alkyl group unsubstituted or substituted with at least one R₁₀ₐ, and a C₁-C₆₀ alkoxy group unsubstituted or substituted with at least one R₁₀ₐ. Z₁ may be a group represented by Formula F-Z or hydrogen.

The fluorine-based compound may be one selected from among Compounds F1 to F4:

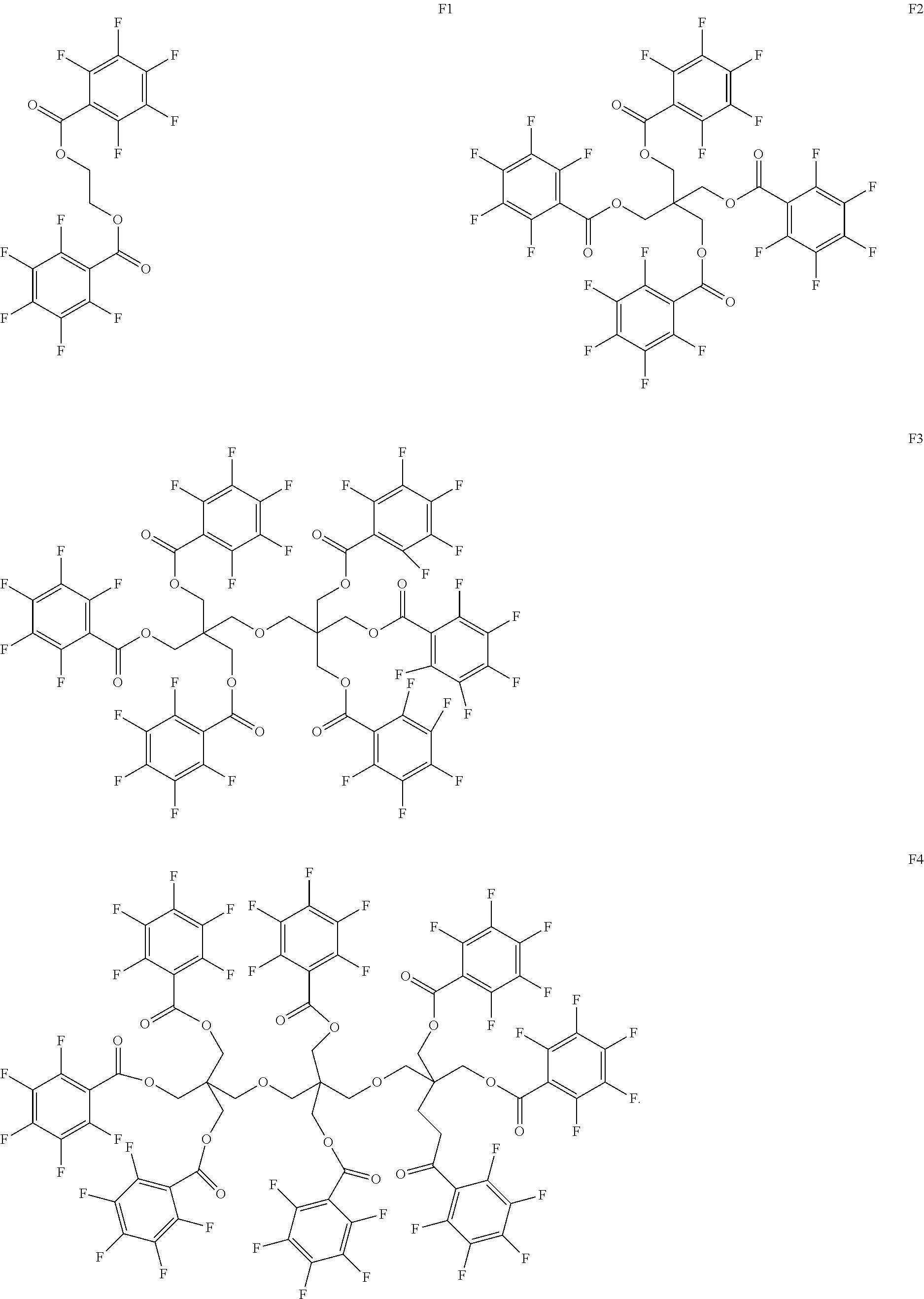

The optoelectronic device 30, 31, or 32 may include at least one fluorine-based compound represented by Formula F. The fluorine-based compound may be applied to the photoactive layer 135, may be mixed with a donor (e.g., the first compound) and/or an acceptor (e.g., the second compound), and may be applied to an interface between the donor and the acceptor. The fluorine-based compound may effectively or suitably separate excitons, which are generated if (e.g., when) the donor absorbs light, into charges (e.g., electrons and holes). In one or more embodiments, the number of excitons that are not separated and are annihilated by the exciton binding energy may be reduced. For example, the fluorine-based compound may improve or enhance exciton separation efficiency. By increasing the amount of charge separated by the fluorine-based compound, the amount of charge that passes through a relatively thick layer (e.g., a hole transport layer) and reaches an electrode (e.g., an anode or a cathode) may be effectively or suitably increased even under a relatively low voltage. As a result, the external quantum efficiency (EQE) of the optoelectronic device may be effectively or suitably increased.

Because the fluorine-based compound has a relatively small molecular weight compared to a compound including substituents, such as bromine (Br), iodine (I), and a cyano group (CN), the fluorine-based compound may be suitable for use in a deposition (e.g., vacuum thermal deposition) process.

### First Compound (Donor)

The first compound may be represented by Formula 1:

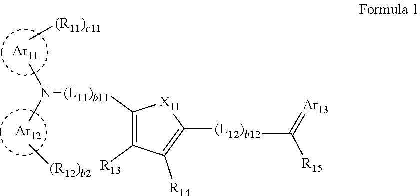

In Formula 1, Ar₁₃ may be a group represented by one selected from among Formulae 1-1 to 1-3:

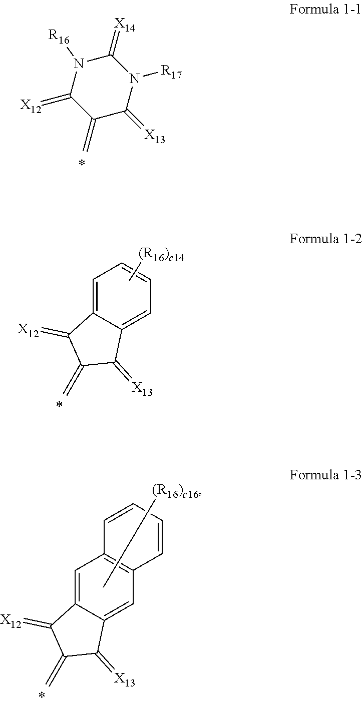

wherein, in Formulae 1 and 1-1 to 1-3,
Ar₁ and Ar₁₂ may each independently be a C₃-C₆₀ carbocyclic group or a C₁-C₆₀ heterocyclic group,
Ar₁₁ and Ar₁₂ may optionally be linked to each other via a single bond (e.g., a single covalent bond), *—O—*′, *—S—*′, *—C(T₁₁)(T₁₂)-*′, *—Si(T₁₁)(T₁₂)-*′, or *—N(T₁₁)-*′,
Ar₁₂ and an X₁₁-containing 5-membered ring may optionally be linked to each other via a single bond (e.g., a single covalent bond), *—O—*′, *—S—*′, *—C(T₁₃)(T₁₄)-*′, *—Si(T₁₃)(T₁₄)-*′, or *—N(T₁₃)-*′,
T₁₁ to T₁₄ may each independently be hydrogen, deuterium, —F, —Cl, a cyano group, a C₁-C₆₀ alkyl group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
X₁₁ may be O, S, Se, Te, SO, SO₂, C(R₁₁ₐ)(R_{11b}), Si(R_{11c})(R_{11d}), or N(R₁₁ₑ),
X₁₂ may be O, S, Se, Te, SO, SO₂, C(R₁₂ₐ)(R_{12b}), Si(R_{12c})(R_{12d}), or N(R₁₂ₑ),
X₁₃ may be O, S, Se, Te, SO, SO₂, C(R₁₃ₐ)(R_{13b}), Si(R_{13c})(R_{13d}), or N(R₁₃ₑ),
X₁₄ may be O, S, Se, Te, SO, SO₂, C(R₁₄ₐ)(R_{14b}), Si(R_{14c})(R_{14d}), or N(R₁₄ₑ),
L₁₁ and L₁₂ may each independently be a single bond (e.g., a single covalent bond), a C₁-C₂₀ alkylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
b11 and b12 may each be an integer of 1 to 3,
c11 and c12 may each be an integer of 1 to 10,
c14 may be an integer of 1 to 4, and c16 may be an integer of 1 to 6, R₁₁ to R₁₇, R₁₁ₐ to R₁₁ₑ, R₁₂ₐ to R₁₂ₑ, R₁₃ₐ to R₁₃ₑ, and R₁₄ₐ to R₁₄ₑ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), Q₁ to Q₃ may each independently be
hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, or a C₁-C₆₀ alkoxy group, or
a C₅-C₆₀ carbocyclic group, a C₁-C₆₀ heterocyclic group, a C₇-C₆₀ arylalkyl group, or a C₂-C₆₀ heteroarylalkyl group, each being unsubstituted or substituted with deuterium, —F, a cyano group, a C₁-C₆₀ alkyl group, a C₁-C₆₀ alkoxy group, a phenyl group, a biphenyl group, or any combination thereof,
* and *′ each indicates a binding site to a neighboring atom and R₁₀ₐ may be the same as defined in one or more embodiments.

The first compound may absorb blue light, green light, red light, near-infrared light, and/or any combination thereof. For example, the first compound may absorb green light having a maximum absorption wavelength in a range of about 450 nm to about 600 nm.

In Formula 1, Ar₁ and Ar₁₂ may each independently be a C₃-C₁₀ cycloalkyl group, a C₁-C₁₀ heterocycloalkyl group, a C₃-C₁₀ cycloalkenyl group, a C₁-C₁₀heterocycloalkenyl group, a C₆-C₆₀ aryl group, a C₁-C₆₀ heteroaryl group, a monovalent non-aromatic condensed polycyclic group, or a monovalent non-aromatic condensed heteropolycyclic group.

For example, Ar₁₁ and Ar₁₂ may each independently be a benzene group, a naphthalene group, a pyridine group, a pyrimidine group, or a triazine group.

In Formula 1, “Ar₁₁ and Ar₁₂ being optionally linked to each other” indicates that Ar₁₁ and Ar₁₂ are linked to each other or are not linked to each other. An example of “Ar₁₁ and Ar₁₂ being linked to each other via a single bond (e.g., a single covalent bond)” may be Compound A1 and/or the like, and an example of “Ar₁₁ and Ar₁₂ being linked to each other via *—C(T₁₁)(T₁₂)-*” may be Compound A65 and/or the like:

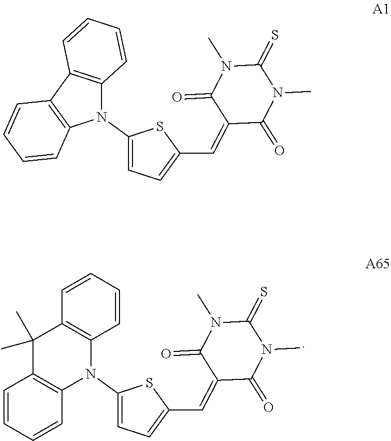

In one or more embodiments, Ar₁₁ and Ar₁₂ may be linked to each other via a single bond (e.g., a single covalent bond), *—O—*′, *—S—*′, *—C(T₁₁)(T₁₂)-*′, *—Si(T₁₁)(T₁₂)-*′, or *—N(T₁₁)-*′.

In one or more embodiments, T₁₁ and T₁₂ may each independently be selected from among:
hydrogen, deuterium, —F, —Cl, and a cyano group; and
a C₁-C₁₀ alkyl group unsubstituted or substituted with deuterium, —F, —Cl, a cyano group, or any combination thereof.

In Formula 1, “Ar₁₂ and an X₁₁-containing 5-membered ring being optionally linked to each other” indicates that Ar₁₂ and the X₁₁-containing 5-membered ring are linked to each other or are not linked to each other. Ar₁₂ and the X₁₁-containing 5-membered ring may be linked to each other at the position of R₁₃ in Formula 1. Examples of “Ar₁₂ and an X₁₁-containing 5-membered ring not being linked to each other” may be Compounds A1 and A65, and an example of “Ar₁₂ and an X₁₁-containing 5-membered ring being linked to each other via *—C(T₁₃)(T₁₄)-*” may be Compound A9 and/or the like:

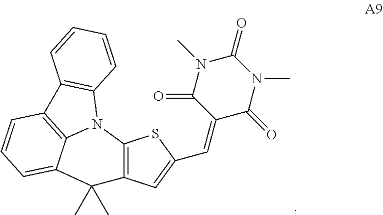 [SMILES: CN1C(=O)C(=Cc2cc3c(s2)-n2c4ccccc4c4cccc(c42)C3(C)C)C(=O)N(C)C1=O]

In one or more embodiments, Ar₁₂ and an X₁₁-containing 5-membered ring may optionally be linked to each other via a single bond (e.g., a single covalent bond) or *—C(T₁₃)(T₁₄)-*′.

In one or more embodiments, T₁₃ and T₁₄ may each independently be selected from among:
hydrogen, deuterium, —F, —Cl, and a cyano group; and
a C₁-C₁₀ alkyl group unsubstituted or substituted with deuterium, —F, —Cl, a cyano group, or any combination thereof.

In one or more embodiments, a moiety represented by

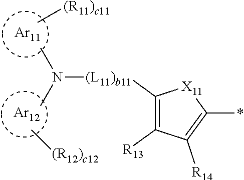

in Formula 1 may be a moiety represented by one selected from among Formulae 1A to 1E:

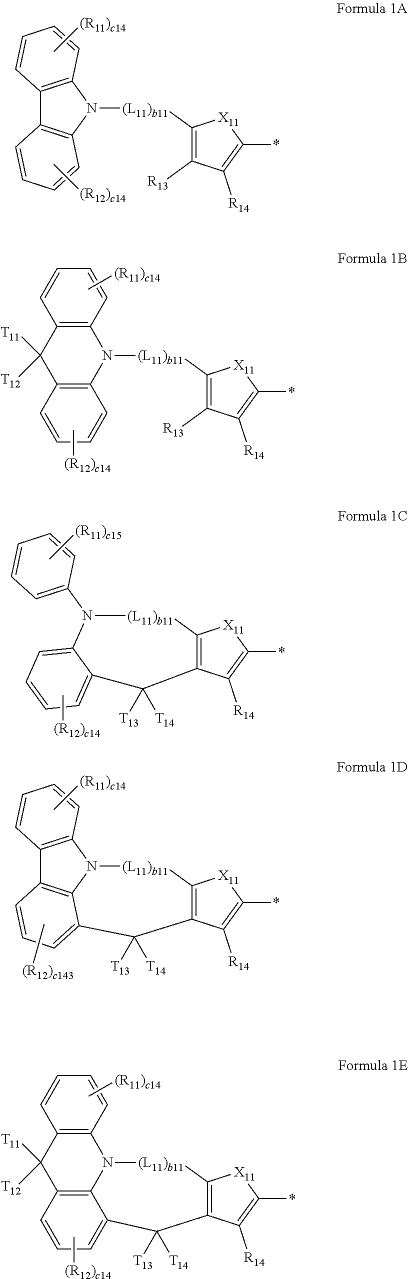

wherein, in Formulae 1A to 1E,
X₁₁, L₁₁, b11, T₁₁ to T₁₄, and R₁₁ to R₁₄ may each be the same as defined in one or more embodiments,
c13 may be an integer of 1 to 3,
c14 may be an integer of 1 to 4, and c15 may be an integer of 1 to 5, and
* indicates a binding site to (L₁₂) b12 in Formula 1.

In Formula 1, Aris may be a group represented by one selected from among Formulae 1-1, 1-2, and 1-3.

In Formulae 1-1 to 1-3, X₁₂ to X₁₄ may each independently be O, S, or Se. At least one selected from X₁₂ and X₁₃ may be O. X₁₄ may be O or S.

In Formulae 1-1 to 1-3, R₁₆ and R₁₇ may each independently be hydrogen, deuterium, —F, a cyano group, a C₁-C₆₀ alkyl group unsubstituted or substituted with at least one R₁₀ₐ, a C₁-C₆₀ alkoxy group unsubstituted or substituted with at least one R₁₀ₐ, a C₆-C₆₀ aryl group unsubstituted or substituted with at least one R₁₀ₐ, or a C₁-C₆₀ heteroaryl group unsubstituted or substituted with at least one R₁₀ₐ.

In Formula 1-2, if (e.g., when) c14 is 2 to 4, a plurality of R₁₆ may be identical to or different from each other. In Formula 1-3, if (e.g., when) c16 is 2 to 6, a plurality of R₁₆ may be identical to or different from each other.

In one or more embodiments, in Formula 1, at least one selected from L₁₁ and L₁₂ may be a single bond (e.g., a single covalent bond). For example, in Formula 1, b11 may be 1, and L₁₁ may be a single bond (e.g., a single covalent bond). For example, in Formula 1, b12 may be 1, and L₁₂ may be a single bond (e.g., a single covalent bond).

In one or more embodiments, the highest occupied molecular orbital (HOMO) energy level of the first compound may be in a range of about −5.5 eV to about −5.0 eV. For example, the absolute value of the HOMO energy level of the first compound may be in a range of about 5.0 eV to about 5.5 eV.

In one or more embodiments, the lowest unoccupied molecular orbital (LUMO) energy level of the first compound may be in a range of about −4.0 eV to about −3.0 eV. For example, the absolute value of the LUMO energy level of the first compound may be in a range of about 3.0 eV to about 4.0 eV.

In one or more embodiments, the first compound may be one selected from among Compounds A1 to A108:

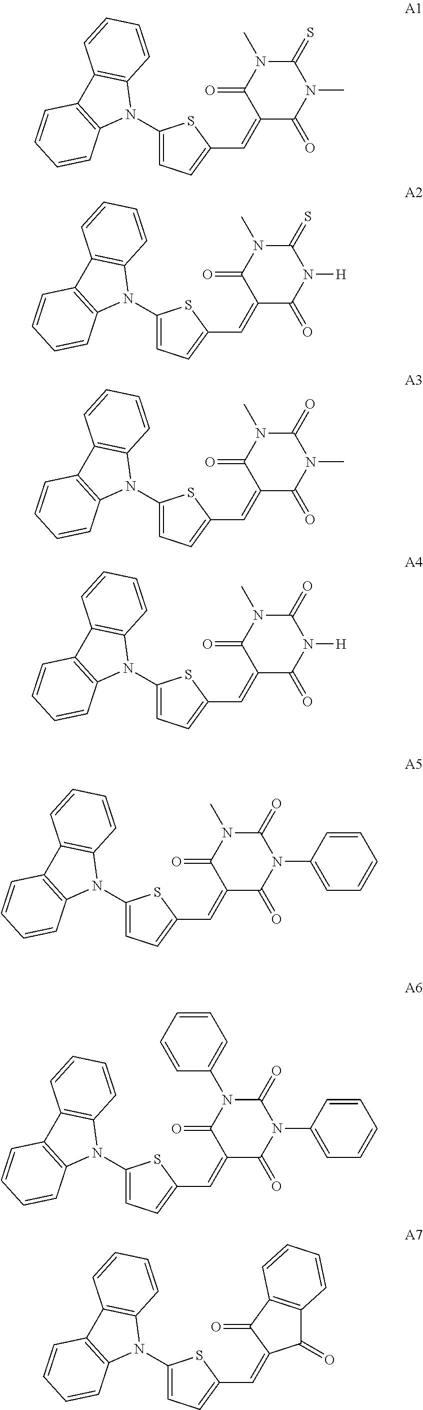

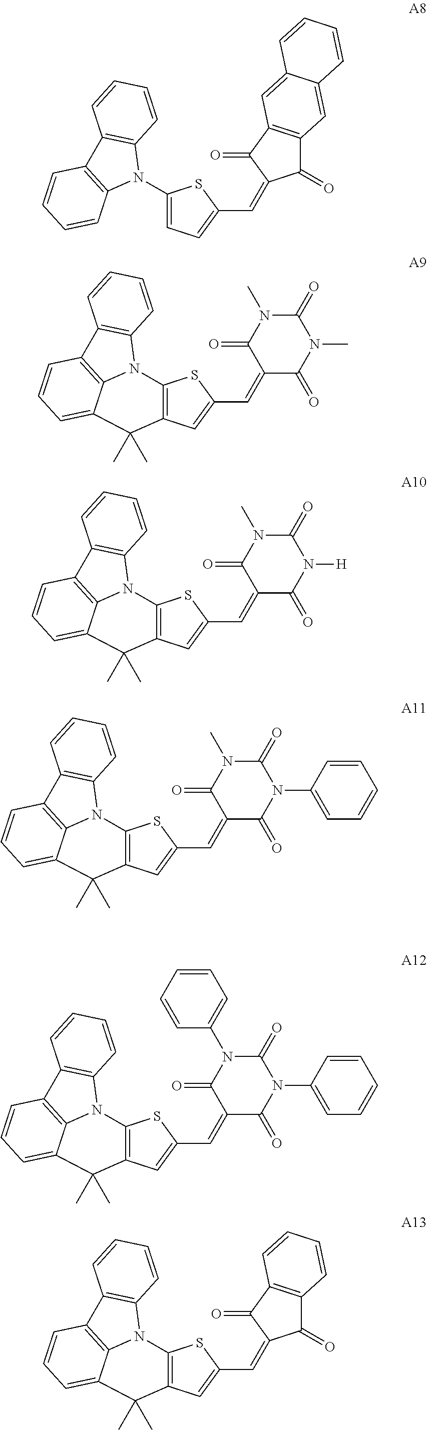

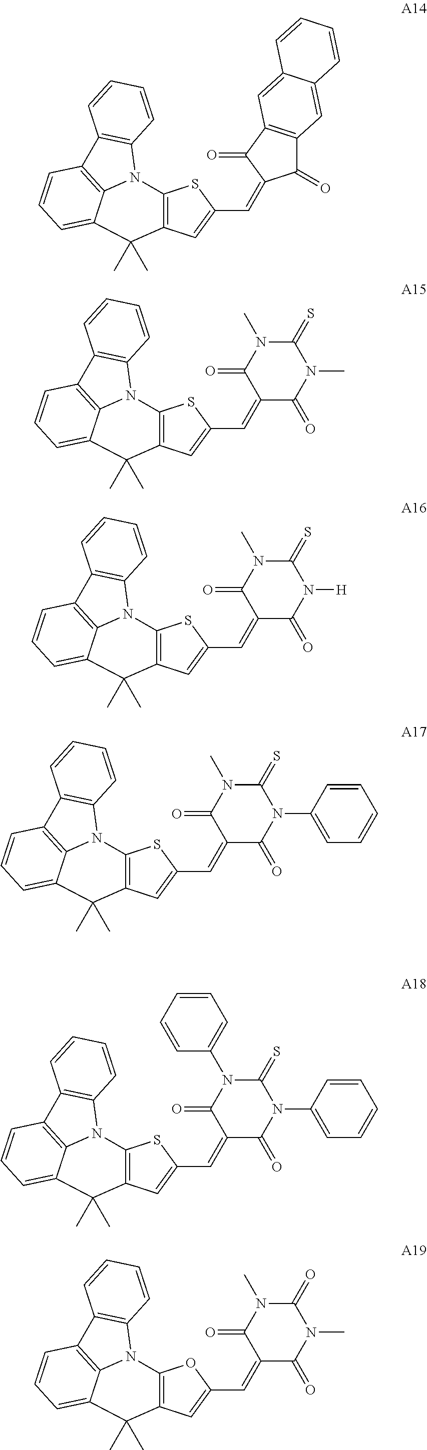

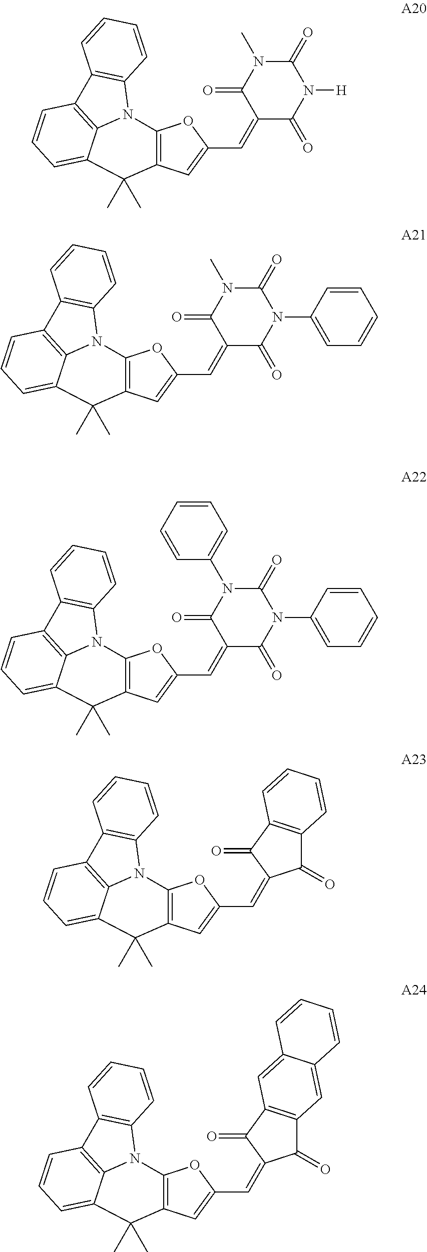

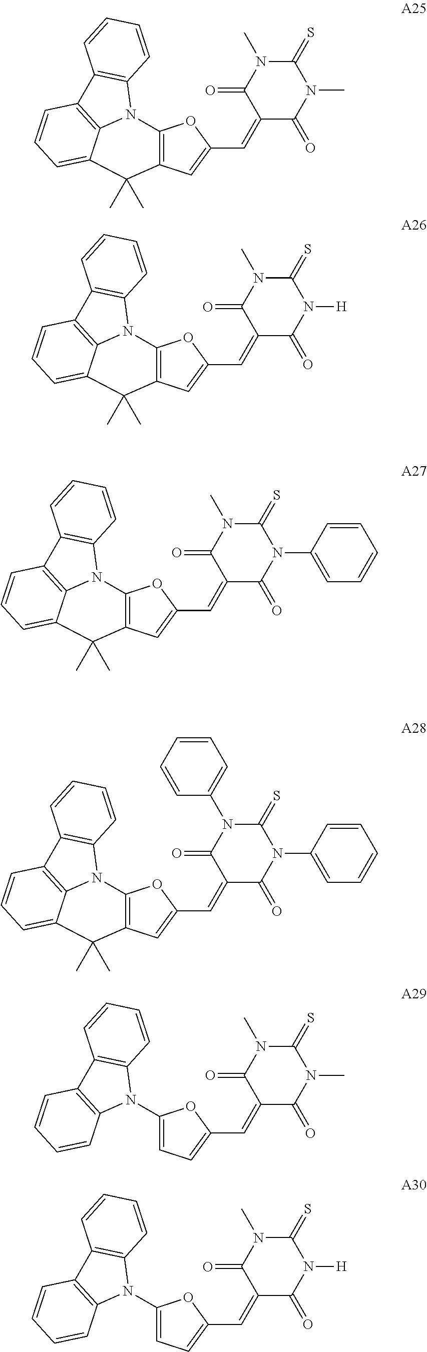

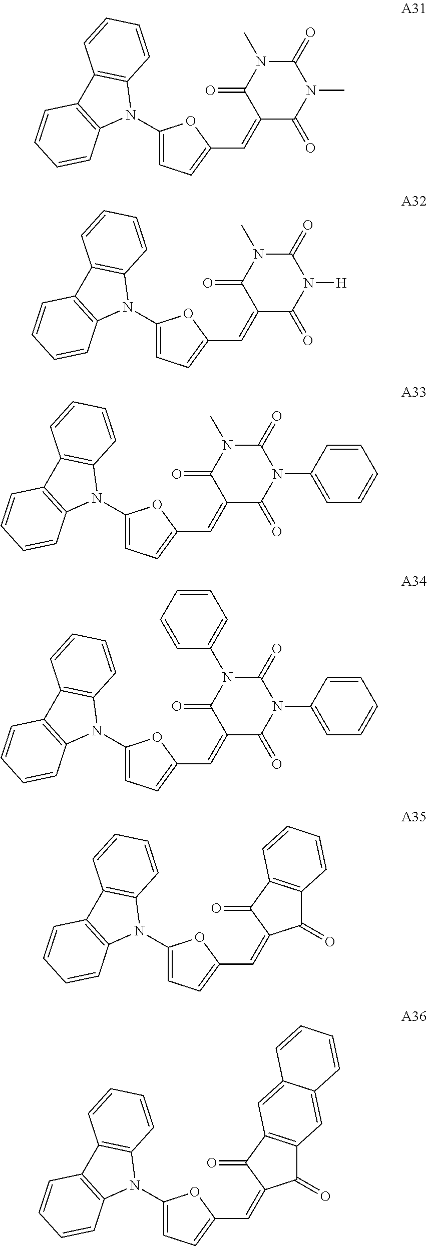

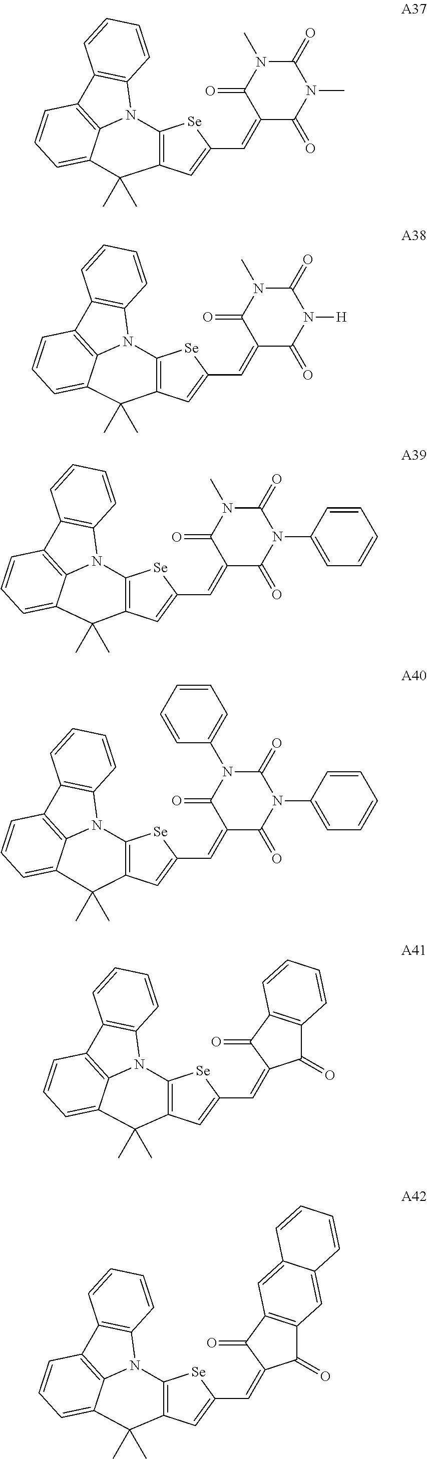

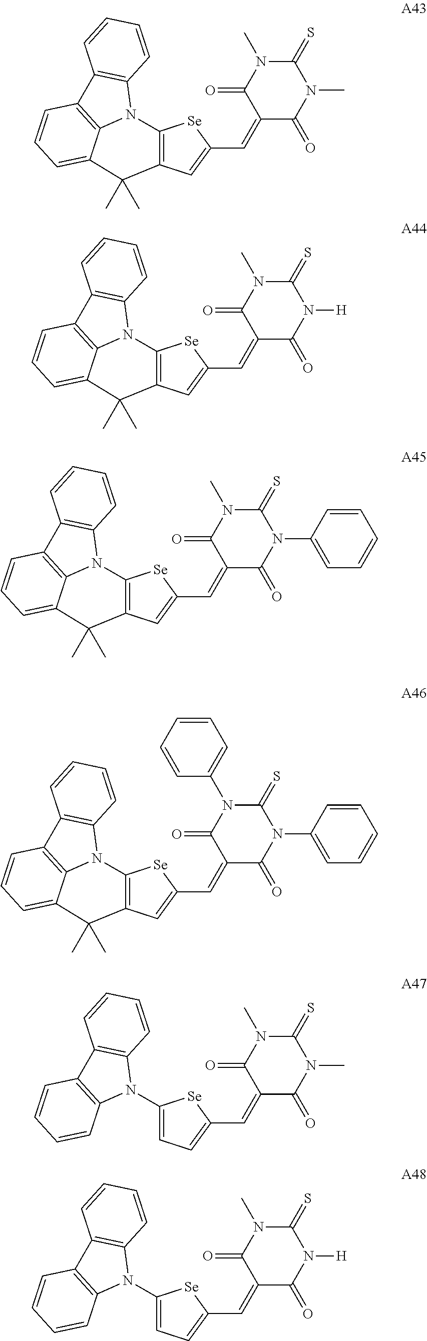

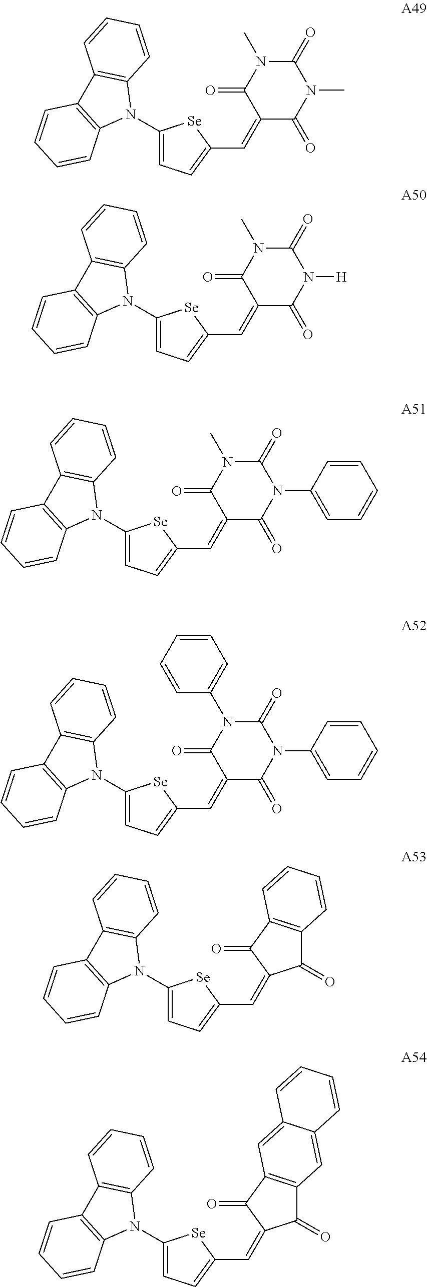 [SMILES: CN1C(=O)C(=Cc2ccc(-n3c4ccccc4c4ccccc43)[se]2)C(=O)N(C)C1=O ; CN1C(=O)NC(=O)/C(=C/c2ccc(-n3c4ccccc4c4ccccc43)[se]2)C1=O ; CN1C(=O)/C(=C\c2ccc(-n3c4ccccc4c4ccccc43)[se]2)C(=O)N(c2ccccc2)C1=O ; O=C1C(=Cc2ccc(-n3c4ccccc4c4ccccc43)[se]2)C(=O)N(c2ccccc2)C(=O)N1c1ccccc1 ; O=C1C(=Cc2ccc(-n3c4ccccc4c4ccccc43)[se]2)C(=O)c2ccccc21 ; O=C1C(=Cc2ccc(-n3c4ccccc4c4ccccc43)[se]2)C(=O)c2cc3ccccc3cc21]

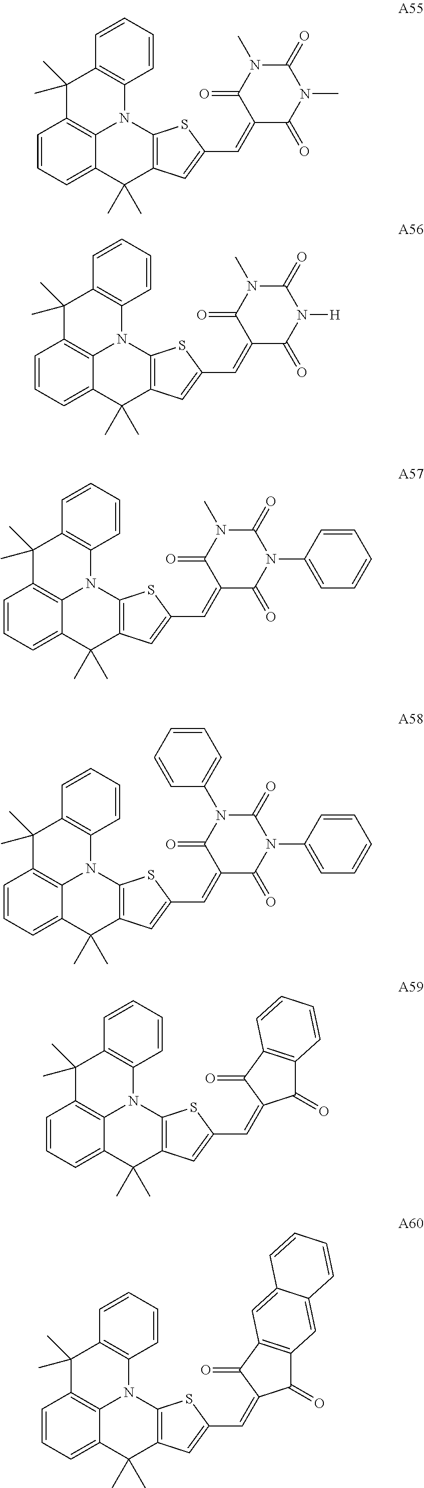

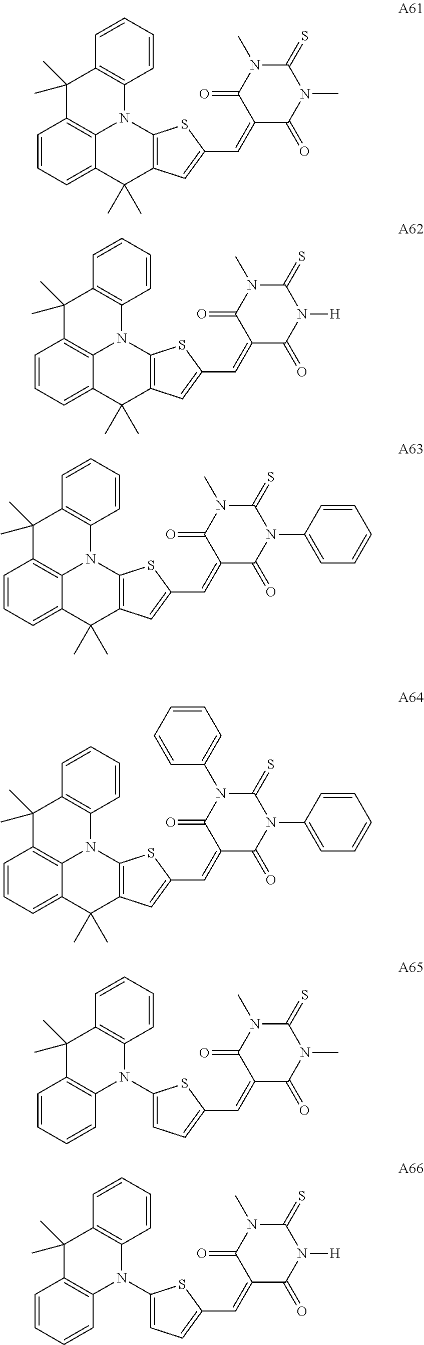

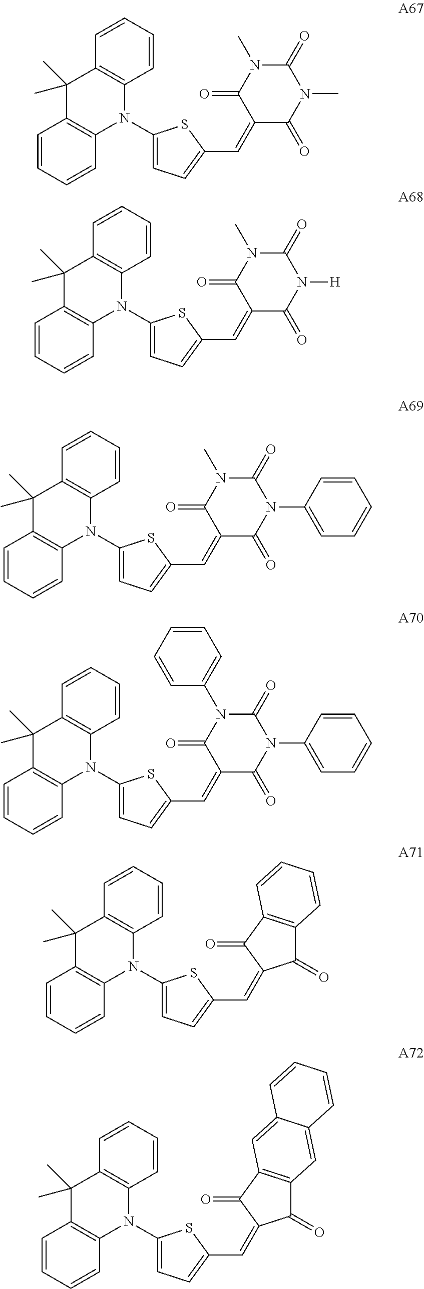

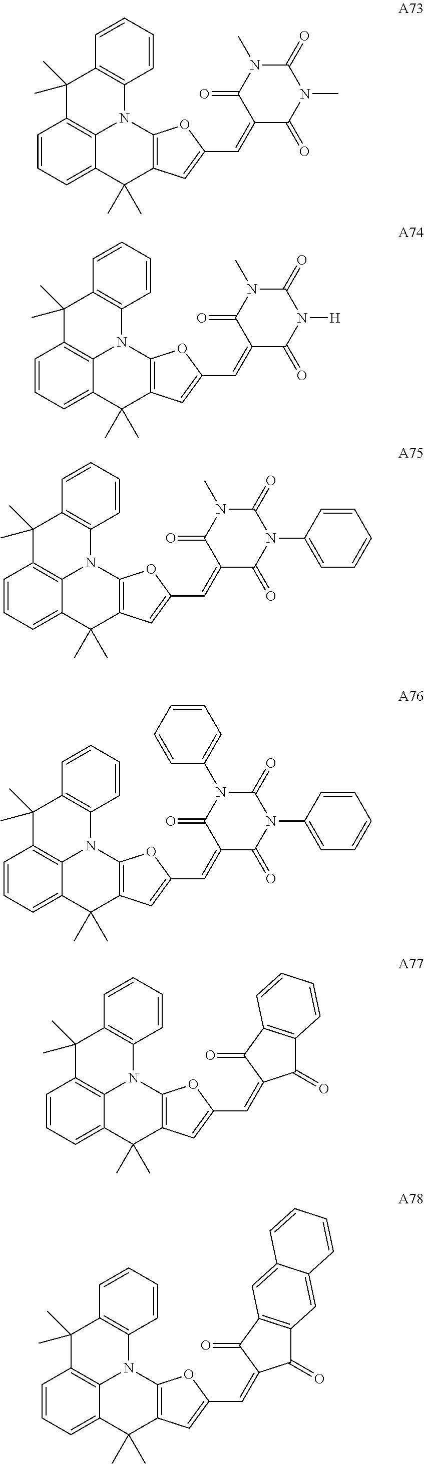

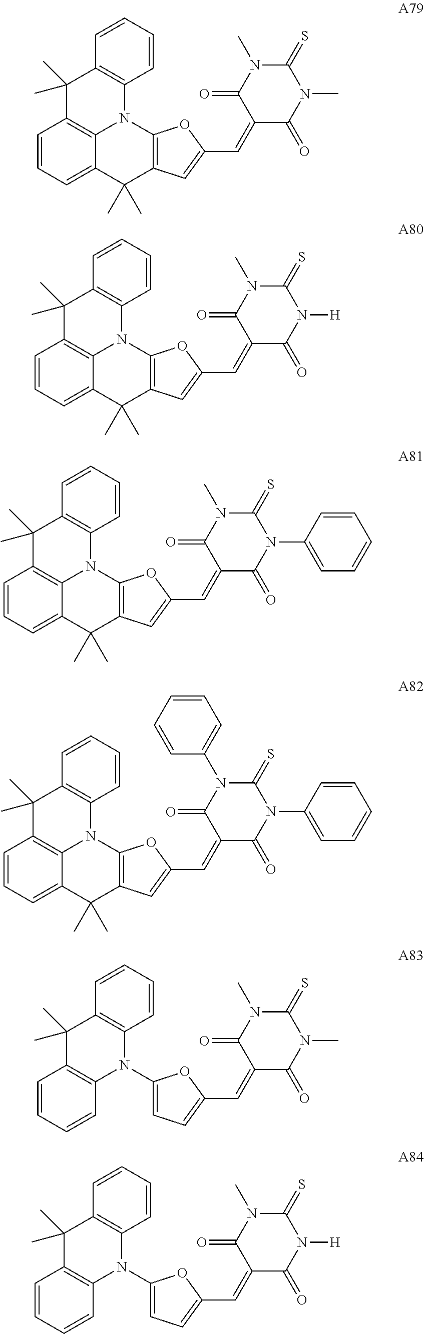

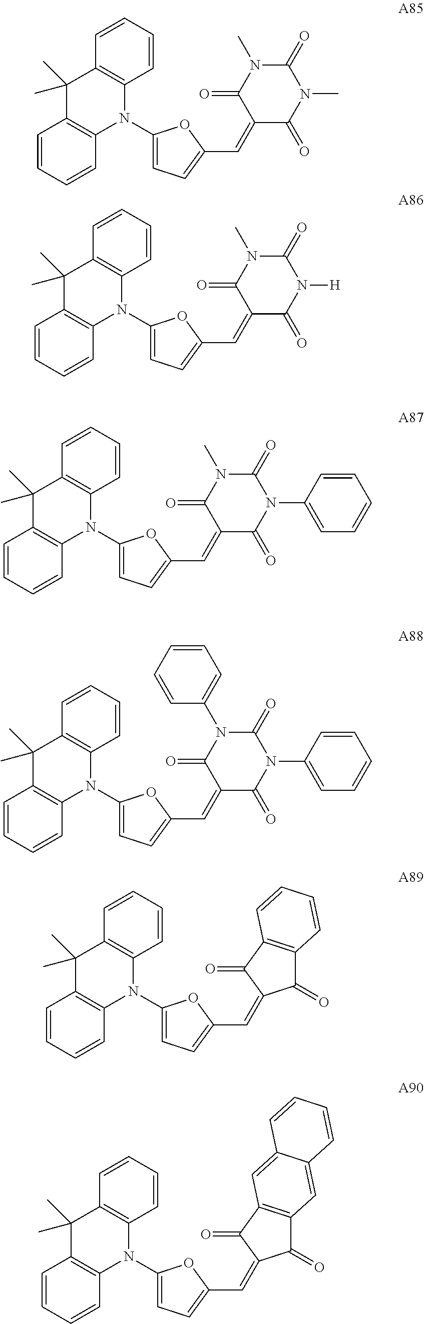

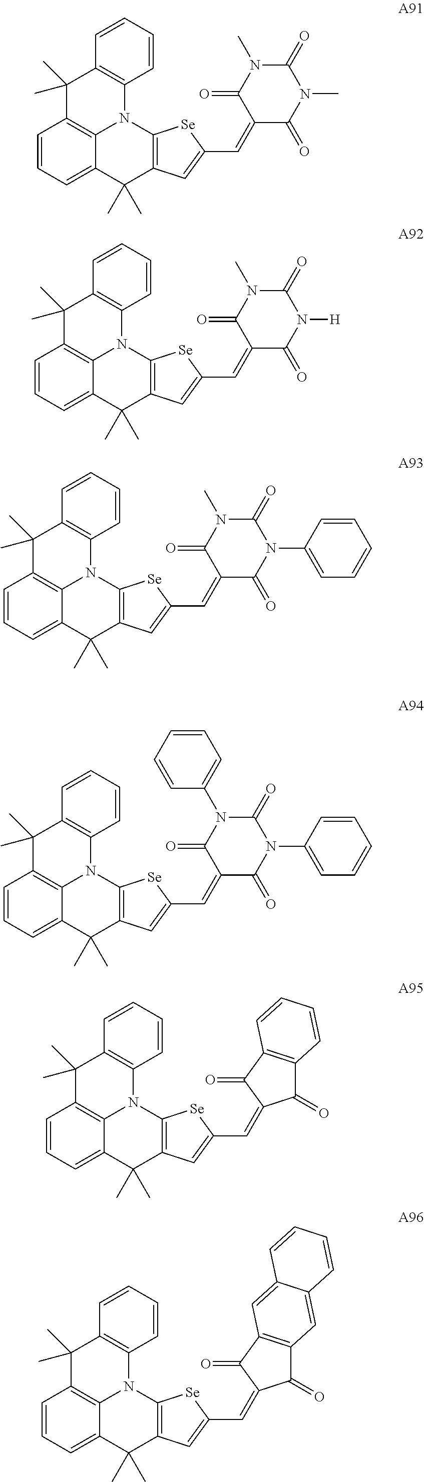

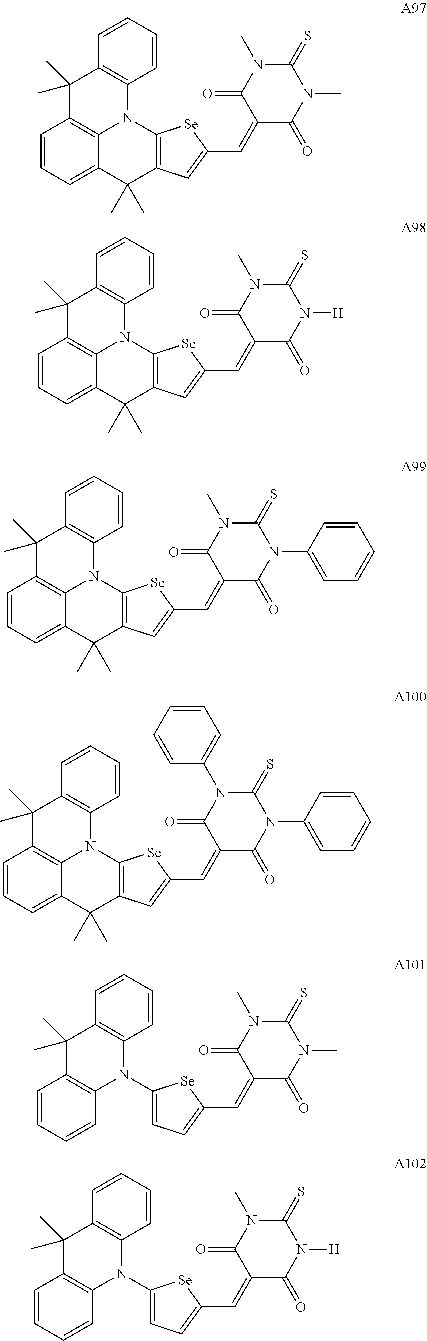

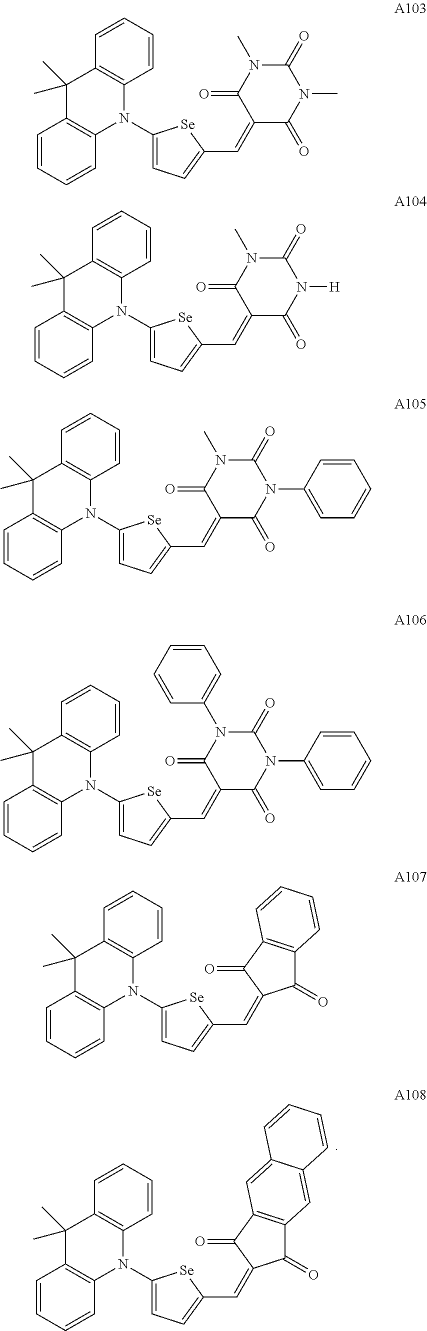

### Second Compound (Acceptor)

The second compound may be represented by Formula 2-1 or 2-2:

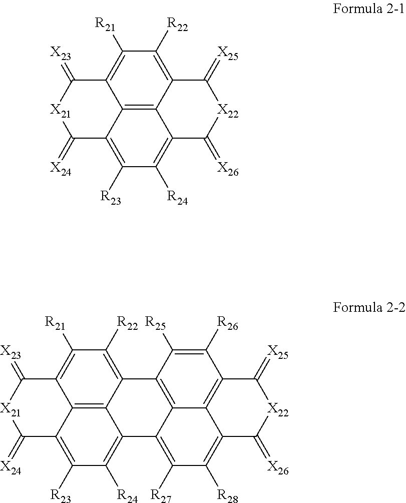

wherein, in Formulae 2-1 and 2-2,
X₂₁ may be O, S, Se, Te, SO, SO₂, C(R₂₁ₐ)(R_{21b}), Si(R_{21c})(R_{21d}), or N(R₂₁ₑ),
X₂₂ may be O, S, Se, Te, SO, SO₂, C(R₂₂ₐ)(R_{22b}), Si(R_{22c})(R_{22d}), or N(R₂₂ₑ),
X₂₃ may be O, S, Se, Te, SO, SO₂, C(R₂₃ₐ)(R_{23b}), Si(R_{23c})(R_{23d}), or N(R₂₃ₑ),
X₂₄ may be O, S, Se, Te, SO, SO₂, C(R₂₄ₐ)(R_{24b}), Si(R_{24c})(R_{24d}), or N(R₂₄ₑ),
X₂₅ may be O, S, Se, Te, SO, SO₂, C(R₂₅ₐ)(R_{25b}), Si(R_{25c})(R_{25d}), or N(R₂₅ₑ),
X₂₆ may be O, S, Se, Te, SO, SO₂, C(R₂₆ₐ)(R_{26b}), Si(R_{26c})(R_{26d}), or N(R₂₆ₑ),
R₂₁ to R₂₈, R₂₁ₐ to R₂₁ₑ, R₂₂ₐ to R₂₂ₑ, R₂₃ₐ to R₂₃ₑ, R₂₄ₐ to R₂₄ₑ, R₂₅ₐ to R₂₅ₑ, and R₂₆ₐ to R₂₆ₑ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and
R₁₀ₐ and Q₁ to Q₃ may each be the same as defined in one or more embodiments.

In one or more embodiments, in Formulae 2-1 and 2-2, X₂₁ may be O, S, or N(R₂₁ₑ), and X₂₂ may be O, S, or N(R₂₂ₑ).

In one or more embodiments, R₂₁ₑ and R₂₂ₑ may each independently be a C₆-C₆₀ aryl group unsubstituted or substituted with at least one R₁₀ₐ or a C₁-C₆₀ heteroaryl group unsubstituted or substituted with at least one R₁₀ₐ. R₂₁ₑ and R₂₂ₑ may each independently be selected from among: a phenyl group; a pyridinyl group; a pyrimidinyl group; a triazinyl group; a pyrazinyl group; a thiophenyl group; and a furanyl group, each being unsubstituted or substituted with deuterium, —F, —Cl, —Br, —I, a cyano group, a C₁-C₁₀ alkyl group being unsubstituted, a C₁-C₁₀ alkyl group substituted with at least one deuterium, a C₁-C₁₀ alkyl group substituted with at least one —F, a C₁-C₁₀ alkyl group substituted with at least one —Cl, a C₁-C₁₀ alkyl group substituted with at least one-Br, a C₁-C₁₀ alkyl group substituted with at least one-I, a C₁-C₁₀ alkyl group substituted with at least one cyano group, or any combination thereof.

In one or more embodiments, in Formulae 2-1 and 2-2, X₂₃ to X₂₆ may each independently be O or S.

In one or more embodiments, the second compound may be one selected from among Compounds B1 to B24:

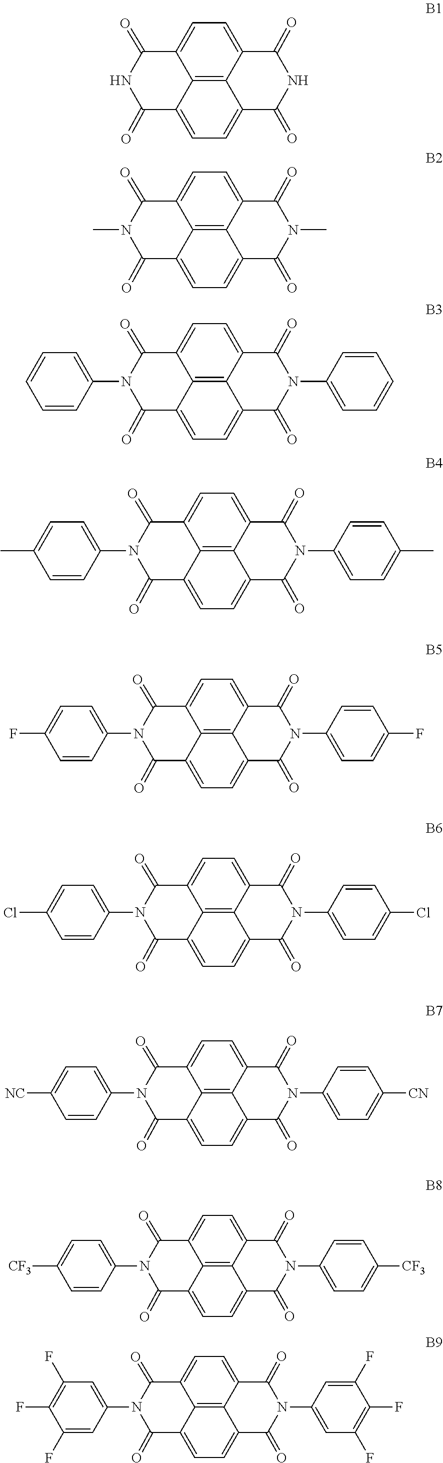

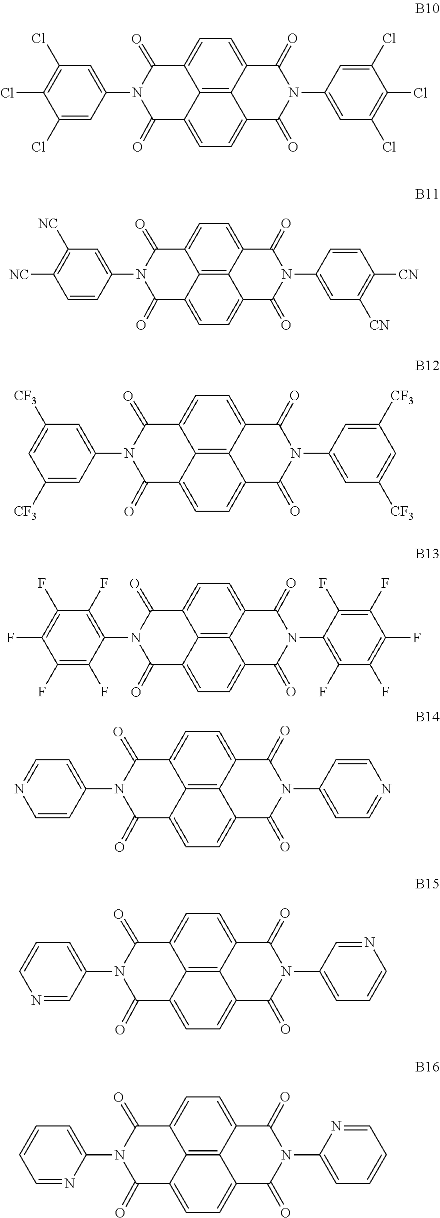

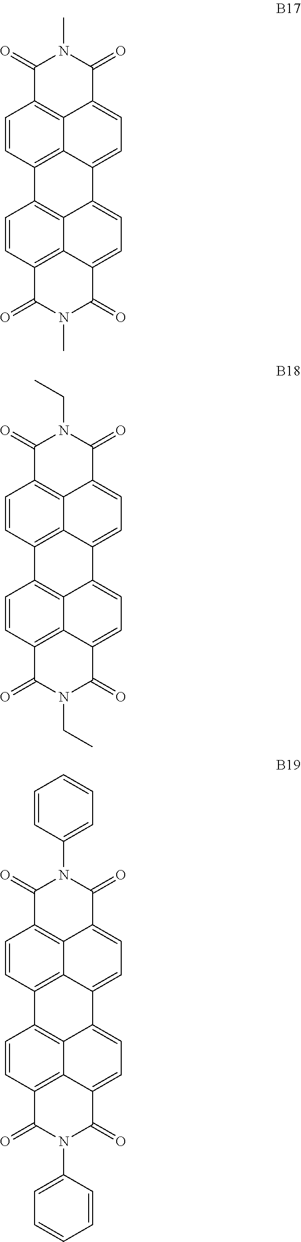

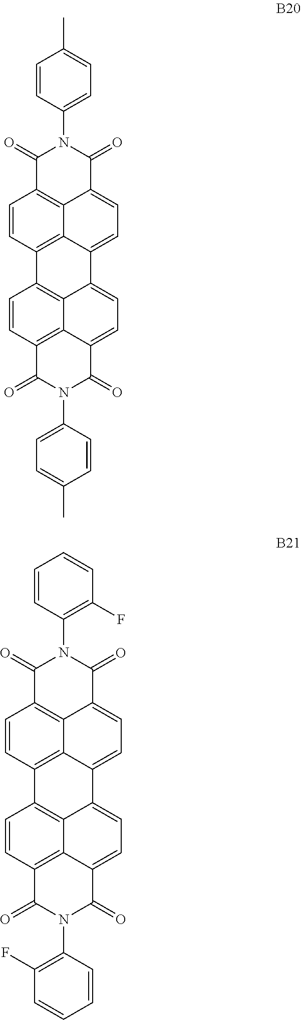

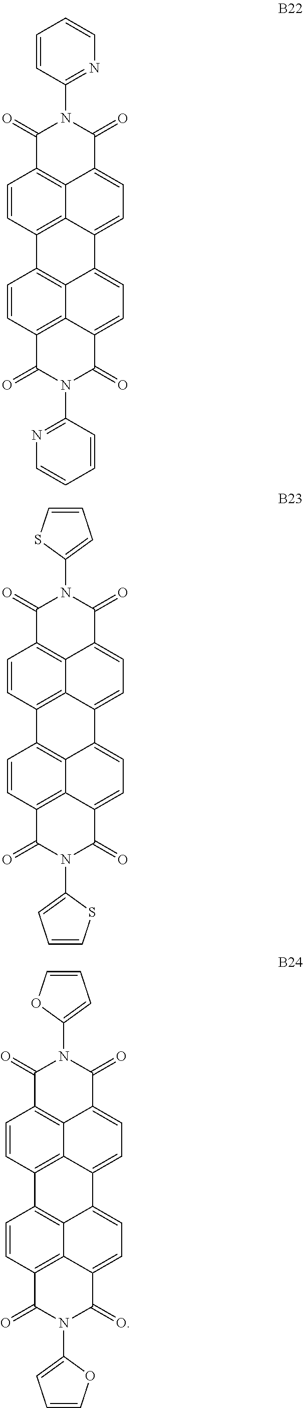

One or more embodiments of the present disclosure provide an electronic apparatus including the optoelectronic device.

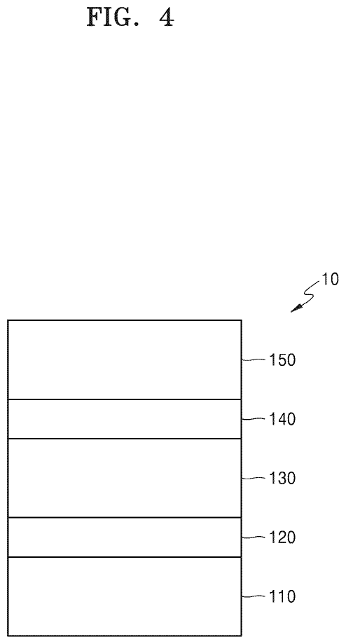

FIG. 4 is a schematic view of a light-emitting device 10 included in an electronic apparatus according to one or more embodiments.

Referring to FIG. 4, the light-emitting device 10 may include a first electrode 110, a hole transport region 120, an emission layer 130, an electron transport region 140, and a second electrode 150.

In one or more embodiments, the electronic apparatus may further include a light-emitting device 10 including an emission layer 130 that is between the first electrode 110 and the second electrode 150 and that does not overlap the photoactive layer 135.

The optoelectronic device may further include: a first hole transport region between the first electrode and the photoactive layer; and a first electron transport region between the photoactive layer and the second electrode.

The light-emitting device may further include: a second hole transport region between the first electrode and the emission layer; and a second electron transport region between the emission layer and the second electrode.

In one or more embodiments, the first hole transport region of the optoelectronic device and the second hole transport region of the light-emitting device may be a common layer. The first hole transport region and the second hole transport region may include substantially the same material and may be formed or provided substantially at the same time (e.g., concurrently).

In one or more embodiments, the first electron transport region of the optoelectronic device and the second electron transport region of the light-emitting device may be another common layer. The first electron transport region and the second electron transport region may include substantially the same material and may be formed or provided substantially at the same time (e.g., concurrently).

One or more embodiments of the present disclosure provide electronic equipment including the electronic apparatus, wherein the electronic equipment may be one selected from among a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality display, an augmented reality display, a vehicle, a video wall including a plurality of displays tiled together, a theater screen, a stadium screen, a phototherapy device, a signboard, a sensor for vehicles, a sensor for home, and a solar cell.

### First Electrode 110

In FIGS. 1 to 4, a substrate may be additionally arranged or provided under the first electrode 110 or on the second electrode 150. As the substrate, a glass substrate and/or a plastic substrate may be used. The substrate may be a flexible substrate. For example, the substrate may include plastics having excellent or suitable heat resistance and durability, such as polyimide, polyethylene terephthalate (PET), polycarbonate, polyethylene naphthalate, polyarylate (PAR), polyetherimide, or any combination thereof.

The first electrode 110 may be formed or provided by depositing and/or sputtering a material to form or provide the first electrode 110 on the substrate. If (e.g., when) the first electrode 110 is an anode, a material to form or provide the first electrode 110 may be a high-work function material that facilitates injection of holes.

The first electrode 110 may be a reflective electrode, a transflective electrode, or a transmissive electrode. If (e.g., when) the first electrode 110 is a transmissive electrode, a material to form or provide the first electrode 110 may include indium tin oxide (ITO), indium zinc oxide (IZO), tin oxide (e.g., SnO₂), zinc oxide (e.g., ZnO), or any combination thereof. In one or more embodiments, if (e.g., when) the first electrode 110 is a transflective electrode or a reflective electrode, a material to form or provide the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a single-layer structure or a multi-layer structure. For example, the first electrode 110 may have a three-layer structure of ITO/Ag/ITO.

### Hole Transport Region 120

The hole transport region 120 may have i) a single-layer structure consisting of (e.g., including) a single material, ii) a single-layer structure including a plurality of different materials, or iii) a multi-layer structure including a plurality of different materials.

The hole transport region 120 may include a hole injection layer, a hole transport layer, an emission auxiliary layer, an electron-blocking layer, or any combination thereof.

In one or more embodiments, the hole transport region 120 may have a multi-layer structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron-blocking layer structure, wherein the constituent layers of each structure are stacked sequentially from the first electrode 110.

The hole transport region 120 may include a compound represented by Formula 201, a compound represented by Formula 202, or any combination thereof:

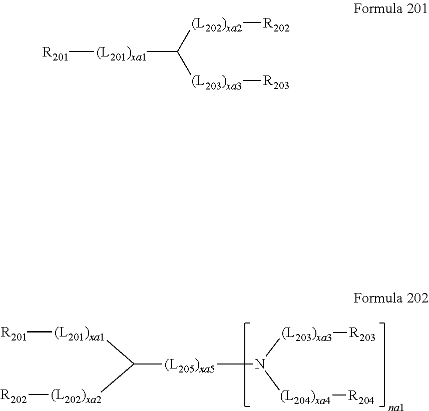

wherein, in Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer of 0 to 5,
xa5 may be an integer of 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other via a single bond (e.g., a single covalent bond), a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group (e.g., a carbazole group and/or the like) unsubstituted or substituted with at least one R₁₀ₐ (e.g., Compound HT16 and/or the like),
R₂₀₃ and R₂₀₄ may optionally be linked to each other via a single bond (e.g., a single covalent bond), a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer of 1 to 4.

In one or more embodiments, each of Formulae 201 and 202 may include at least one selected from among the groups represented by Formulae CY201 to CY217:

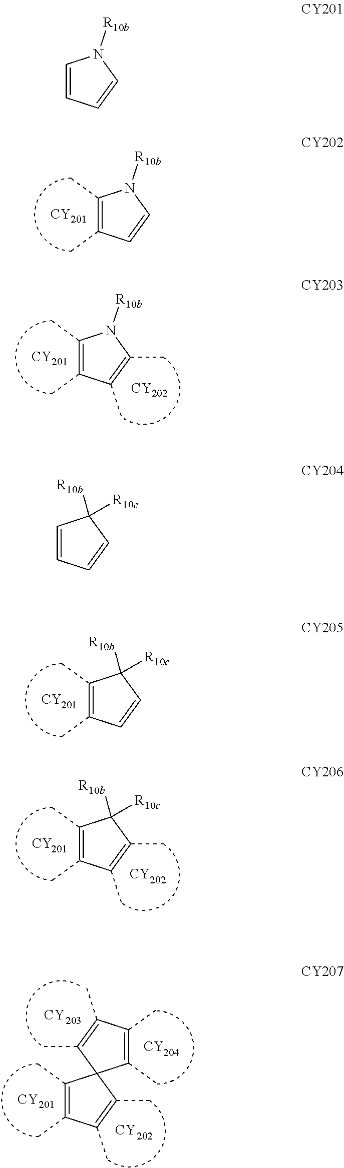

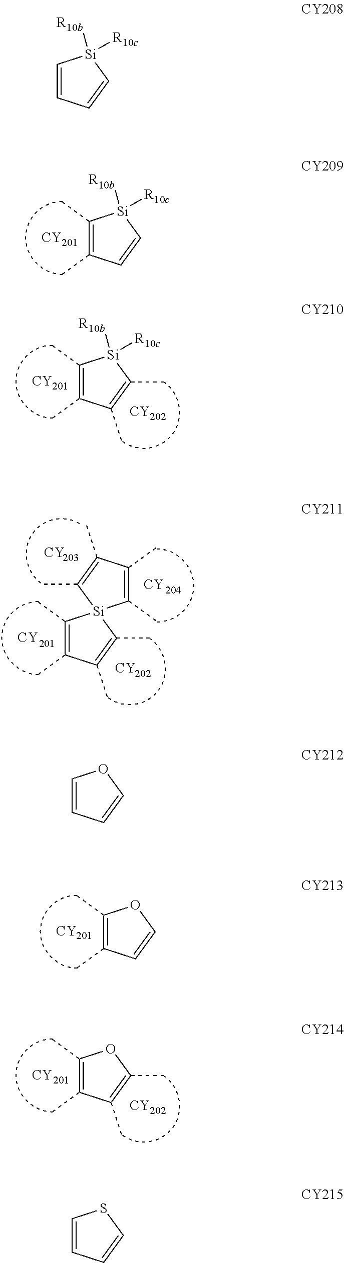

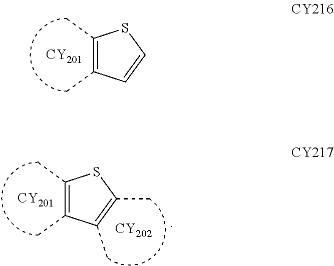

In Formulae CY201 to CY217, R_{10b} and R_{10c} may each be the same as defined with respect to R₁₀ₐ, ring CY201 to ring CY204 may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

In one or more embodiments, in Formulae CY201 to CY217, ring CY201 to ring CY204 may each independently be a benzene group, a naphthalene group, a phenanthrene group, or an anthracene group.

In one or more embodiments, each of Formulae 201 and 202 may include at least one selected from among the groups represented by Formulae CY201 to CY203.

In one or more embodiments, Formula 201 may include at least one selected from among the groups represented by Formulae CY201 to CY203 and at least one selected from among the groups represented by Formulae CY204 to CY217.

In one or more embodiments, in Formula 201, xa1 may be 1, R₂₀₁ may be a group represented by one selected from among Formulae CY201 to CY203, xa2 may be 0, and R₂₀₂ may be a group represented by one selected from among Formulae CY204 to CY207.

In one or more embodiments, each of Formulae 201 and 202 may not include the groups represented by Formulae CY201 to CY203.

In one or more embodiments, each of Formulae 201 and 202 may not include the groups represented by Formulae CY201 to CY203 and may include at least one selected from among the groups represented by Formulae CY204 to CY217.

In one or more embodiments, each of Formulae 201 and 202 may not include the groups represented by Formulae CY201 to CY217.

In one or more embodiments, the hole transport region 120 may include: one selected from among Compounds HT1 to HT46; m-MTDATA; TDATA; 2-TNATA; NPB(NPD); β-NPB; TPD; spiro-TPD; spiro-NPB; methylated NPB; TAPC; HMTPD; 4,4′,4″-tris(N-carbazolyl)triphenylamine (TCTA); polyaniline/dodecylbenzenesulfonic acid (PANI/DBSA); poly(3,4-ethylenedioxythiophene)/poly(4-styrenesulfonate) (PEDOT/PSS); polyaniline/camphor sulfonic acid (PANI/CSA); polyaniline/poly(4-styrenesulfonate) (PANI/PSS); or any combination thereof:

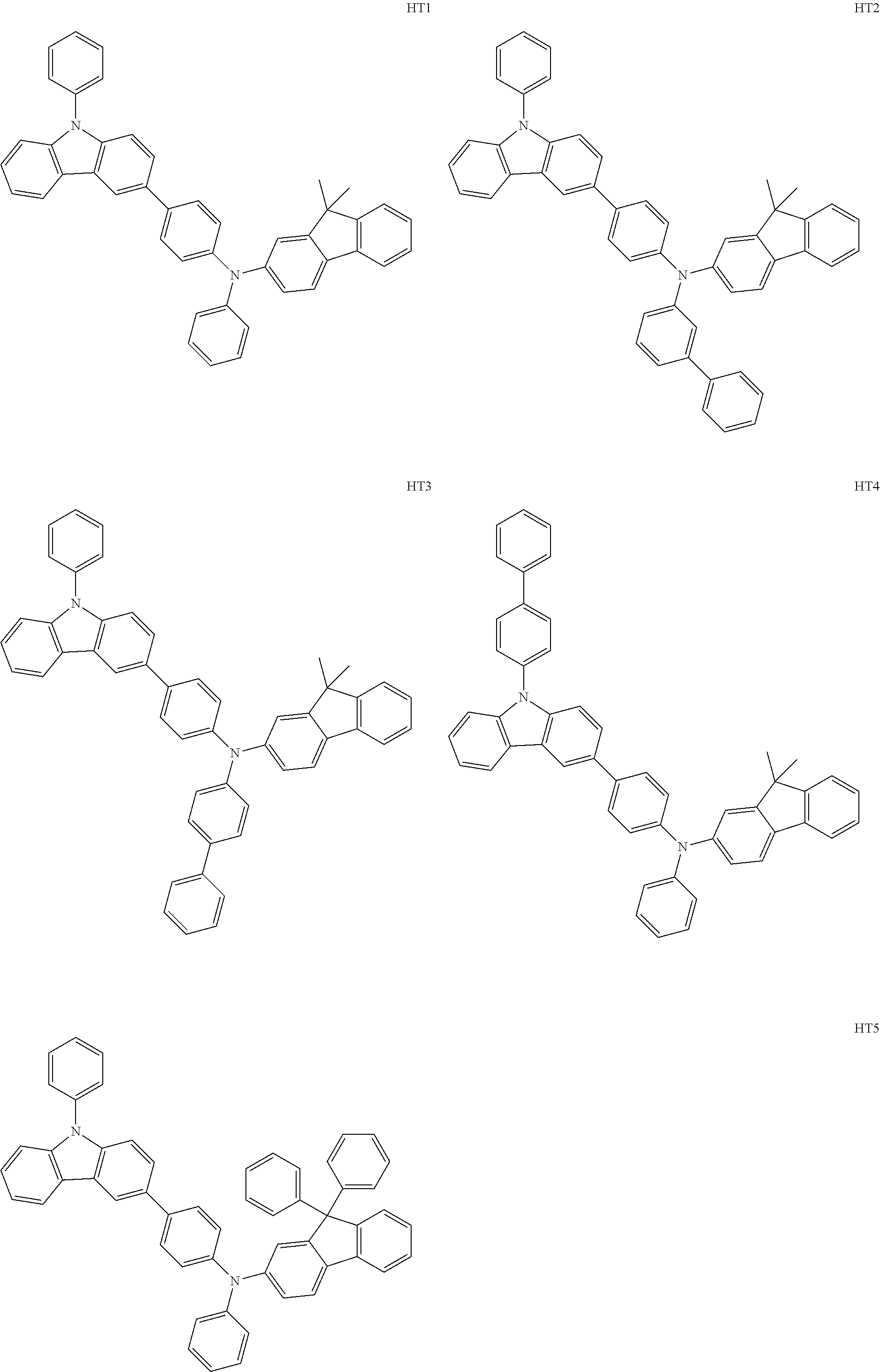

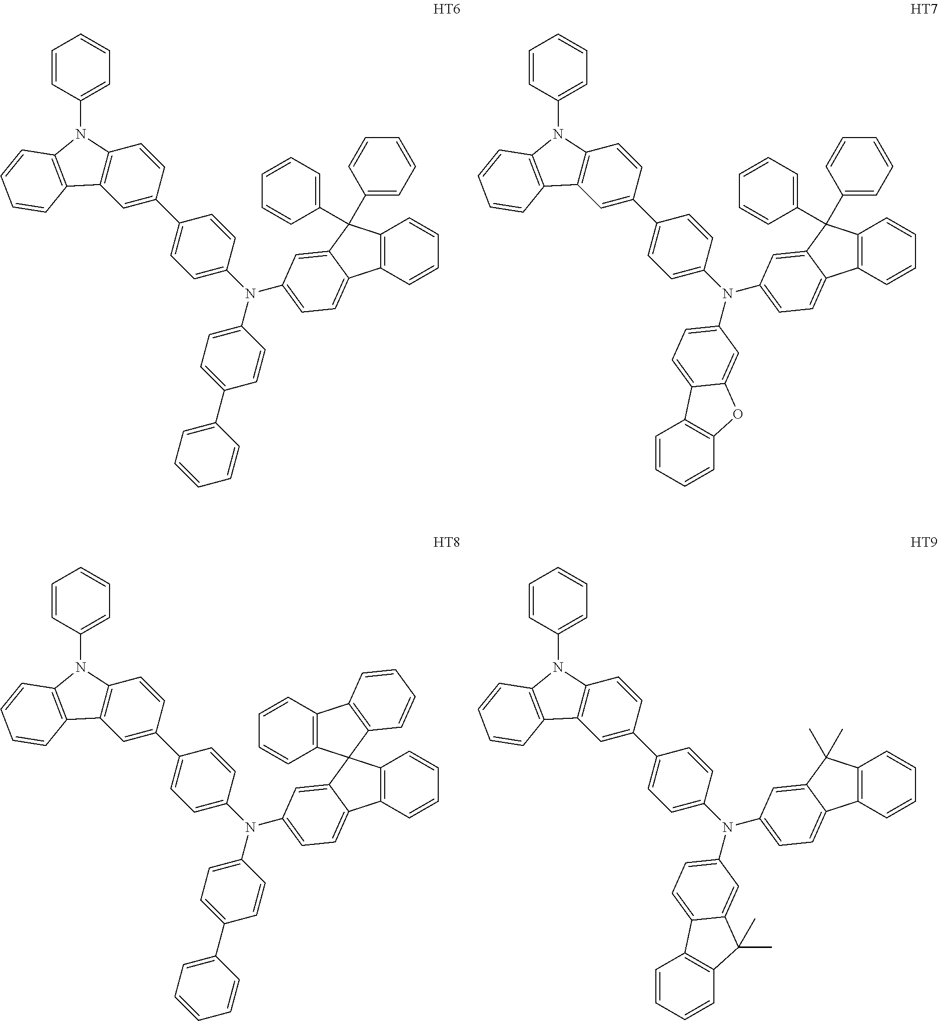 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

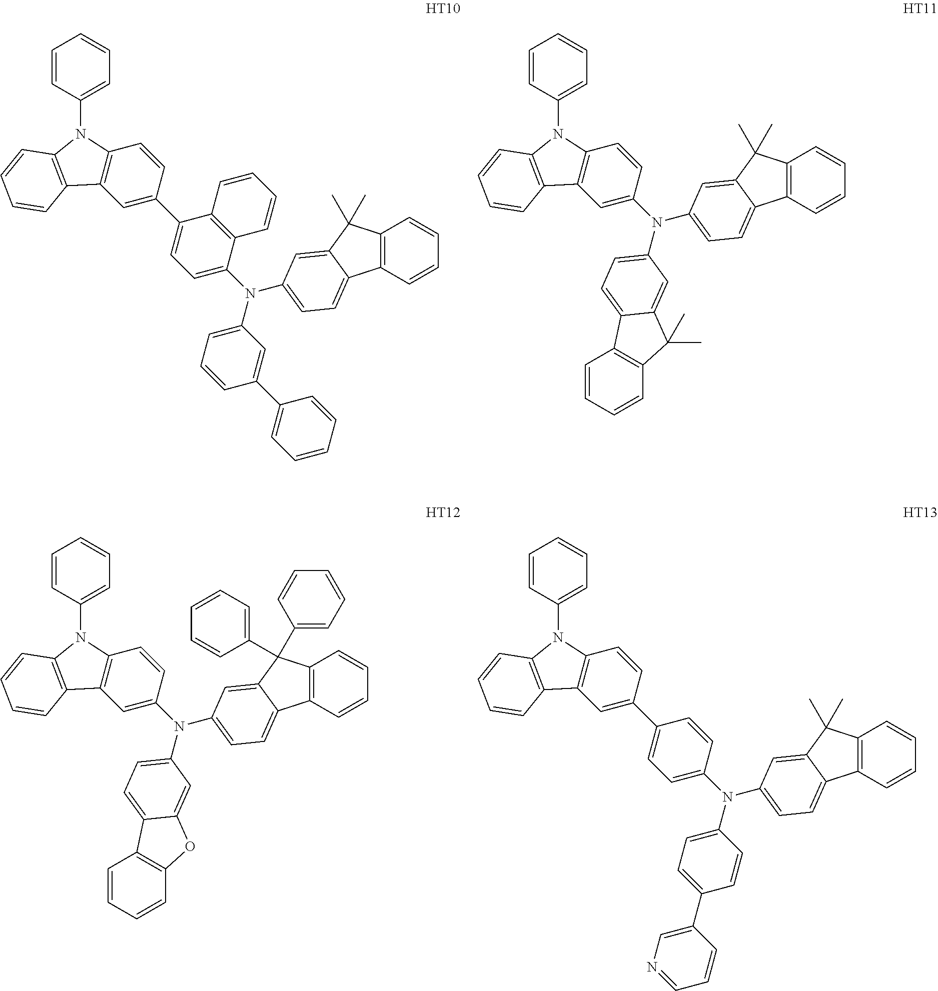 [SMILES: CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1 ; CC1(C)c2ccccc2-c2ccc(N(c3ccc(-c4cccnc4)cc3)c3ccc(-c4ccc5c(c4)c4ccccc4n5-c4ccccc4)cc3)cc21]

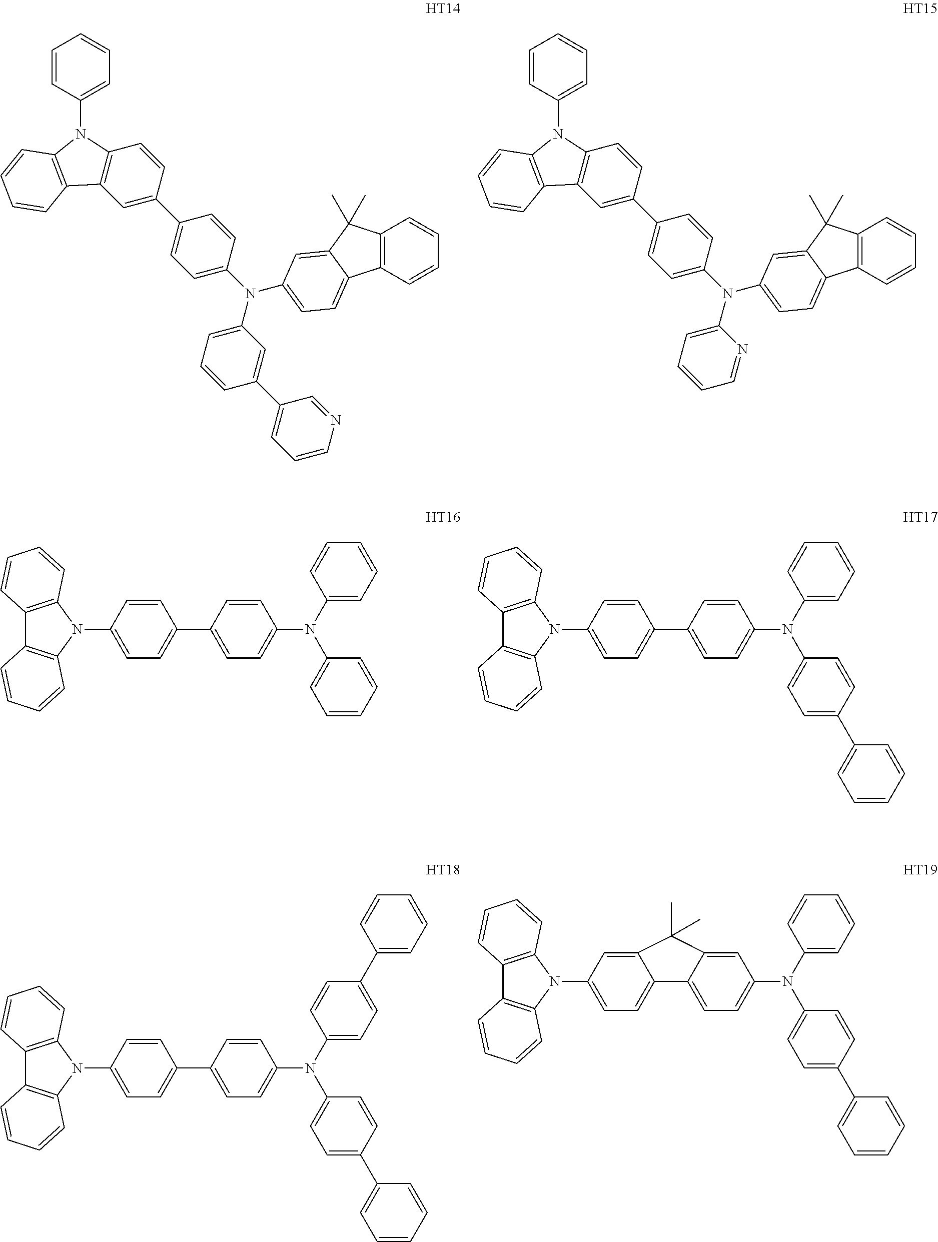 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2cc(N(c3ccccc3)c3ccc(-c4ccccc4)cc3)ccc2-c2ccc(-n3c4ccccc4c4ccccc43)cc21]

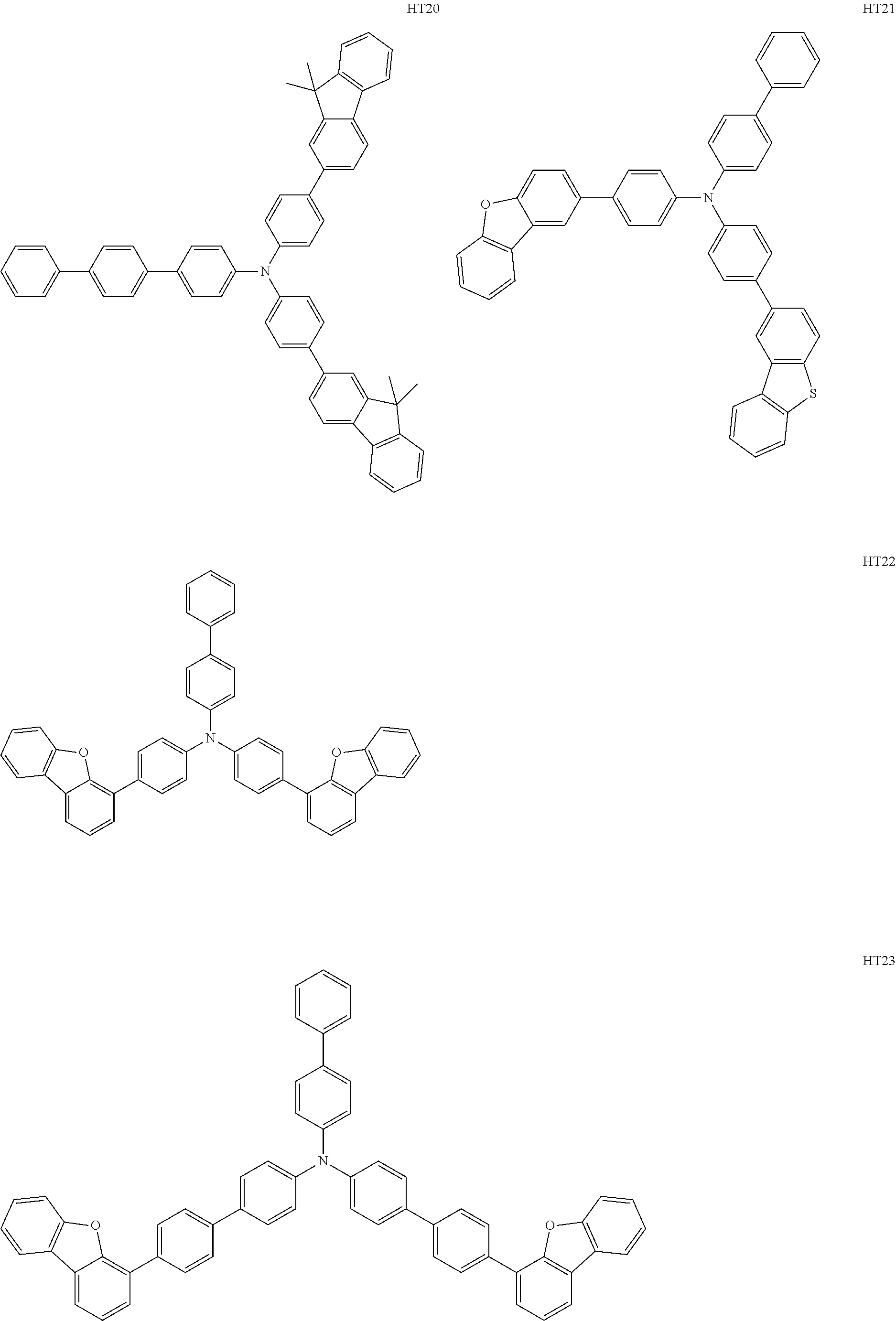 [SMILES: CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

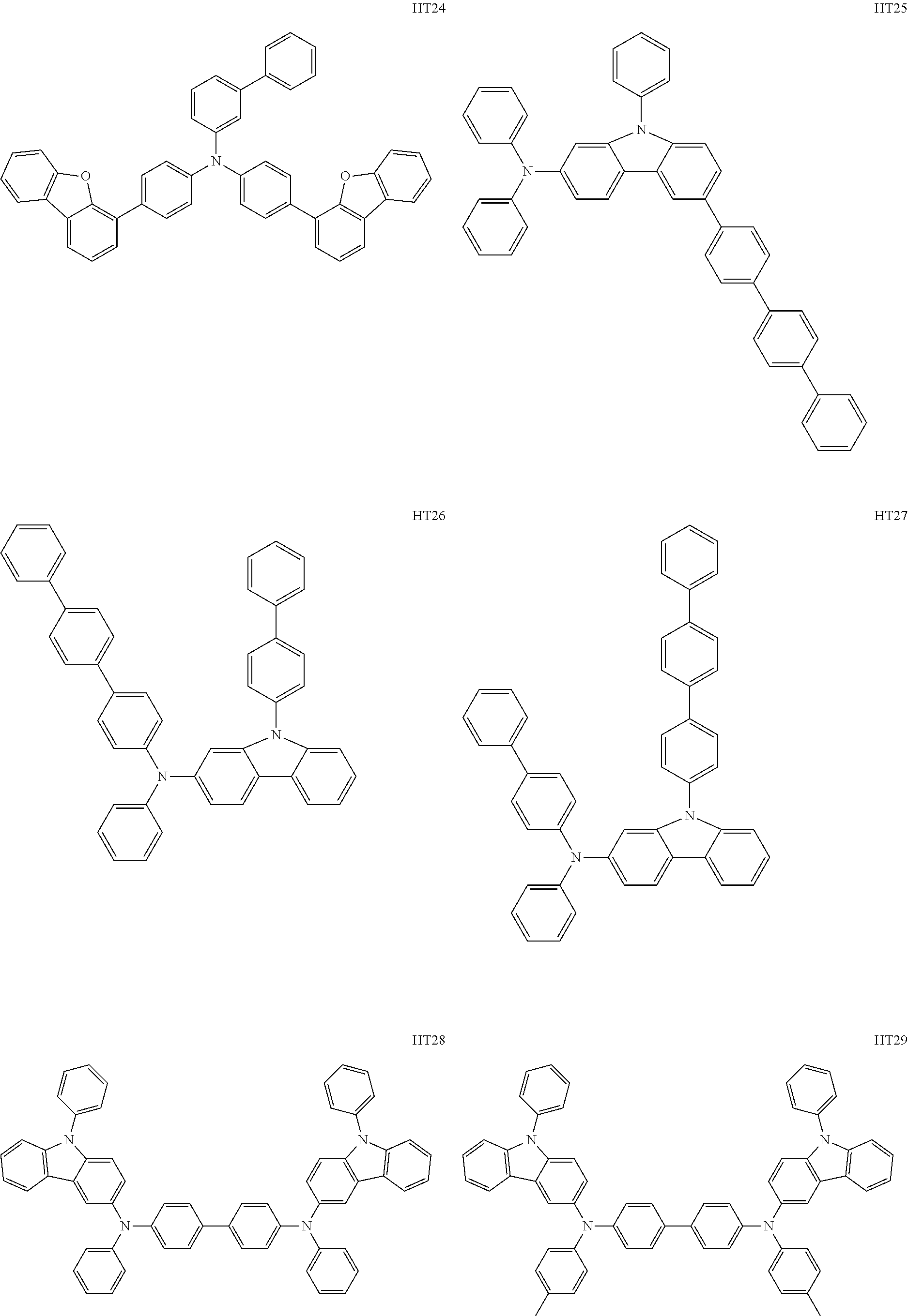

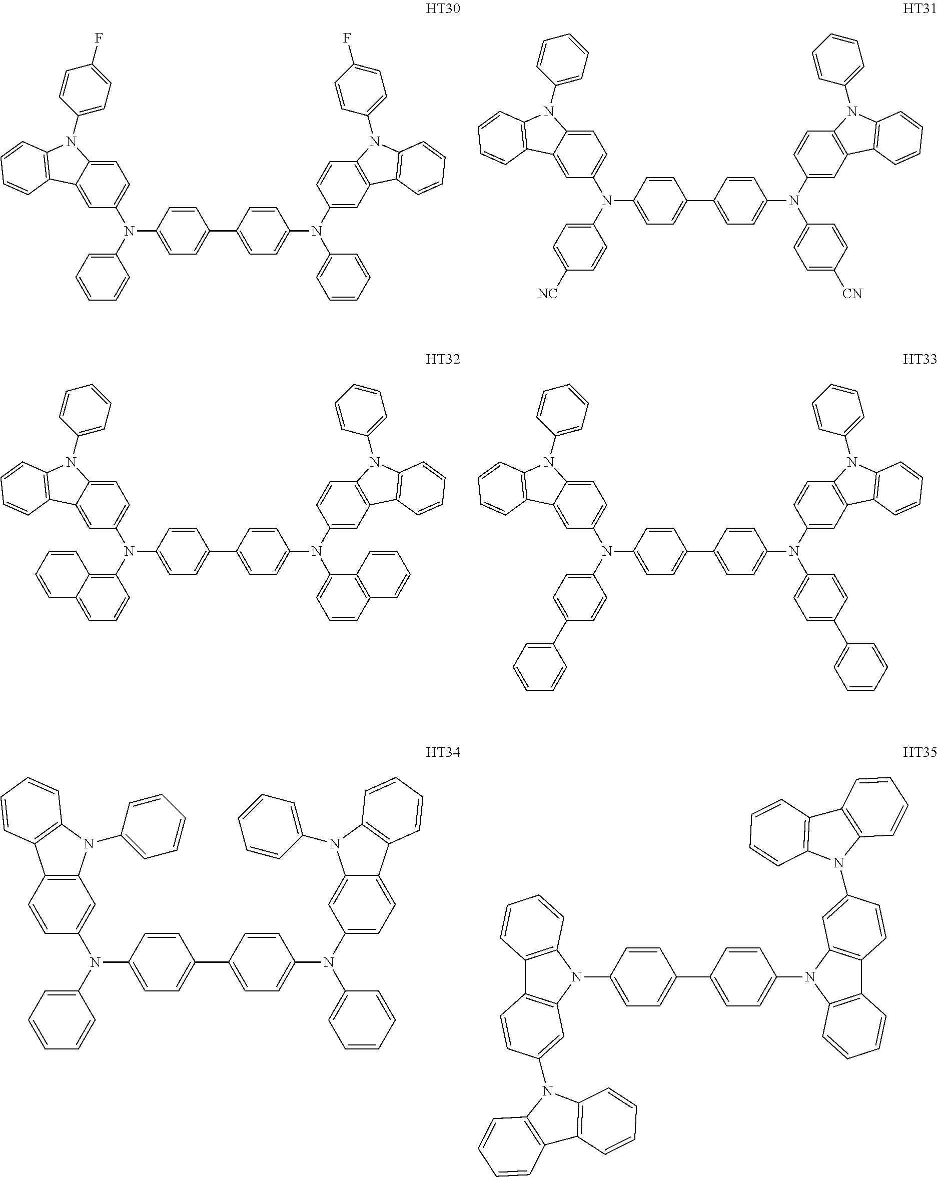

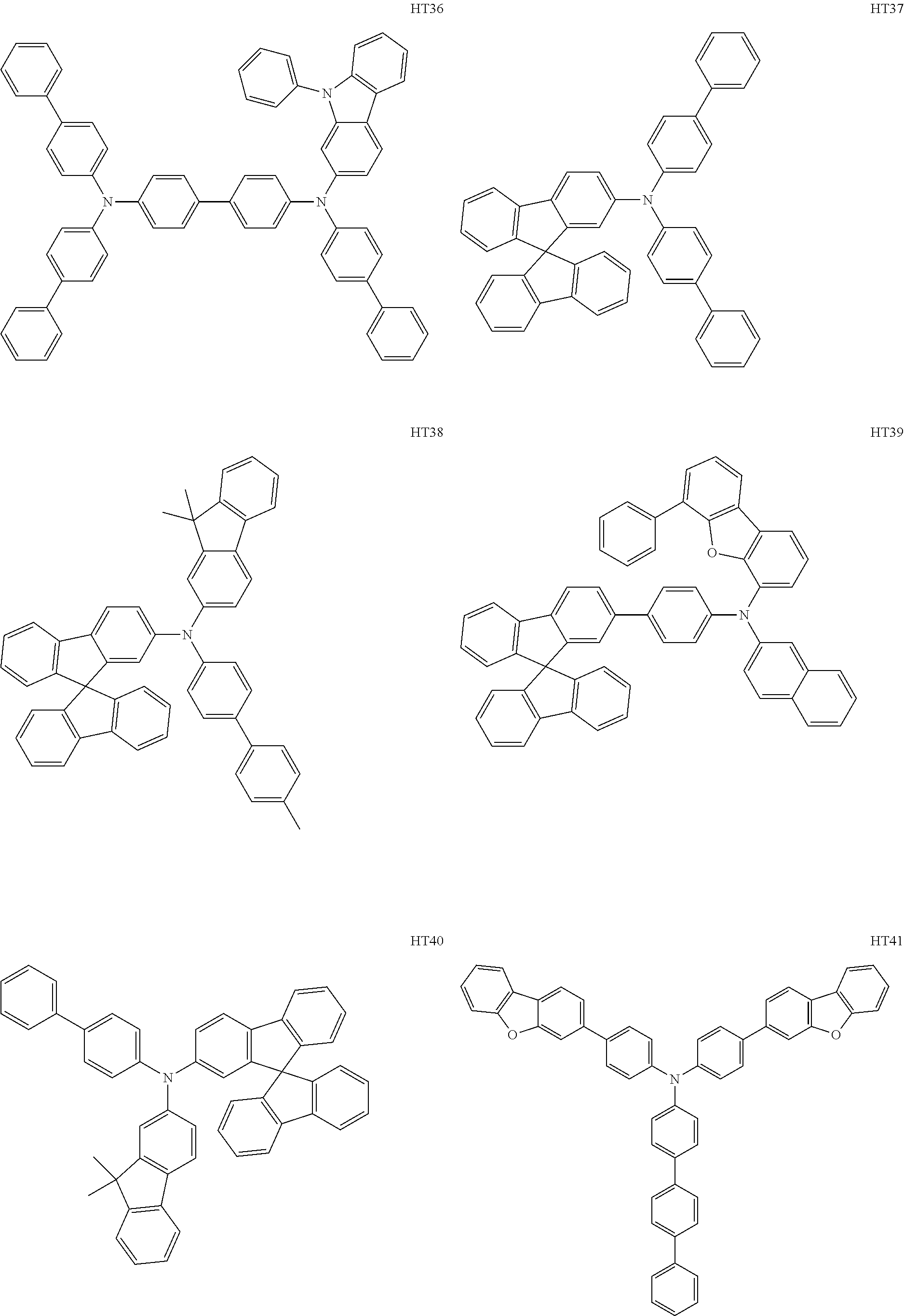

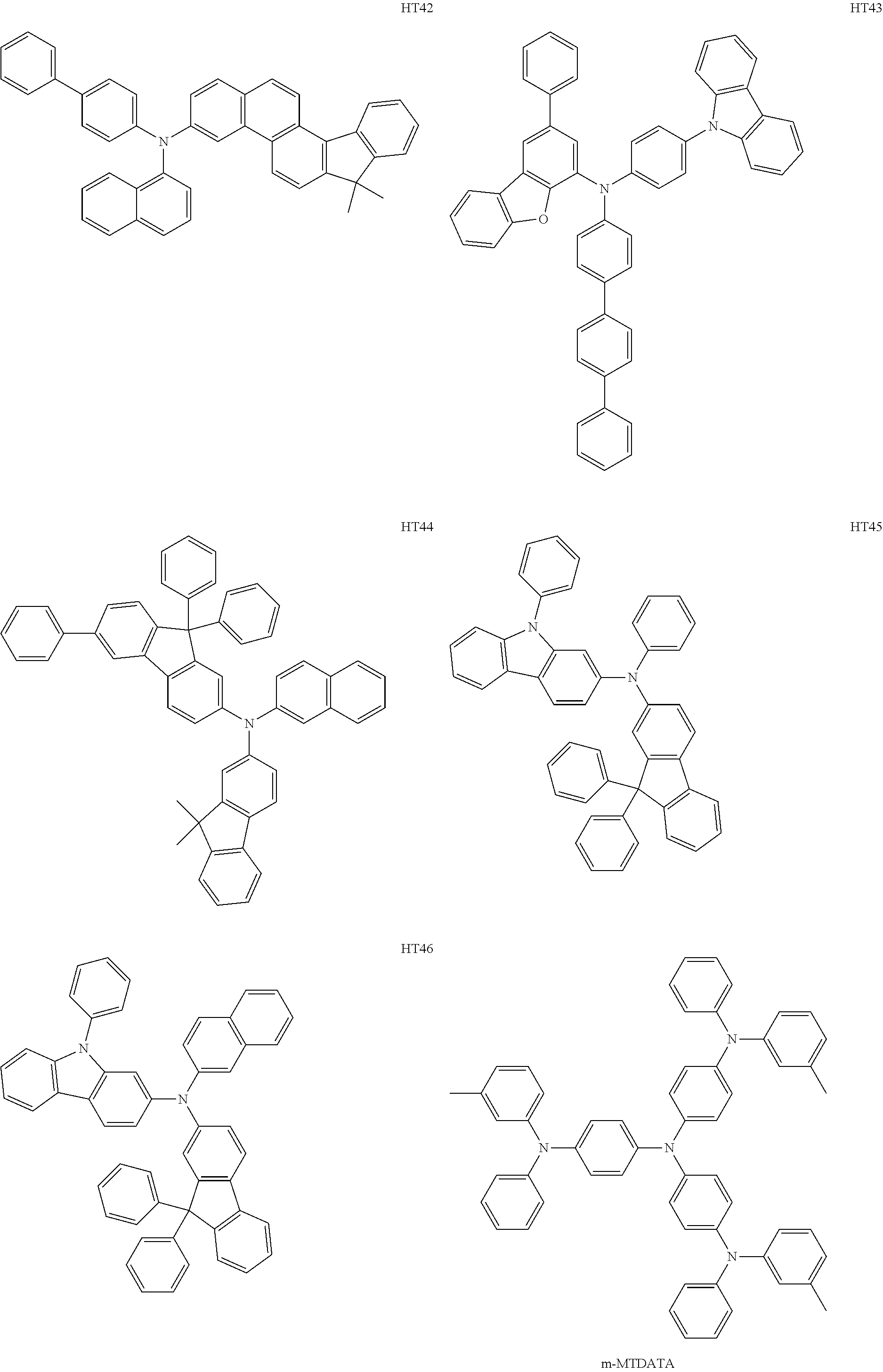

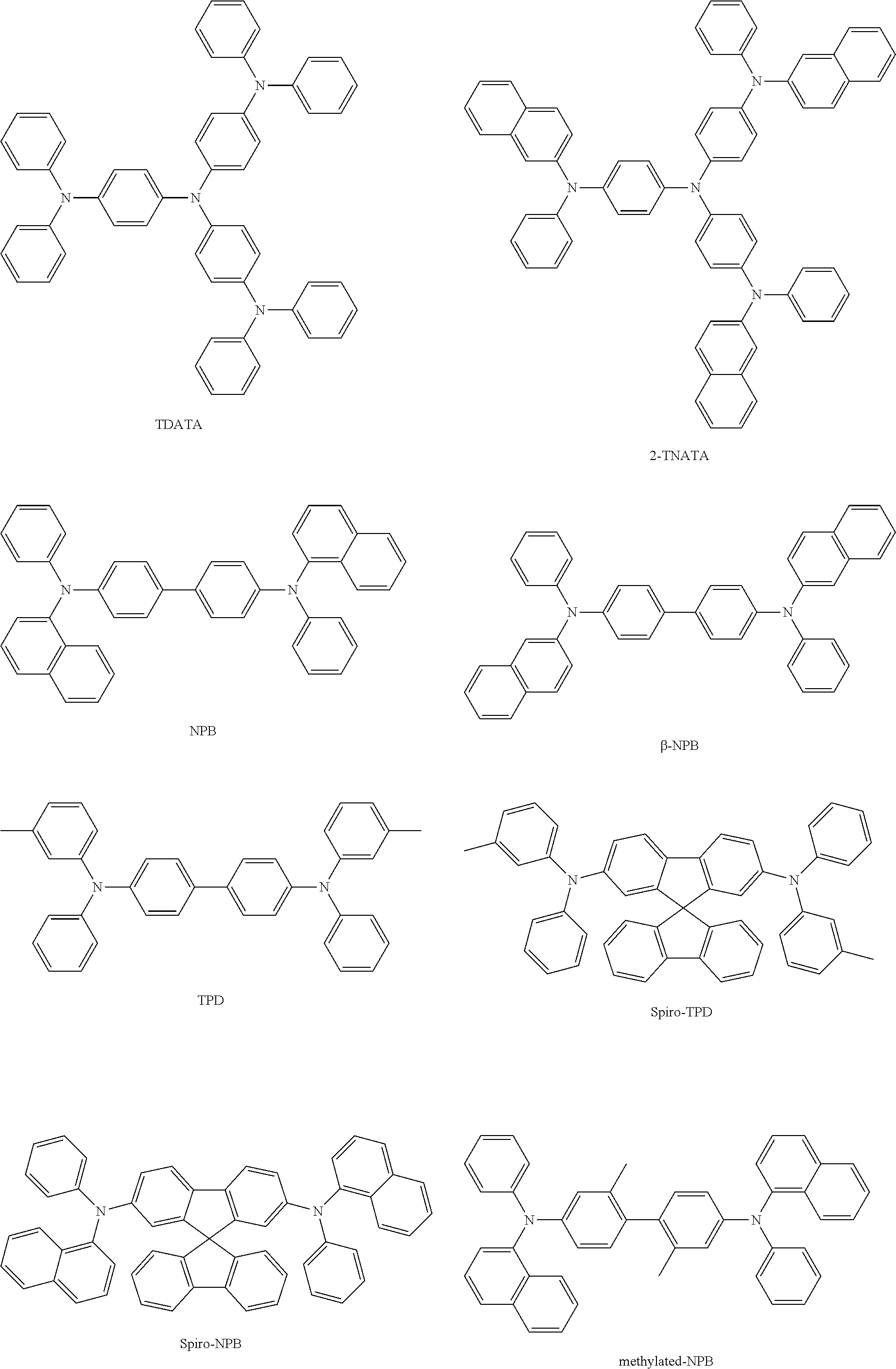

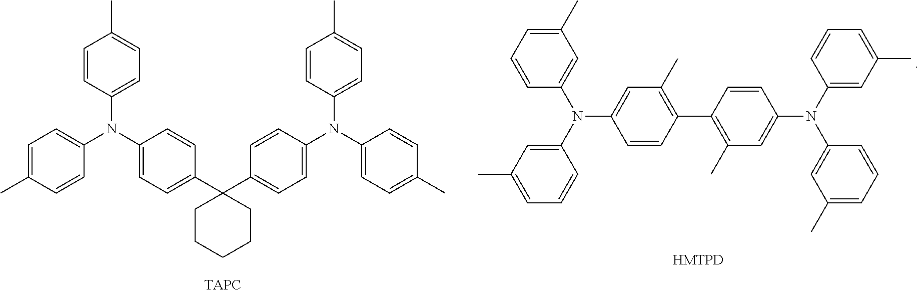

The thickness of the hole transport region 120 may be in a range of about 50 Å to about 10,000 Å, for example, about 100 Å to about 4,000 Å. If (e.g., when) the hole transport region 120 includes a hole injection layer, a hole transport layer, or any combination thereof, the thickness of the hole injection layer may be in a range of about 30 Å to about 9,000 Å, for example, about 100 Å to about 1,000 Å, and the thickness of the hole transport layer may be in a range of about 50 Å to about 2,000 Å, for example, about 100 Å to about 1,500 Å. If (e.g., when) the thicknesses of the hole transport region 120, the hole injection layer, and the hole transport layer are within the foregoing ranges, satisfactory hole-transporting characteristics may be obtained without a substantial increase in driving voltage.

The emission auxiliary layer may increase or enhance light-emission efficiency by compensating for an optical resonance distance according to the wavelength of light emitted by the emission layer 130, and the electron-blocking layer may block the leakage of electrons from the emission layer 130 to the hole transport region 120 (or reduce a degree to or occurrence of which electrons leak from the emission layer 130 to the hole transport region 120). Materials that may be included in the hole transport region 120 may be included in the emission auxiliary layer and the electron-blocking layer.

p-Dopant

The hole transport region 120 may include, in addition to the materials as described in one or more embodiments, a charge-generation material for the improvement or enhancement of conductive (e.g., electrically conductive) properties. The charge-generation material may be uniformly (e.g., substantially uniformly) or non-uniformly dispersed in the hole transport region 120 (e.g., in the form of a single layer consisting of (e.g., including) a charge-generation material).

The charge-generation material may be, for example, a p-dopant.

In one or more embodiments, the LUMO energy level of the p-dopant may be about −3.5 eV or less.

In a layer including the p-dopant in the hole transport region 120, the amount of the p-dopant may be in a range of about 0.1 vol % to about 10 vol %, for example, about 0.5 vol % to about 5 vol %.

In one or more embodiments, the p-dopant may include a quinone derivative, a cyano group-containing compound, a compound including an element EL1 and an element EL2, or any combination thereof.

Examples of the quinone derivative may include TCNQ, F4-TCNQ, and/or the like.

Examples of the cyano group-containing compound may include HAT-CN, a compound represented by Formula 221, and/or the like:

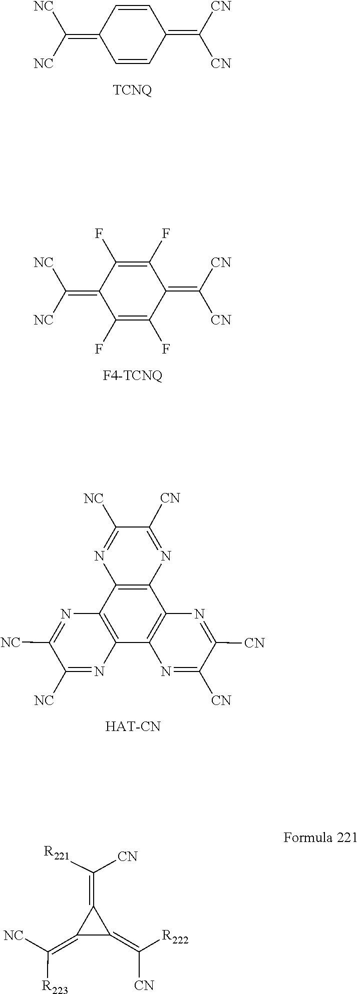

wherein, in Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one selected from among R₂₂₁ to R₂₂₃ may each independently be a C₃-C₆₀ carbocyclic group or a C₁-C₆₀ heterocyclic group, each being unsubstituted or substituted with: a cyano group; —F; —Cl; —Br; —I; a C₁-C₂₀ alkyl group unsubstituted or substituted with a cyano group, —F, —Cl, —Br, —I, or any combination thereof; or any combination thereof.

In the compound including the element EL1 and the element EL2, the element EL1 may be a metal, a metalloid, or a combination thereof, and the element EL2 may be a non-metal, a metalloid, or a combination thereof.

Examples of the metal may include: an alkali metal (e.g., lithium (Li), sodium (Na), potassium (K), rubidium (Rb), cesium (Cs), and/or the like); an alkaline earth metal (e.g., beryllium (Be), magnesium (Mg), calcium (Ca), strontium (Sr), barium (Ba), and/or the like); a transition metal (e.g., titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), and/or the like); a post-transition metal (e.g., zinc (Zn), indium (In), tin (Sn), and/or the like); a lanthanide metal (e.g., lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and/or the like); and/or the like.

Examples of the metalloid may include silicon (Si), antimony (Sb), tellurium (Te), and/or the like.

Examples of the non-metal may include oxygen (O), a halogen (e.g., F, Cl, Br, I, and/or the like), and/or the like.

Examples of the compound including the element EL1 and the element EL2 may include a metal oxide, a metal halide (e.g., a metal fluoride, a metal chloride, a metal bromide, a metal iodide, and/or the like), a metalloid halide (e.g., a metalloid fluoride, a metalloid chloride, a metalloid bromide, a metalloid iodide, and/or the like), a metal telluride, or any combination thereof.

Examples of the metal oxide may include a tungsten oxide (e.g., WO, W₂O₃, WO₂, WO₃, W₂O₅, and/or the like), a vanadium oxide (e.g., VO, V₂O₃, VO₂, V₂O₅, and/or the like), a molybdenum oxide (e.g., MoO, Mo₂O₃, MoO₂, MoO₃, Mo₂O₅, and/or the like), a rhenium oxide (e.g., ReO₃ and/or the like), and/or the like.

Examples of the metal halide may include an alkali metal halide, an alkaline earth metal halide, a transition metal halide, a post-transition metal halide, a lanthanide metal halide, and/or the like.

Examples of the alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, CsI, and/or the like.

Examples of the alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, BaI₂, and/or the like.

Examples of the transition metal halide may include a titanium halide (e.g., TiF₄, TiCl₄, TiBr₄, TiI₄, and/or the like), a zirconium halide (e.g., ZrF₄, ZrCl₄, ZrBr₄, ZrI₄, and/or the like), a hafnium halide (e.g., HfF₄, HfCl₄, HfBr₄, HfI₄, and/or the like), a vanadium halide (e.g., VF₃, VCl₃, VBr₃, VI₃, and/or the like), a niobium halide (e.g., NbF₃, NbCl₃, NbBr₃, NbI₃, and/or the like), a tantalum halide (e.g., TaF₃, TaCl₃, TaBr₃, TaI₃, and/or the like), a chromium halide (e.g., CrF₃, CrCl₃, CrBr₃, CrI₃, and/or the like), a molybdenum halide (e.g., MoF₃, MoCl₃, MoBr₃, MoI₃, and/or the like), a tungsten halide (e.g., WF₃, WCl₃, WBr₃, WI₃, and/or the like), a manganese halide (e.g., MnF₂, MnCl₂, MnBr₂, MnI₂, and/or the like), a technetium halide (e.g., TcF₂, TcCl₂, TcBr₂, TcI₂, and/or the like), a rhenium halide (e.g., ReF₂, ReCl₂, ReBr₂, ReI₂, and/or the like), an iron halide (e.g., FeF₂, FeCl₂, FeBr₂, FeI₂, and/or the like), a ruthenium halide (e.g., RuF₂, RuCl₂, RuBr₂, RuI₂, and/or the like), an osmium halide (e.g., OsF₂, OsCl₂, OsBr₂, OsI₂, and/or the like), a cobalt halide (e.g., CoF₂, CoCl₂, CoBr₂, CoI₂, and/or the like), a rhodium halide (e.g., RhF₂, RhCl₂, RhBr₂, RhI₂, and/or the like), an iridium halide (e.g., IrF₂, IrCl₂, IrBr₂, IrI₂, and/or the like), a nickel halide (e.g., NiF₂, NiCl₂, NiBr₂, NiI₂, and/or the like), a palladium halide (e.g., PdF₂, PdCl₂, PdBr₂, PdI₂, and/or the like), a platinum halide (e.g., PtF₂, PtCl₂, PtBr₂, PtI₂, and/or the like), a copper halide (e.g., CuF, CuCl, CuBr, CuI, and/or the like), a silver halide (e.g., AgF, AgCl, AgBr, AgI, and/or the like), a gold halide (e.g., AuF, AuCl, AuBr, AuI, and/or the like), and/or the like.

Examples of the post-transition metal halide may include a zinc halide (e.g., ZnF₂, ZnCl₂, ZnBr₂, ZnI₂, and/or the like), an indium halide (e.g., InI₃ and/or the like), a tin halide (e.g., SnI₂ and/or the like), and/or the like.

Examples of the lanthanide metal halide may include YbF, YbF₂, YbF₃, SmF₃, YbCl, YbCl₂, YbCl₃, SmCl₃, YbBr, YbBr₂, YbBr₃, SmBr₃, YbI, YbI₂, YbI₃, SmI₃, and/or the like.

Examples of the metalloid halide may include an antimony halide (e.g., SbCl₅ and/or the like) and/or the like.

Examples of the metal telluride may include an alkali metal telluride (e.g., Li₂Te, Na₂Te, K₂Te, Rb₂Te, Cs₂Te, and/or the like), an alkaline earth metal telluride (e.g., BeTe, MgTe, CaTe, SrTe, BaTe, and/or the like), a transition metal telluride (e.g., TiTe₂, ZrTe₂, HfTe₂, V₂Te₃, Nb₂Te₃, Ta₂Te₅, Cr₂Te₃, Mo₂Te₅, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, and/or the like), a post-transition metal telluride (e.g., ZnTe and/or the like), a lanthanide metal telluride (e.g., LaTe, CeTe, PrTe, NdTe, PmTe, EuTe, GdTe, TbTe, DyTe, HoTe, ErTe, TmTe, YbTe, LuTe, and/or the like), and/or the like.

### Emission Layer 130

The light-emitting device 10 may include an emission layer 130 on the hole transport region 120.

The emission layer 130 may further include, in addition to one or more suitable organic materials, a metal-containing compound, such as an organometallic compound, an inorganic material, such as quantum dots, and/or the like.

In one or more embodiments, the emission layer 130 may include i) two or more emitting units sequentially stacked between the first electrode 110 and the second electrode 150, and ii) a charge generation layer between adjacent emitting units among the two or more emitting units. If (e.g., when) the emission layer 130 includes the emitting units and the charge generation layer as described in one or more embodiments, the light-emitting device 10 may be a tandem light-emitting device.

If (e.g., when) the light-emitting device 10 is a full-color light-emitting device, the emission layer 130 may be patterned into a red emission layer, a green emission layer, and/or a blue emission layer, according to a subpixel. In one or more embodiments, the emission layer 130 may have a stacked structure of two or more layers selected from among a red emission layer, a green emission layer, and a blue emission layer, in which the two or more layers contact each other or are separated from each other, to emit white light. In one or more embodiments, the emission layer 130 may include two or more materials selected from among a red light-emitting material, a green light-emitting material, and a blue light-emitting material, in which the two or more materials are mixed with each other in a single layer, to emit white light.

The emission layer 130 may include a host and a dopant. The dopant may include a phosphorescent dopant, a fluorescent dopant, or any combination thereof.

The amount of the dopant in the emission layer 130 may be in a range of about 0.01 parts by weight to about 15 parts by weight based on 100 parts by weight of the host.

In one or more embodiments, the emission layer 130 may include quantum dots.

In one or more embodiments, the emission layer 130 may include a delayed fluorescence material. The delayed fluorescence material may act as a host or a dopant in the emission layer 130.

The thickness of the emission layer 130 may be in a range of about 100 Å to about 1,000 Å, for example, about 200 Å to about 600 Å. If (e.g., when) the thickness of the emission layer 130 is within the foregoing ranges, excellent or suitable luminescence characteristics may be obtained without a substantial increase in driving voltage.

### Host

The host may include a compound represented by Formula 301:

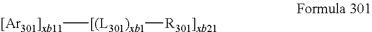

wherein, in Formula 301,
Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xb11 may be 1, 2, or 3,
xb1 may be an integer of 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer of 1 to 5, and
Q₃₀₁ to Q₃₀₃ may each be the same as defined with respect to Q₁.

In one or more embodiments, if (e.g., when) xb11 in Formula 301 is 2 or more, two or more of Ar₃₀₁ may be linked to each other via a single bond (e.g., a single covalent bond).

In one or more embodiments, the host may include a compound represented by Formula 301-1, a compound represented by Formula 301-2, or any combination thereof:

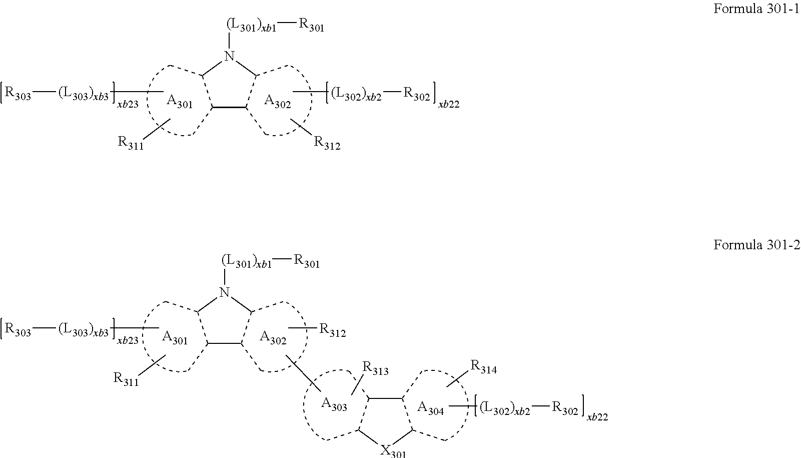

wherein, in Formulae 301-1 and 301-2,
ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N [(L₃₀₄) xb4-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ may each be the same as defined in one or more embodiments,
L₃₀₂ to L₃₀₄ may each independently be the same as defined with respect to L₃₀₁,
xb2 to xb4 may each independently be the same as defined with respect to xb1, and
R₃₀₂ to R₃₀₅ and R₃₁₁ to R₃₁₄ may each be the same as defined with respect to R₃₀₁.

In one or more embodiments, the host may include an alkaline earth metal complex, a post-transition metal complex, or any combination thereof. For example, the host may include a Be complex (e.g., Compound H55), a Mg complex, a Zn complex, or any combination thereof.

In one or more embodiments, the host may include: one selected from among Compounds H1 to H128; 9,10-di(2-naphthyl) anthracene (ADN); 2-methyl-9,10-bis(naphthalen-2-yl) anthracene (MADN); 9,10-di-(2-naphthyl)-2-t-butyl-anthracene (TBADN); 4,4′-bis(N-carbazolyl)-1,1′-biphenyl (CBP); 1,3-di(carbazol-9-yl)benzene (mCP); 1,3,5-tri (carbazol-9-yl)benzene (TCP); or any combination thereof:

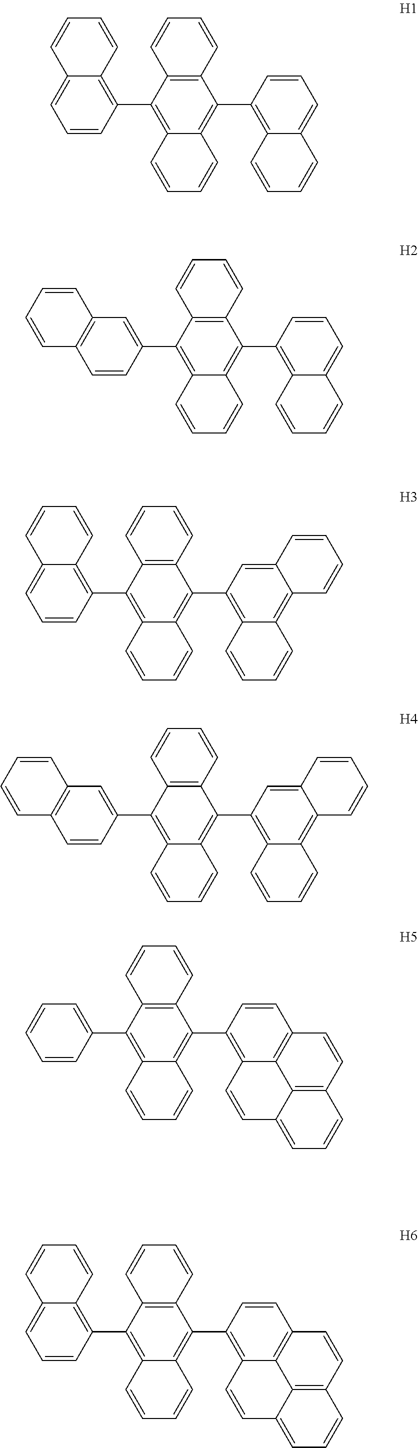

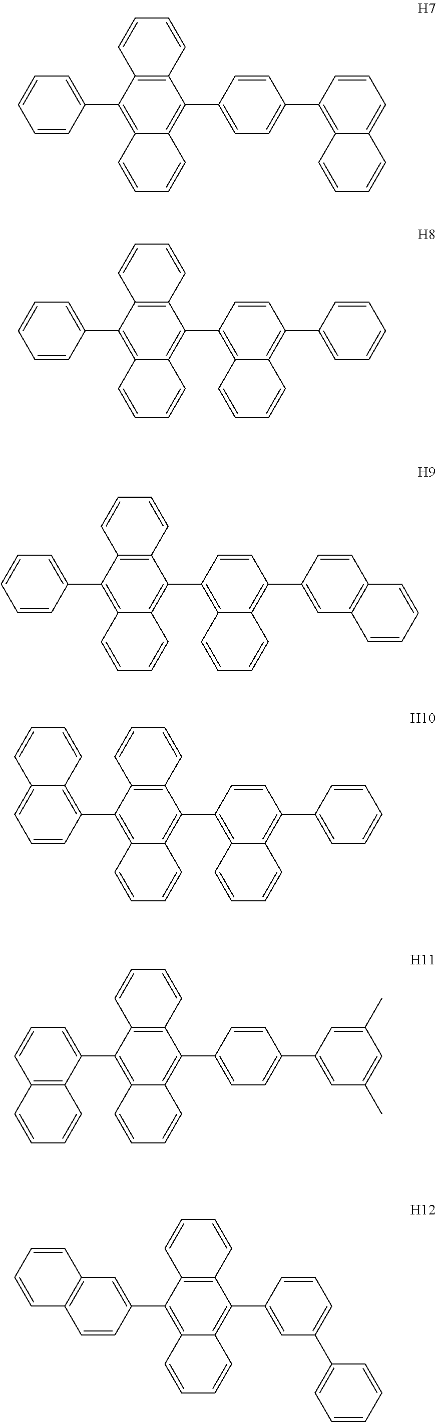

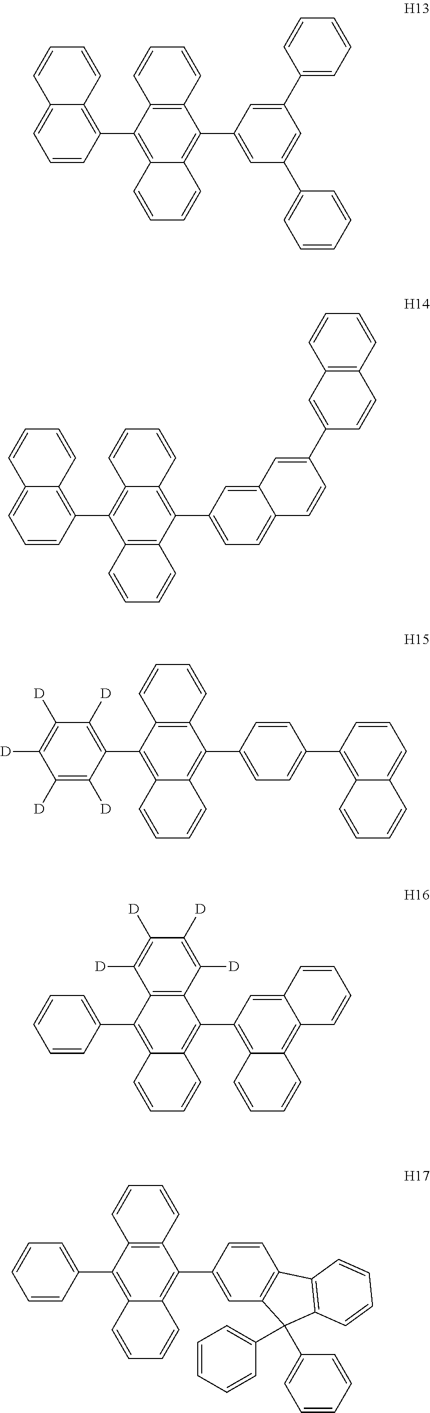

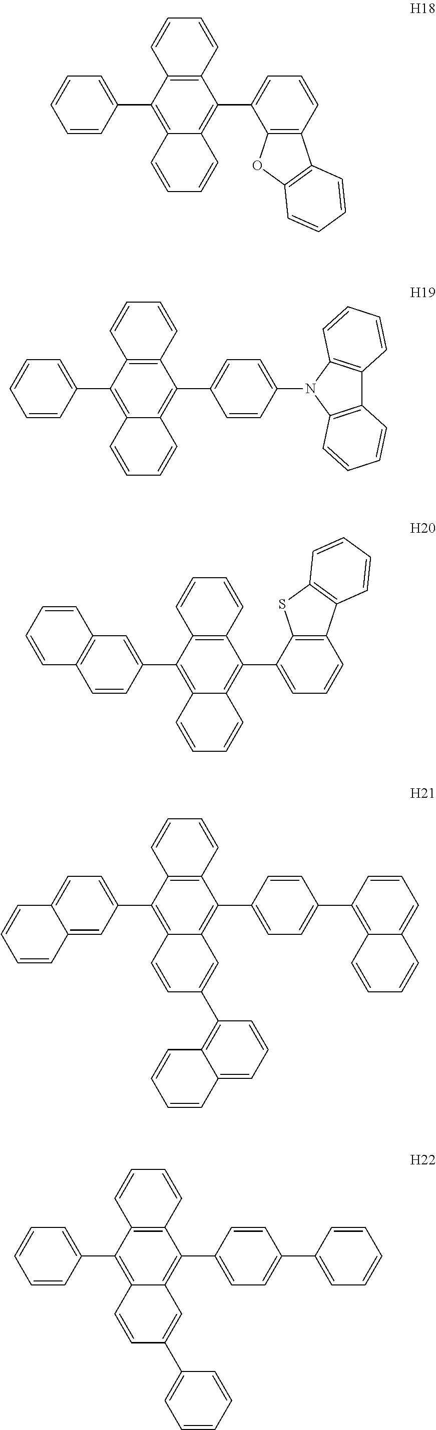

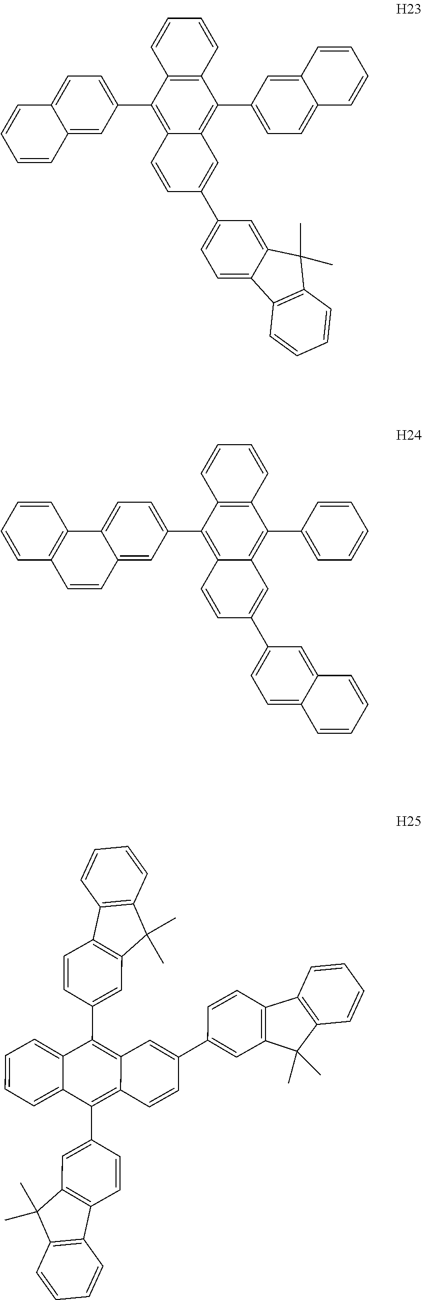

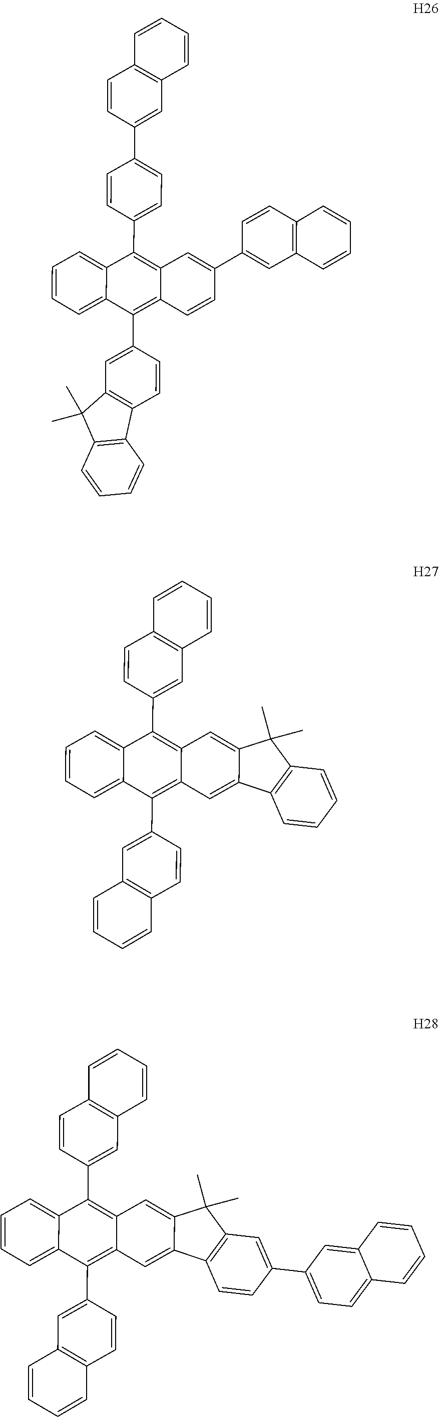

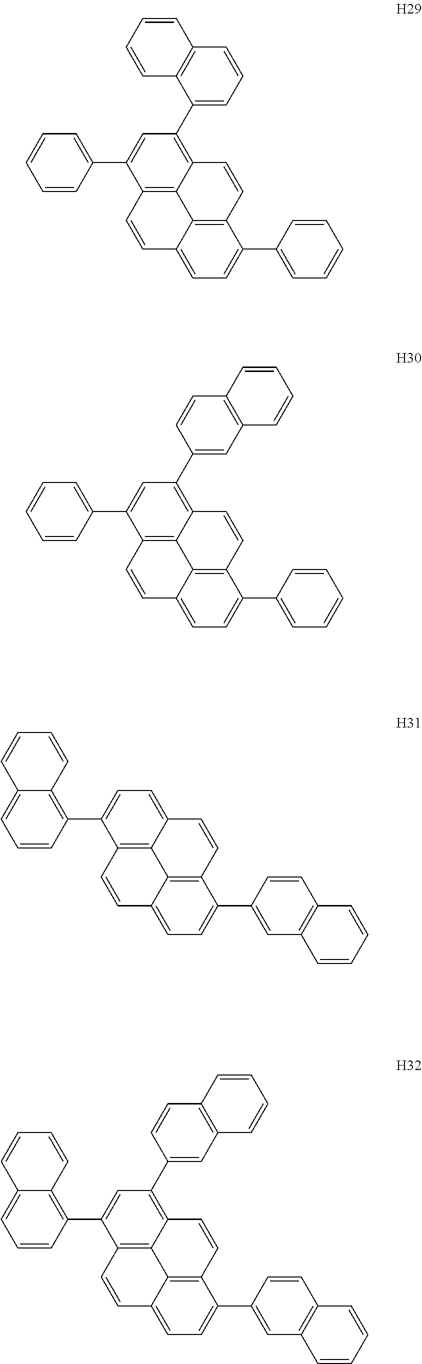

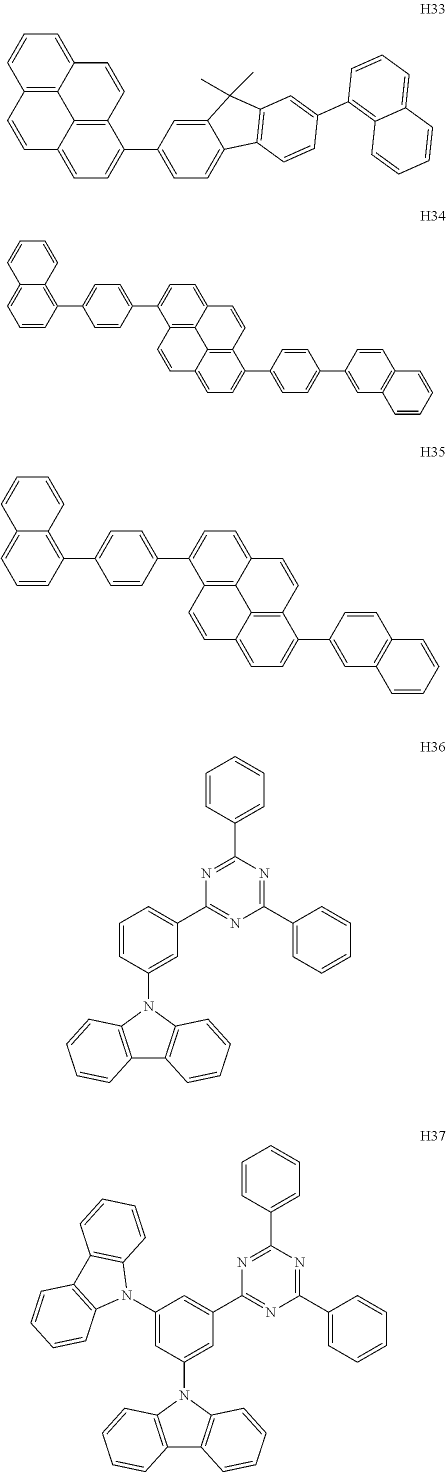

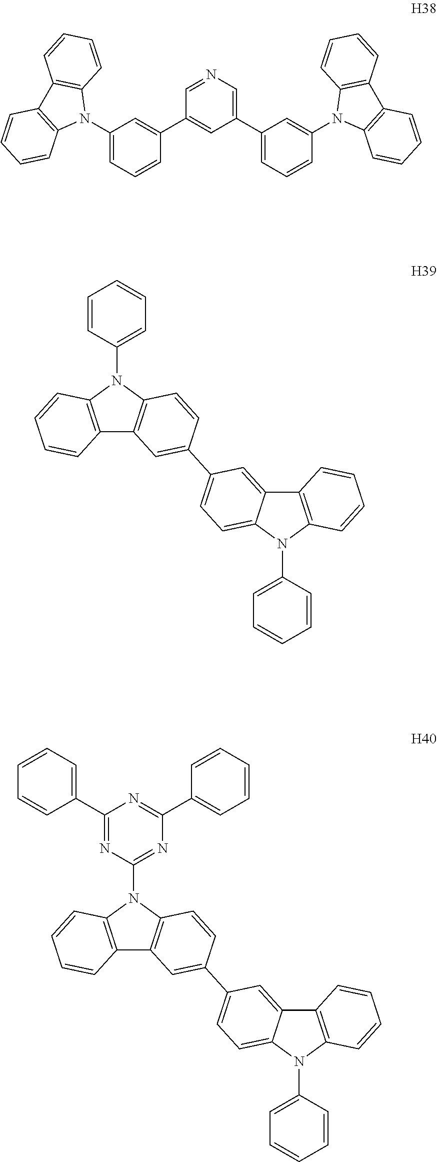 [SMILES: c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1 ; c1ccc(-c2nc(-c3ccccc3)nc(-n3c4ccccc4c4cc(-c5ccc6c(c5)c5ccccc5n6-c5ccccc5)ccc43)n2)cc1]

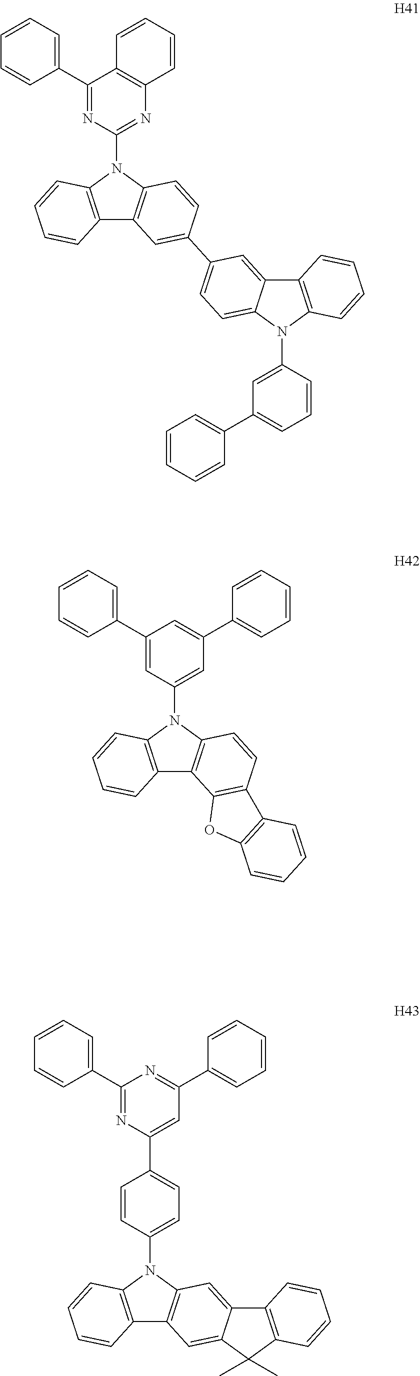 [SMILES: c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1 ; CC1(C)c2ccccc2-c2cc3c(cc21)c1ccccc1n3-c1ccc(-c2cc(-c3ccccc3)nc(-c3ccccc3)n2)cc1]

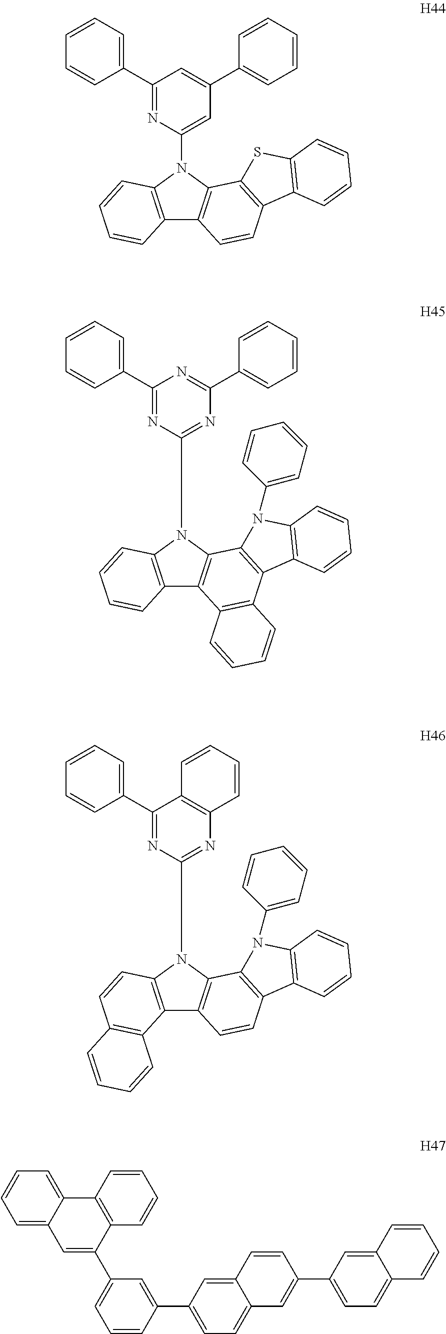

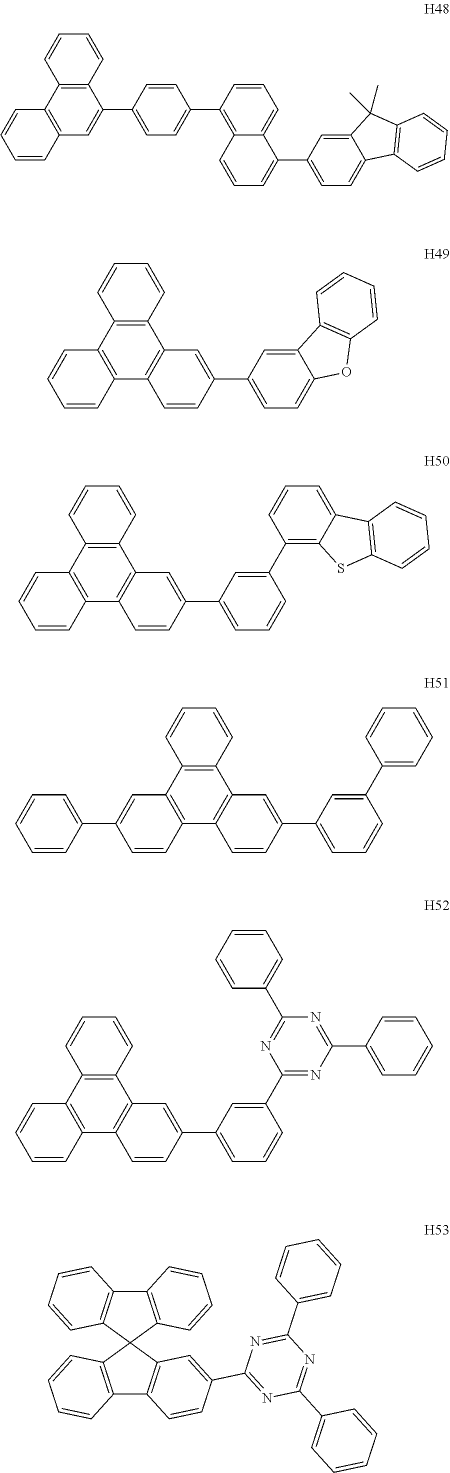

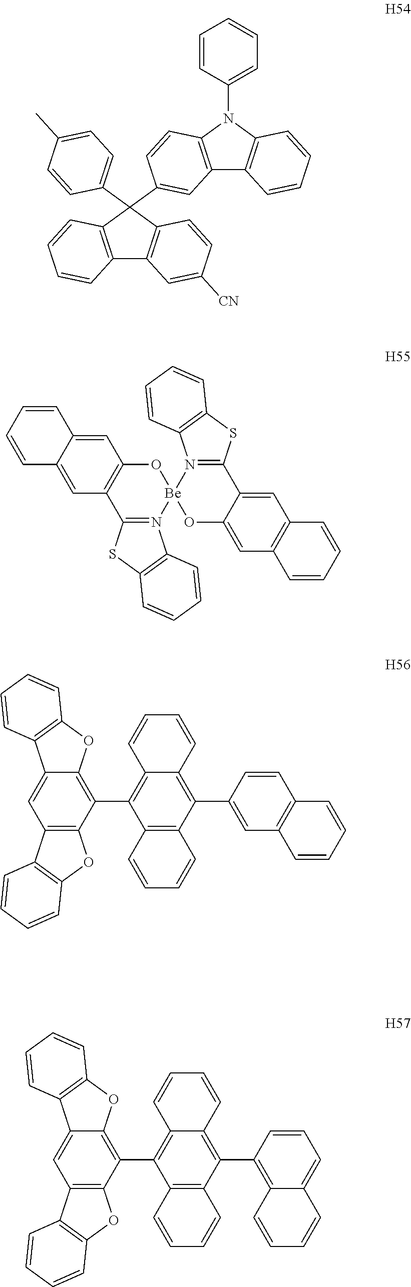

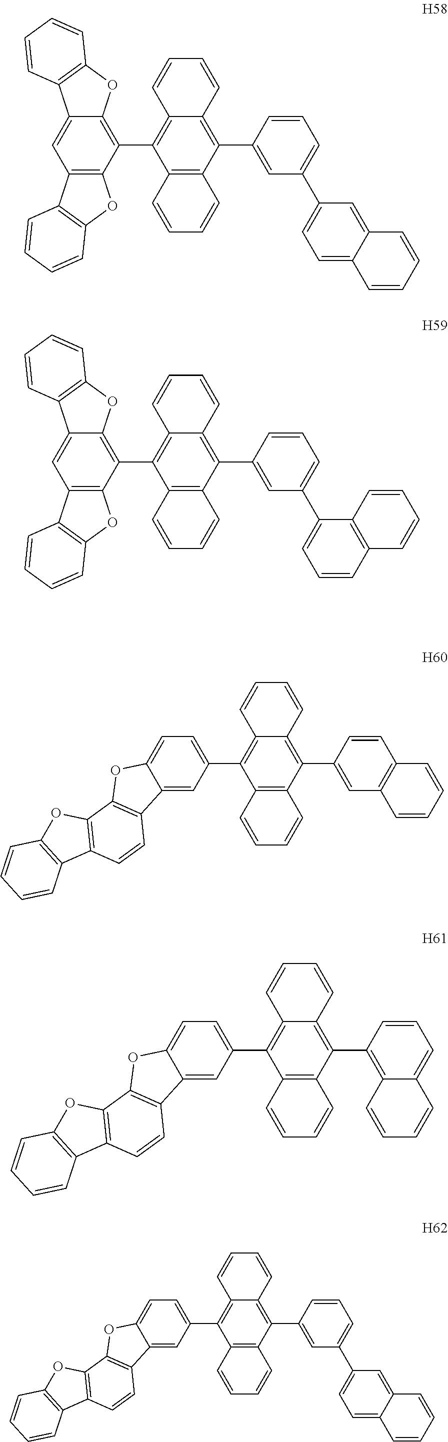 [SMILES: c1cc(-c2ccc3ccccc3c2)cc(-c2c3ccccc3c(-c3c4oc5ccccc5c4cc4c3oc3ccccc34)c3ccccc23)c1 ; c1cc(-c2cccc3ccccc23)cc(-c2c3ccccc3c(-c3c4oc5ccccc5c4cc4c3oc3ccccc34)c3ccccc23)c1 ; c1ccc2cc(-c3c4ccccc4c(-c4ccc5oc6c(ccc7c8ccccc8oc76)c5c4)c4ccccc34)ccc2c1 ; c1ccc2c(-c3c4ccccc4c(-c4ccc5oc6c(ccc7c8ccccc8oc76)c5c4)c4ccccc34)cccc2c1 ; c1cc(-c2ccc3ccccc3c2)cc(-c2c3ccccc3c(-c3ccc4oc5c(ccc6c7ccccc7oc65)c4c3)c3ccccc23)c1]

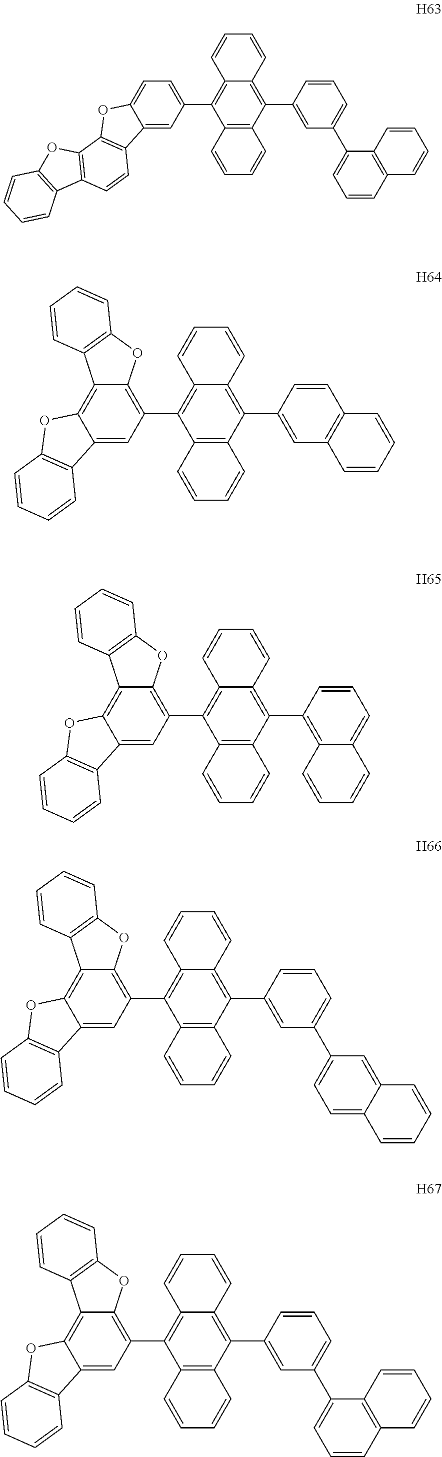 [SMILES: c1cc(-c2cccc3ccccc23)cc(-c2c3ccccc3c(-c3ccc4oc5c(ccc6c7ccccc7oc65)c4c3)c3ccccc23)c1 ; c1ccc2cc(-c3c4ccccc4c(-c4cc5c6ccccc6oc5c5c4oc4ccccc45)c4ccccc34)ccc2c1 ; c1ccc2c(-c3c4ccccc4c(-c4cc5c6ccccc6oc5c5c4oc4ccccc45)c4ccccc34)cccc2c1 ; c1cc(-c2ccc3ccccc3c2)cc(-c2c3ccccc3c(-c3cc4c5ccccc5oc4c4c3oc3ccccc34)c3ccccc23)c1 ; c1cc(-c2cccc3ccccc23)cc(-c2c3ccccc3c(-c3cc4c5ccccc5oc4c4c3oc3ccccc34)c3ccccc23)c1]

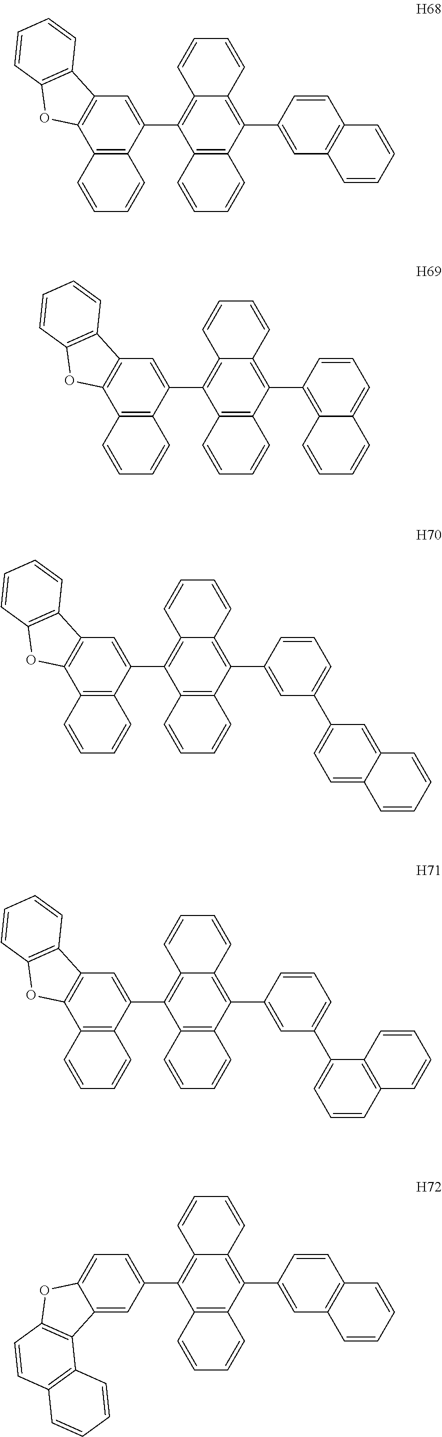 [SMILES: c1ccc2cc(-c3c4ccccc4c(-c4cc5c6ccccc6oc5c5ccccc45)c4ccccc34)ccc2c1 ; c1ccc2c(-c3c4ccccc4c(-c4cc5c6ccccc6oc5c5ccccc45)c4ccccc34)cccc2c1 ; c1cc(-c2ccc3ccccc3c2)cc(-c2c3ccccc3c(-c3cc4c5ccccc5oc4c4ccccc34)c3ccccc23)c1 ; c1cc(-c2cccc3ccccc23)cc(-c2c3ccccc3c(-c3cc4c5ccccc5oc4c4ccccc34)c3ccccc23)c1 ; c1ccc2cc(-c3c4ccccc4c(-c4ccc5oc6ccc7ccccc7c6c5c4)c4ccccc34)ccc2c1]

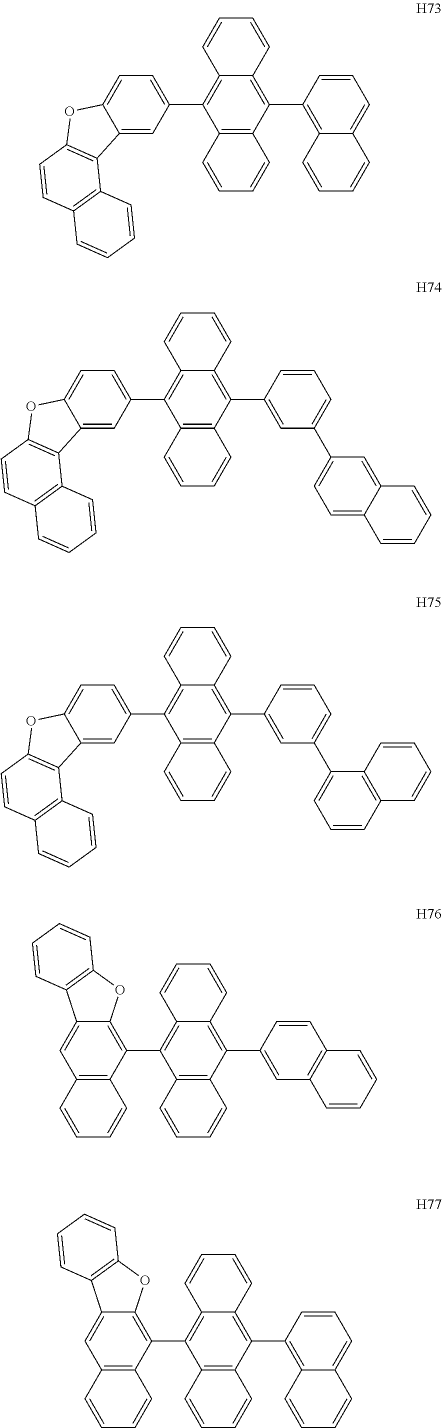 [SMILES: c1ccc2c(-c3c4ccccc4c(-c4ccc5oc6ccc7ccccc7c6c5c4)c4ccccc34)cccc2c1 ; c1cc(-c2ccc3ccccc3c2)cc(-c2c3ccccc3c(-c3ccc4oc5ccc6ccccc6c5c4c3)c3ccccc23)c1 ; c1cc(-c2cccc3ccccc23)cc(-c2c3ccccc3c(-c3ccc4oc5ccc6ccccc6c5c4c3)c3ccccc23)c1 ; c1ccc2cc(-c3c4ccccc4c(-c4c5ccccc5cc5c4oc4ccccc45)c4ccccc34)ccc2c1 ; c1ccc2c(-c3c4ccccc4c(-c4c5ccccc5cc5c4oc4ccccc45)c4ccccc34)cccc2c1]

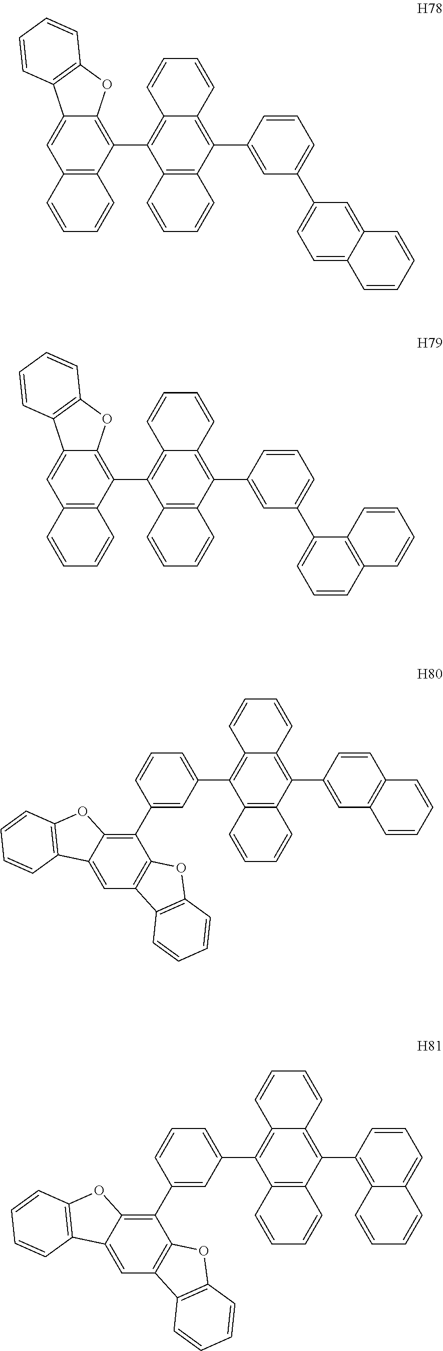 [SMILES: c1cc(-c2ccc3ccccc3c2)cc(-c2c3ccccc3c(-c3c4ccccc4cc4c3oc3ccccc34)c3ccccc23)c1 ; c1cc(-c2cccc3ccccc23)cc(-c2c3ccccc3c(-c3c4ccccc4cc4c3oc3ccccc34)c3ccccc23)c1 ; c1cc(-c2c3ccccc3c(-c3ccc4ccccc4c3)c3ccccc23)cc(-c2c3oc4ccccc4c3cc3c2oc2ccccc23)c1 ; c1cc(-c2c3ccccc3c(-c3cccc4ccccc34)c3ccccc23)cc(-c2c3oc4ccccc4c3cc3c2oc2ccccc23)c1]

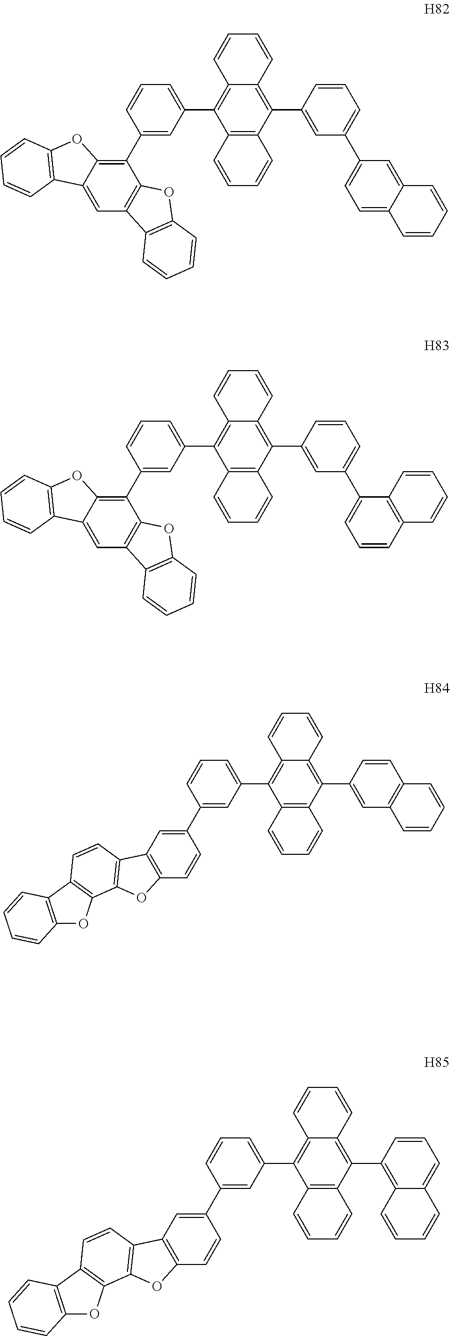 [SMILES: c1cc(-c2ccc3ccccc3c2)cc(-c2c3ccccc3c(-c3cccc(-c4c5oc6ccccc6c5cc5c4oc4ccccc45)c3)c3ccccc23)c1 ; c1cc(-c2cccc3ccccc23)cc(-c2c3ccccc3c(-c3cccc(-c4c5oc6ccccc6c5cc5c4oc4ccccc45)c3)c3ccccc23)c1 ; c1cc(-c2ccc3oc4c(ccc5c6ccccc6oc54)c3c2)cc(-c2c3ccccc3c(-c3ccc4ccccc4c3)c3ccccc23)c1 ; c1cc(-c2ccc3oc4c(ccc5c6ccccc6oc54)c3c2)cc(-c2c3ccccc3c(-c3cccc4ccccc34)c3ccccc23)c1]

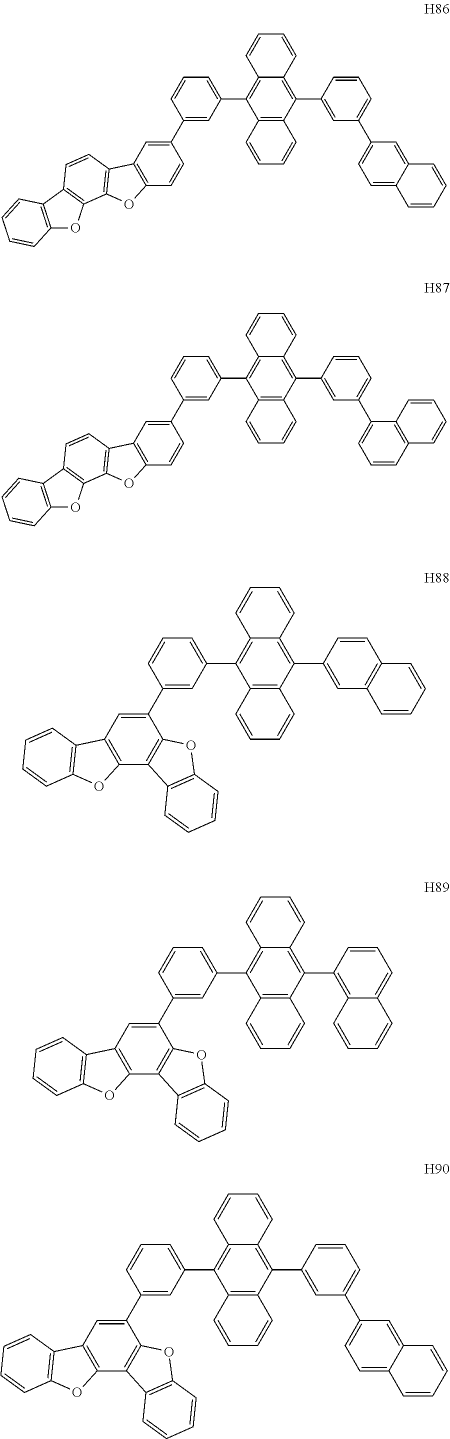 [SMILES: c1cc(-c2ccc3ccccc3c2)cc(-c2c3ccccc3c(-c3cccc(-c4ccc5oc6c(ccc7c8ccccc8oc76)c5c4)c3)c3ccccc23)c1 ; c1cc(-c2ccc3oc4c(ccc5c6ccccc6oc54)c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3c2oc2ccccc23)c1 ; c1cc(-c2c3ccccc3c(-c3cccc4ccccc34)c3ccccc23)cc(-c2cc3c4ccccc4oc3c3c2oc2ccccc23)c1 ; c1cc(-c2ccc3ccccc3c2)cc(-c2c3ccccc3c(-c3cccc(-c4cc5c6ccccc6oc5c5c4oc4ccccc45)c3)c3ccccc23)c1]

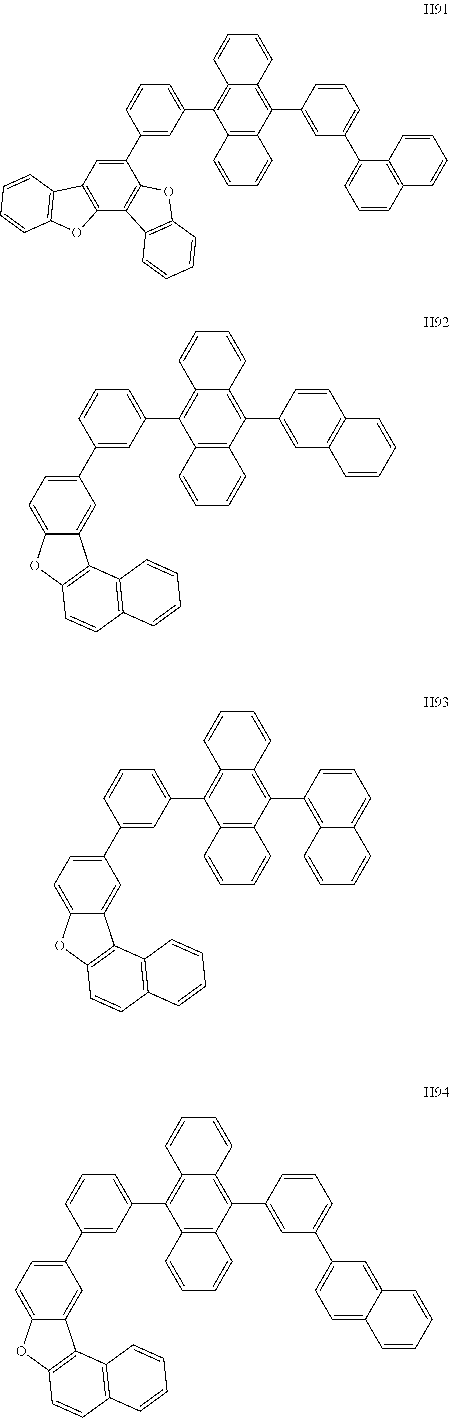 [SMILES: c1cc(-c2cccc3ccccc23)cc(-c2c3ccccc3c(-c3cccc(-c4cc5c6ccccc6oc5c5c4oc4ccccc45)c3)c3ccccc23)c1 ; c1cc(-c2ccc3oc4ccc5ccccc5c4c3c2)cc(-c2c3ccccc3c(-c3ccc4ccccc4c3)c3ccccc23)c1 ; c1cc(-c2ccc3oc4ccc5ccccc5c4c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6ccc7ccccc7c6c5c4)c3)c3ccccc23)c1]

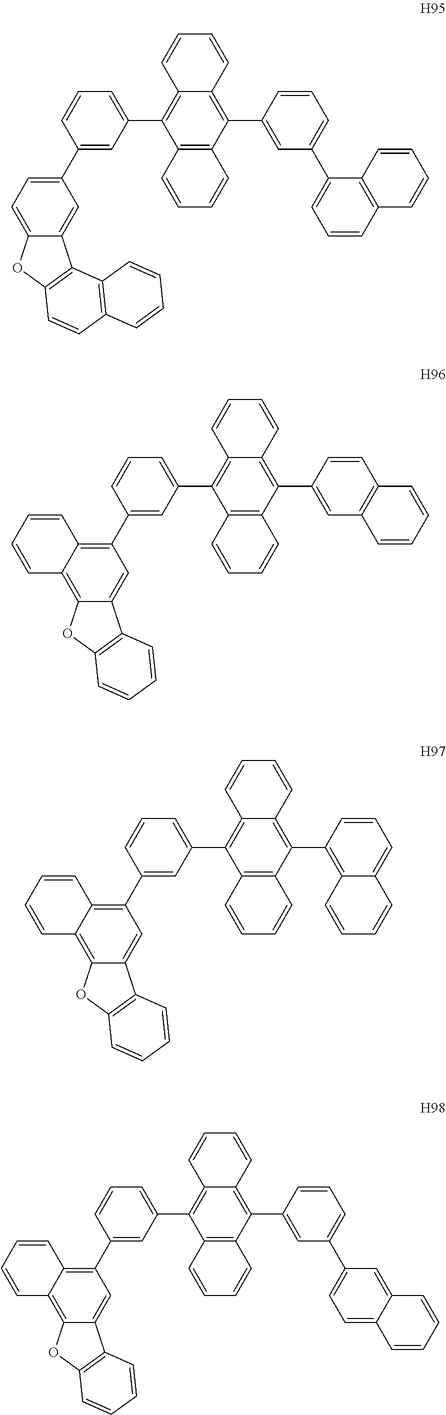 [SMILES: c1cc(-c2ccc3oc4ccc5ccccc5c4c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3ccccc23)c1 ; c1cc(-c2c3ccccc3c(-c3cccc4ccccc34)c3ccccc23)cc(-c2cc3c4ccccc4oc3c3ccccc23)c1 ; c1cc(-c2ccc3ccccc3c2)cc(-c2c3ccccc3c(-c3cccc(-c4cc5c6ccccc6oc5c5ccccc45)c3)c3ccccc23)c1]

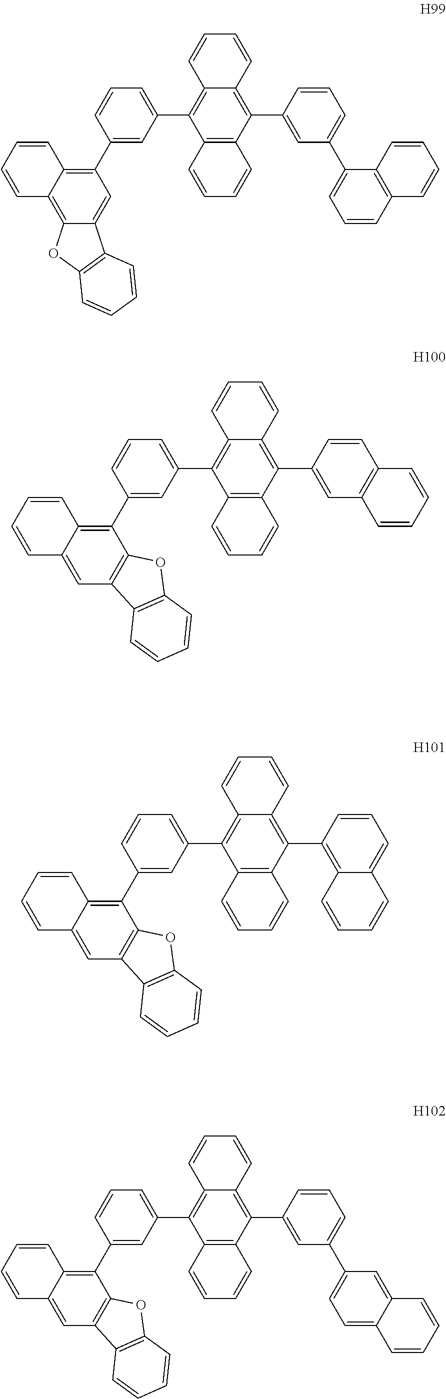 [SMILES: c1cc(-c2cccc3ccccc23)cc(-c2c3ccccc3c(-c3cccc(-c4cc5c6ccccc6oc5c5ccccc45)c3)c3ccccc23)c1 ; c1cc(-c2c3ccccc3c(-c3ccc4ccccc4c3)c3ccccc23)cc(-c2c3ccccc3cc3c2oc2ccccc23)c1 ; c1cc(-c2c3ccccc3c(-c3cccc4ccccc34)c3ccccc23)cc(-c2c3ccccc3cc3c2oc2ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1]

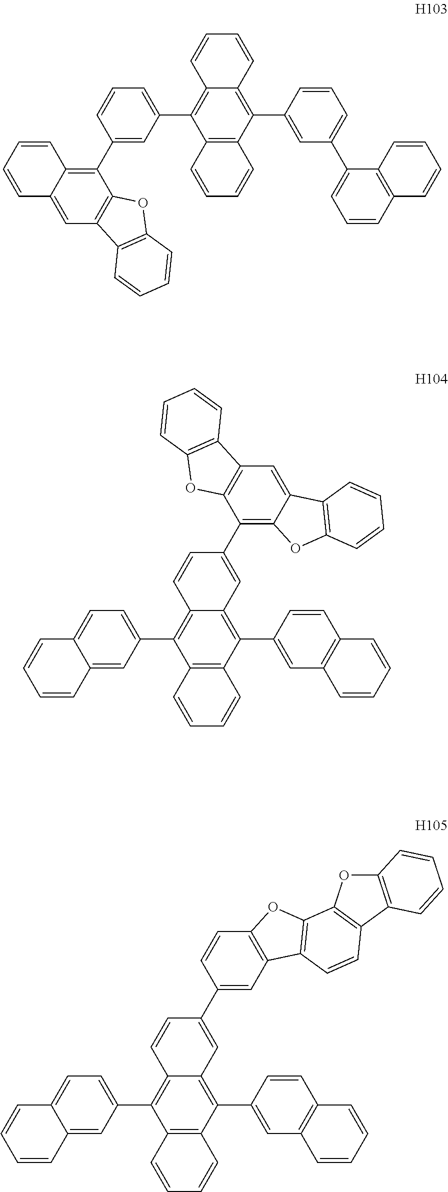 [SMILES: c1cc(-c2cccc3ccccc23)cc(-c2c3ccccc3c(-c3cccc(-c4c5ccccc5cc5c4oc4ccccc45)c3)c3ccccc23)c1 ; c1ccc2cc(-c3c4ccccc4c(-c4ccc5ccccc5c4)c4cc(-c5c6oc7ccccc7c6cc6c5oc5ccccc56)ccc34)ccc2c1 ; c1ccc2cc(-c3c4ccccc4c(-c4ccc5ccccc5c4)c4cc(-c5ccc6oc7c(ccc8c9ccccc9oc87)c6c5)ccc34)ccc2c1]

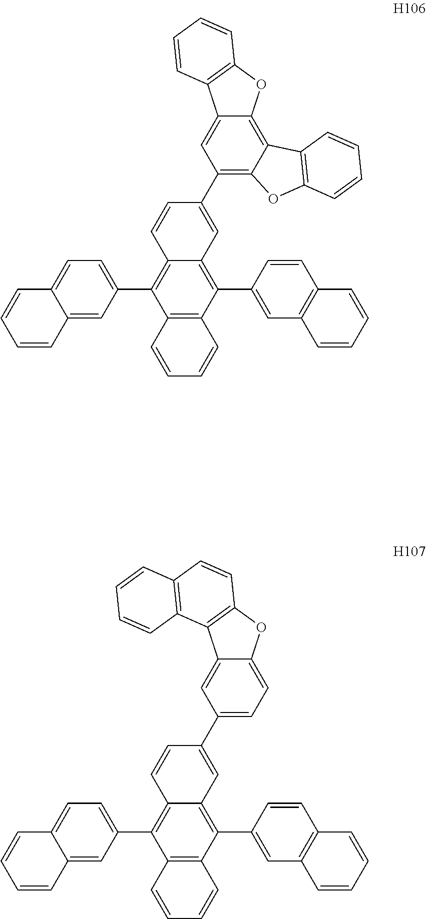 [SMILES: c1ccc2cc(-c3c4ccccc4c(-c4ccc5ccccc5c4)c4cc(-c5cc6c7ccccc7oc6c6c5oc5ccccc56)ccc34)ccc2c1 ; c1ccc2cc(-c3c4ccccc4c(-c4ccc5ccccc5c4)c4cc(-c5ccc6oc7ccc8ccccc8c7c6c5)ccc34)ccc2c1]

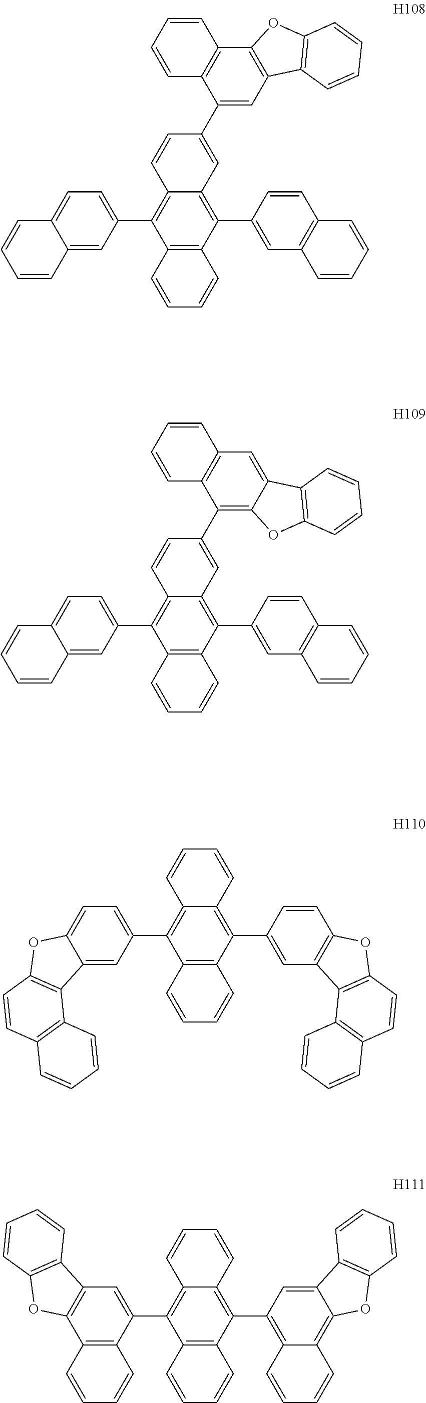 [SMILES: c1ccc2cc(-c3c4ccccc4c(-c4ccc5ccccc5c4)c4cc(-c5cc6c7ccccc7oc6c6ccccc56)ccc34)ccc2c1 ; c1ccc2cc(-c3c4ccccc4c(-c4ccc5ccccc5c4)c4cc(-c5c6ccccc6cc6c5oc5ccccc56)ccc34)ccc2c1 ; c1ccc2c(c1)ccc1oc3ccc(-c4c5ccccc5c(-c5ccc6oc7ccc8ccccc8c7c6c5)c5ccccc45)cc3c12 ; c1ccc2c(c1)oc1c3ccccc3c(-c3c4ccccc4c(-c4cc5c6ccccc6oc5c5ccccc45)c4ccccc34)cc21]

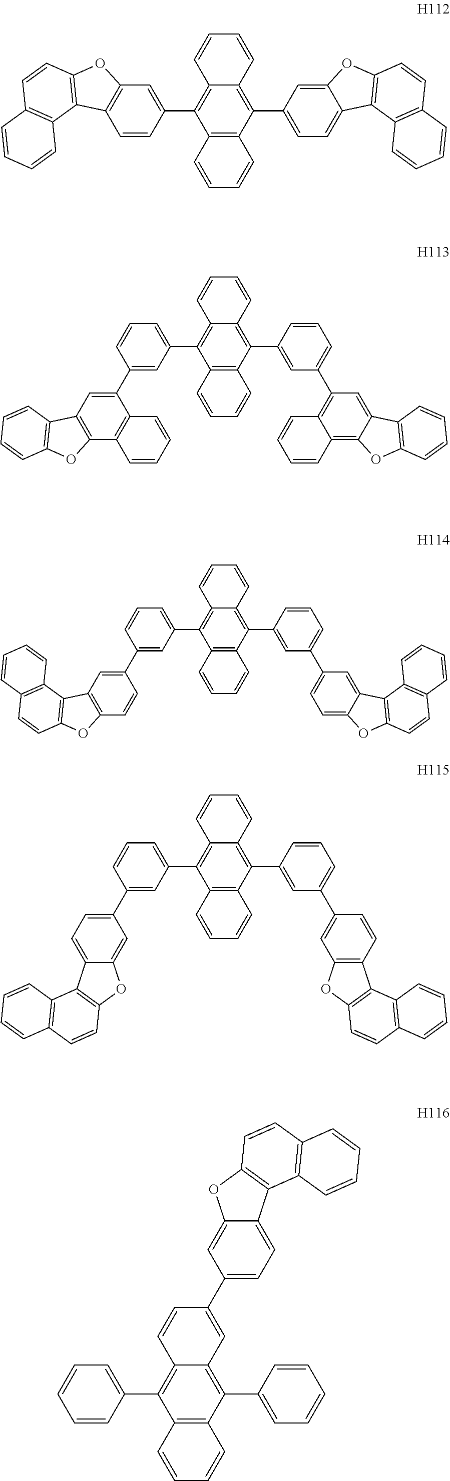 [SMILES: c1ccc2c(c1)ccc1oc3cc(-c4c5ccccc5c(-c5ccc6c(c5)oc5ccc7ccccc7c56)c5ccccc45)ccc3c12 ; c1cc(-c2c3ccccc3c(-c3cccc(-c4cc5c6ccccc6oc5c5ccccc45)c3)c3ccccc23)cc(-c2cc3c4ccccc4oc3c3ccccc23)c1 ; c1cc(-c2ccc3oc4ccc5ccccc5c4c3c2)cc(-c2c3ccccc3c(-c3cccc(-c4ccc5oc6ccc7ccccc7c6c5c4)c3)c3ccccc23)c1 ; c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1]

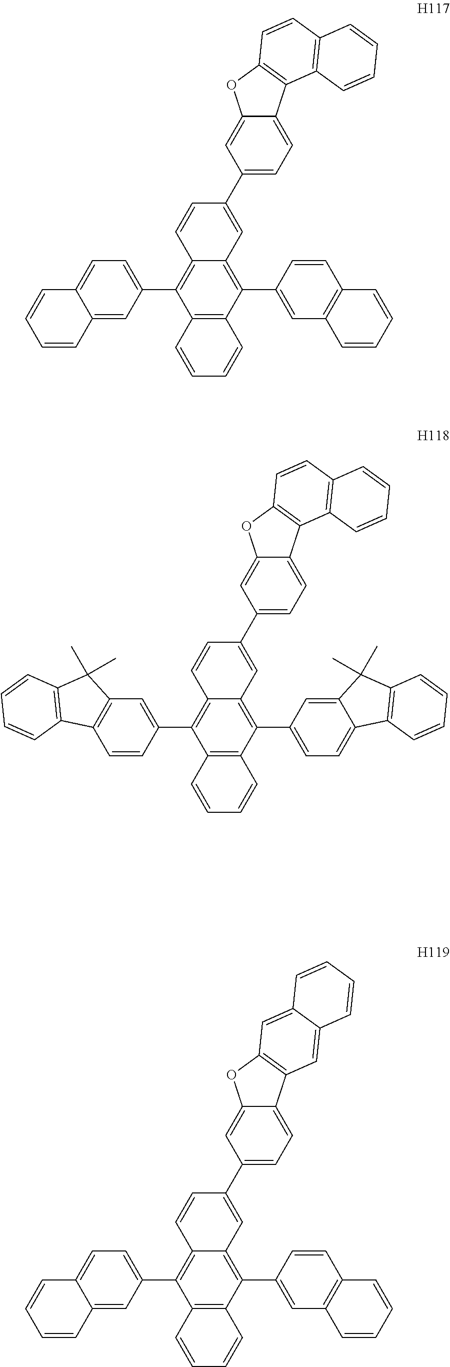 [SMILES: c1ccc2cc(-c3c4ccccc4c(-c4ccc5ccccc5c4)c4cc(-c5ccc6c(c5)oc5ccc7ccccc7c56)ccc34)ccc2c1 ; CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21 ; c1ccc2cc(-c3c4ccccc4c(-c4ccc5ccccc5c4)c4cc(-c5ccc6c(c5)oc5cc7ccccc7cc56)ccc34)ccc2c1]

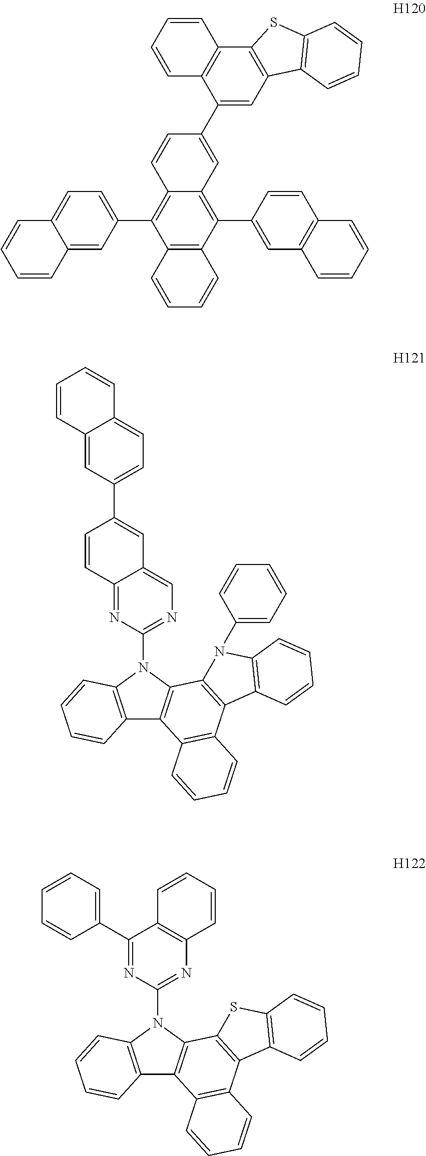 [SMILES: c1ccc2cc(-c3c4ccccc4c(-c4ccc5ccccc5c4)c4cc(-c5cc6c7ccccc7sc6c6ccccc56)ccc34)ccc2c1 ; c1ccc(-n2c3ccccc3c3c4ccccc4c4c5ccccc5n(-c5ncc6cc(-c7ccc8ccccc8c7)ccc6n5)c4c32)cc1 ; c1ccc(-c2nc(-n3c4ccccc4c4c5ccccc5c5c6ccccc6sc5c43)nc3ccccc23)cc1]

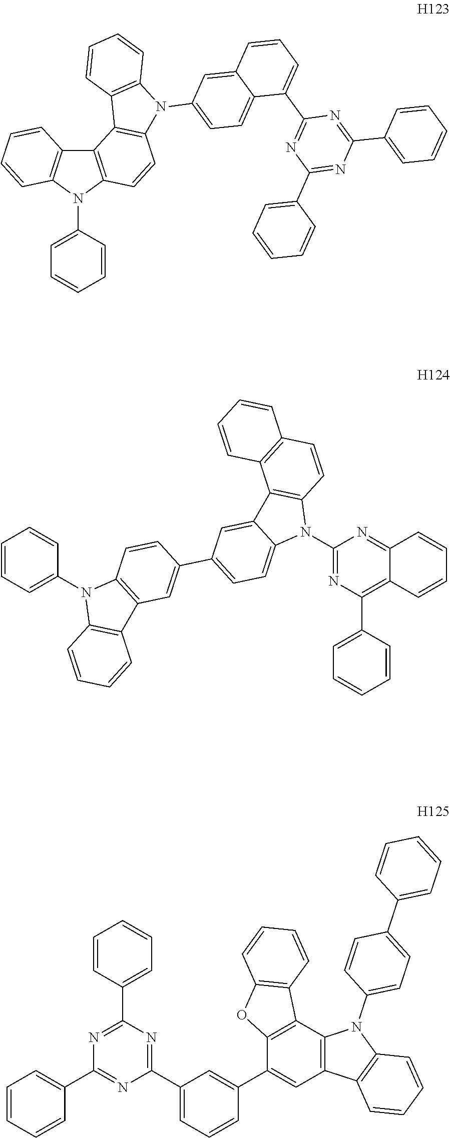 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1]

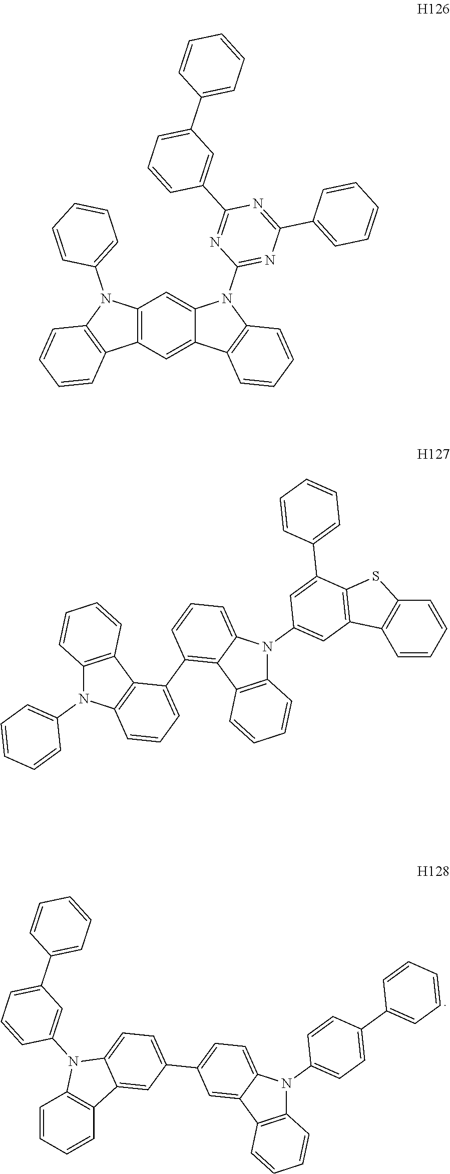 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2ccc(-n3c4ccccc4c4cc(-c5ccc6c(c5)c5ccccc5n6-c5cccc(-c6ccccc6)c5)ccc43)cc2)cc1]

### Phosphorescent Dopant

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In one or more embodiments, the phosphorescent dopant may include an organometallic compound represented by Formula 401:

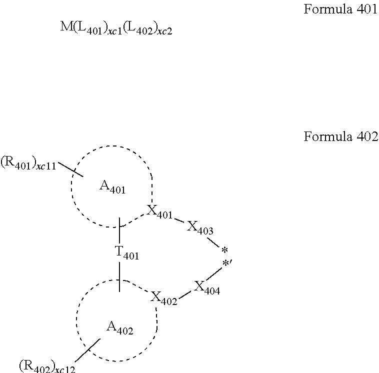

wherein, in Formulae 401 and 402,
M may be a transition metal (e.g., iridium (Ir), platinum (Pt), palladium (Pd), osmium (Os), titanium (T₁), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2, or 3, wherein, if (e.g., when) xc1 is 2 or more, two or more of L₄₀₁ may be identical to or different from each other,
L₄₀₂ may be an organic ligand, and xc2 may be 0, 1, 2, 3, or 4, wherein, if (e.g., when) xc2 is 2 or more, two or more of L₄₀₂ may be identical to or different from each other,
X₄₀₁ and X₄₀₂ may each independently be nitrogen or carbon,
ring A401 and ring A402 may each independently be a C₃-C₆₀ carbocyclic group or a C₁-C₆₀ heterocyclic group,
T₄₀₁ may be a single bond (e.g., a single covalent bond), *—O—*′, *—S—*′, *—C(═O)—*′, *—N(Q₄₁₁)-*′, *—C(Q₄₁₁)(Q₄₁₂)-*′, *—C(Q₄₁₁)=C(Q₄₁₂)-*′, *—C(Q₄₁₁)=*′, or *═C═*′,
X₄₀₃ and X₄₀₄ may each independently be a chemical bond (e.g., a covalent bond or a coordinate bond), O, S, N(Q₄₁₃), B(Q₄₁₃), P(Q₄₁₃), C(Q₄₁₃)(Q₄₁₄), or Si(Q₄₁₃)(Q₄₁₄),
Q₄₁₁ to Q₄₁₄ may each be the same as defined with respect to Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₅-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ may each be the same as defined with respect to Q₁,
xc11 and xc12 may each independently be an integer of 0 to 10, and
* and *′ in Formula 402 each indicate a binding site to M in Formula 401.

In one or more embodiments, in Formula 402, i) X₄₀₁ may be nitrogen, and X₄₀₂ may be carbon, or ii) each of X₄₀₁ and X₄₀₂ may be nitrogen.

In one or more embodiments, if (e.g., when) xc1 in Formula 401 is 2 or more, two rings A401 selected from among two or more of L₄₀₁ may optionally be linked to each other via T₄₀₂, which is a linking group, and two rings A402 selected from among two or more of L₄₀₁ may optionally be linked to each other via T₄₀₃, which is a linking group (see Compounds PD1 to PD4 and PD7). T₄₀₂ and T₄₀₃ may each be the same as defined with respect to T₄₀₁.

In Formula 401, L₄₀₂ may be an organic ligand. For example, L₄₀₂ may include a halogen group, a diketone group (e.g., an acetylacetonate group), a carboxylic acid group (e.g., a picolinate group), —C(═O), an isonitrile group, a —CN group, a phosphorus-containing group (e.g., a phosphine group, a phosphite group, and/or the like), or any combination thereof.

The phosphorescent dopant may include, for example, one selected from among Compounds PD1 to PD39, or any combination thereof:

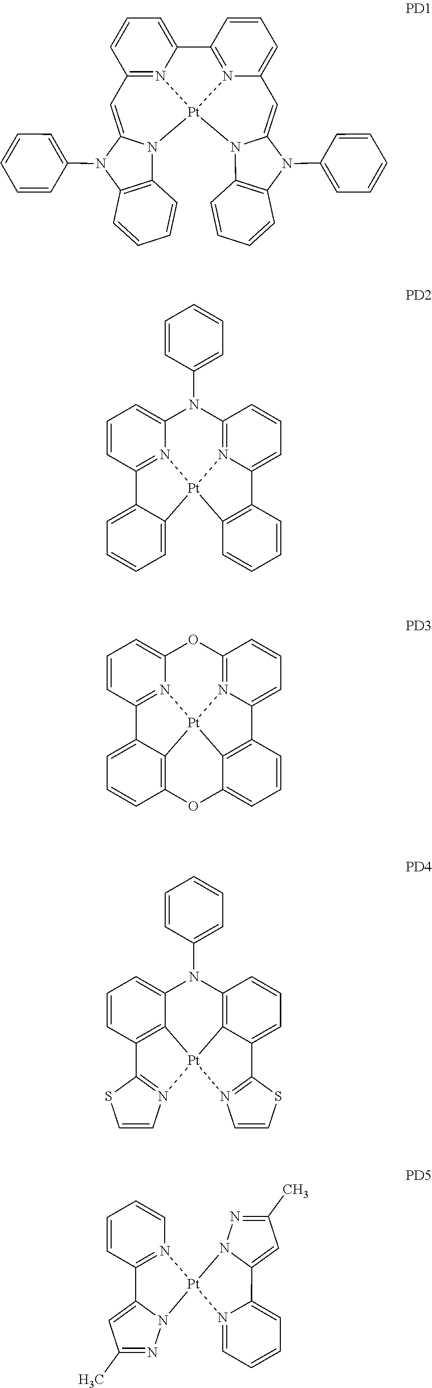

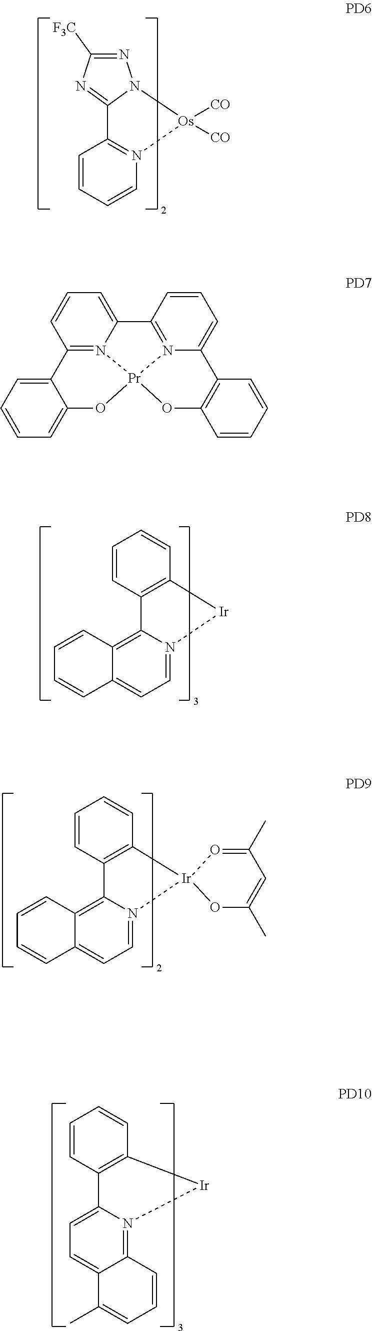

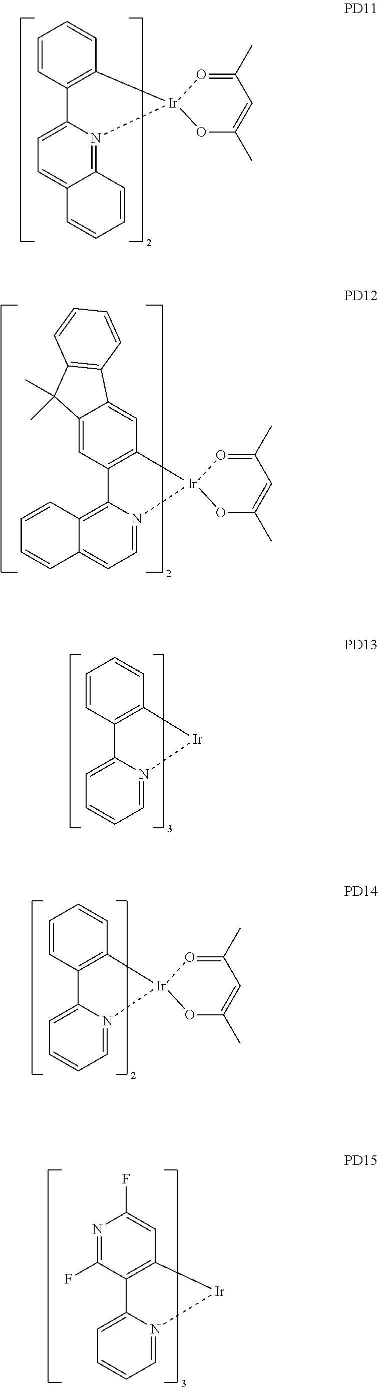

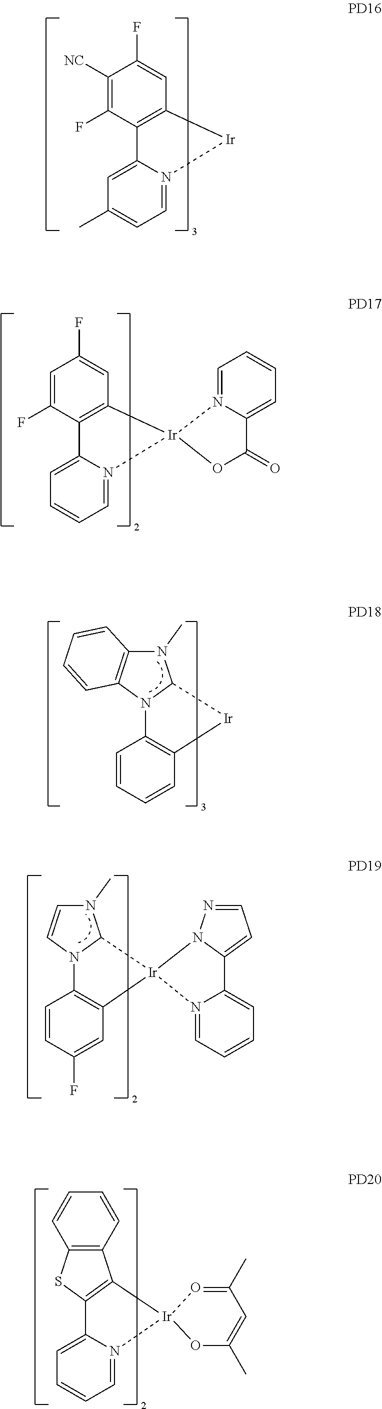

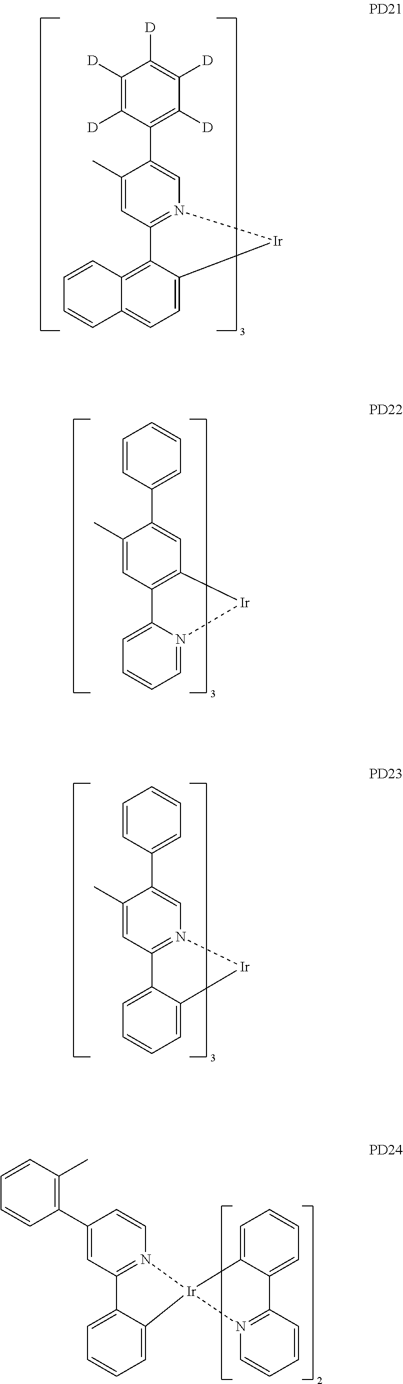

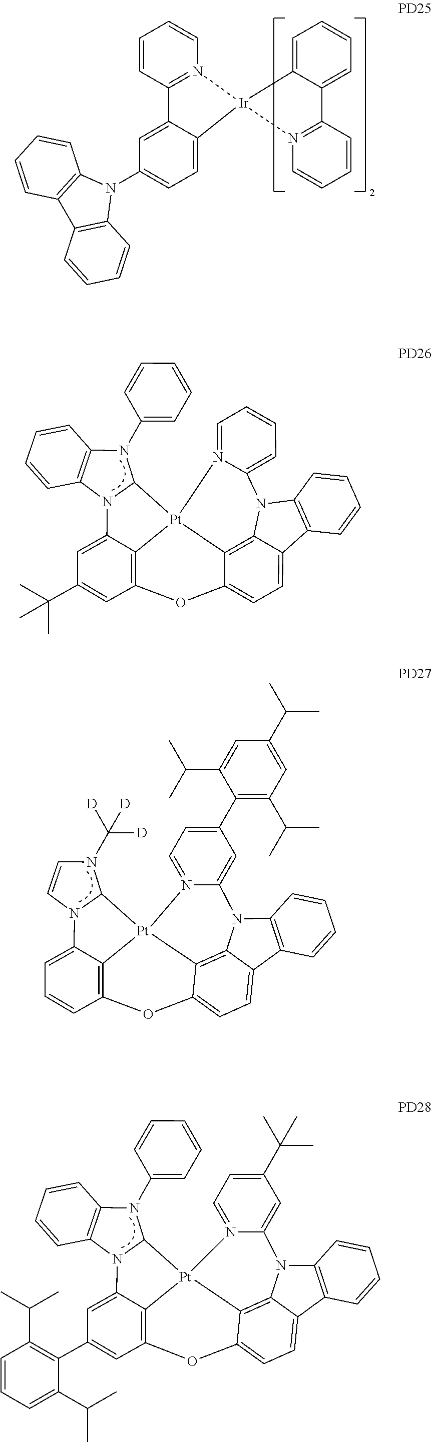

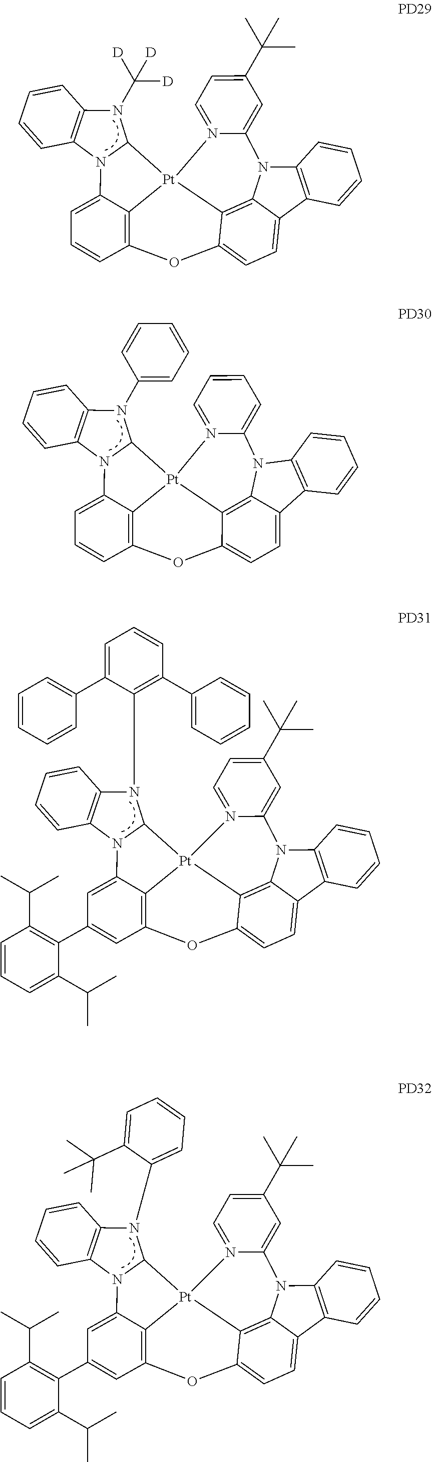

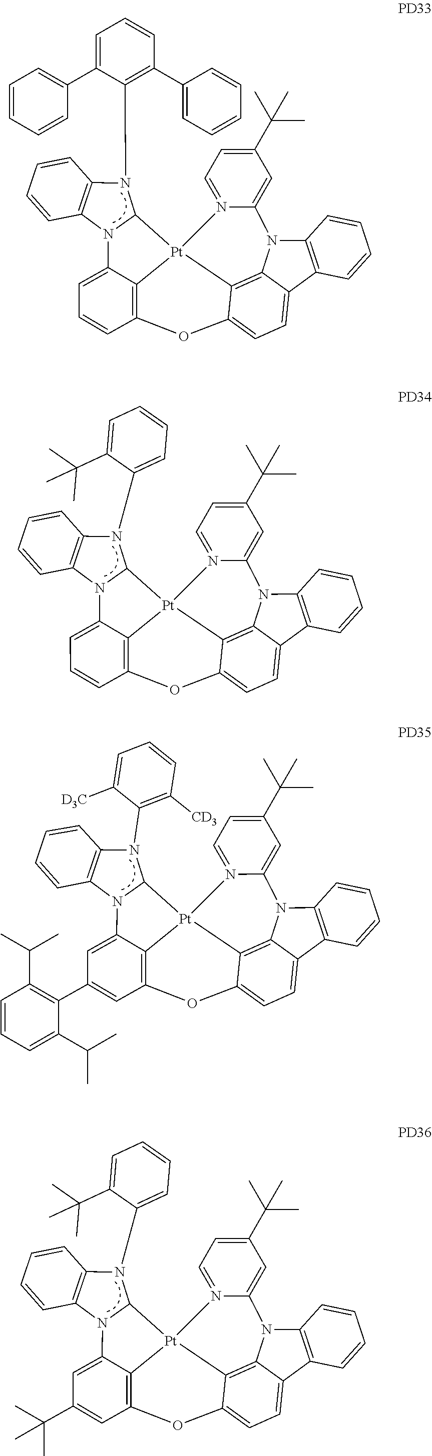

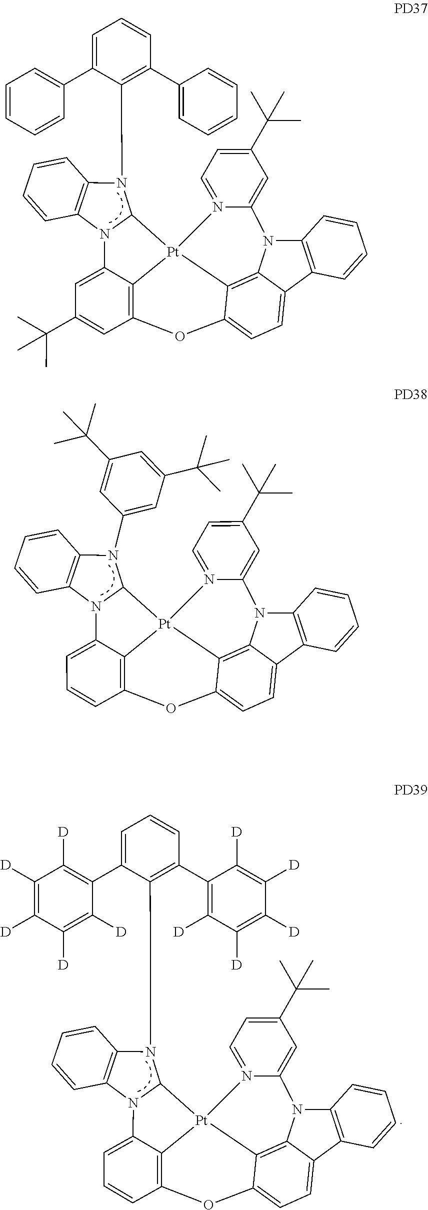

### Fluorescent Dopant

The fluorescent dopant may include an amine group-containing compound, a styryl group-containing compound, or any combination thereof.

In one or more embodiments, the fluorescent dopant may include a compound represented by Formula 501:

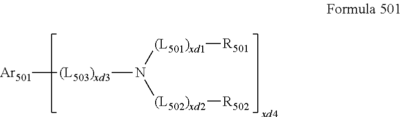

wherein, in Formula 501,
Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xd1 to xd3 may each independently be 0, 1, 2, or 3, and
xd4 may be 1, 2, 3, 4, 5, or 6.

In one or more embodiments, Ar₅₀₁ in Formula 501 may be a condensed cyclic group (e.g., an anthracene group, a chrysene group, a pyrene group, and/or the like) in which three or more monocyclic groups are condensed with each other.

In one or more embodiments, xd4 in Formula 501 may be 2.

In one or more embodiments, the fluorescent dopant may include: one selected from among Compounds FD1 to FD37; DPVBi; DPAVBi; or any combination thereof:

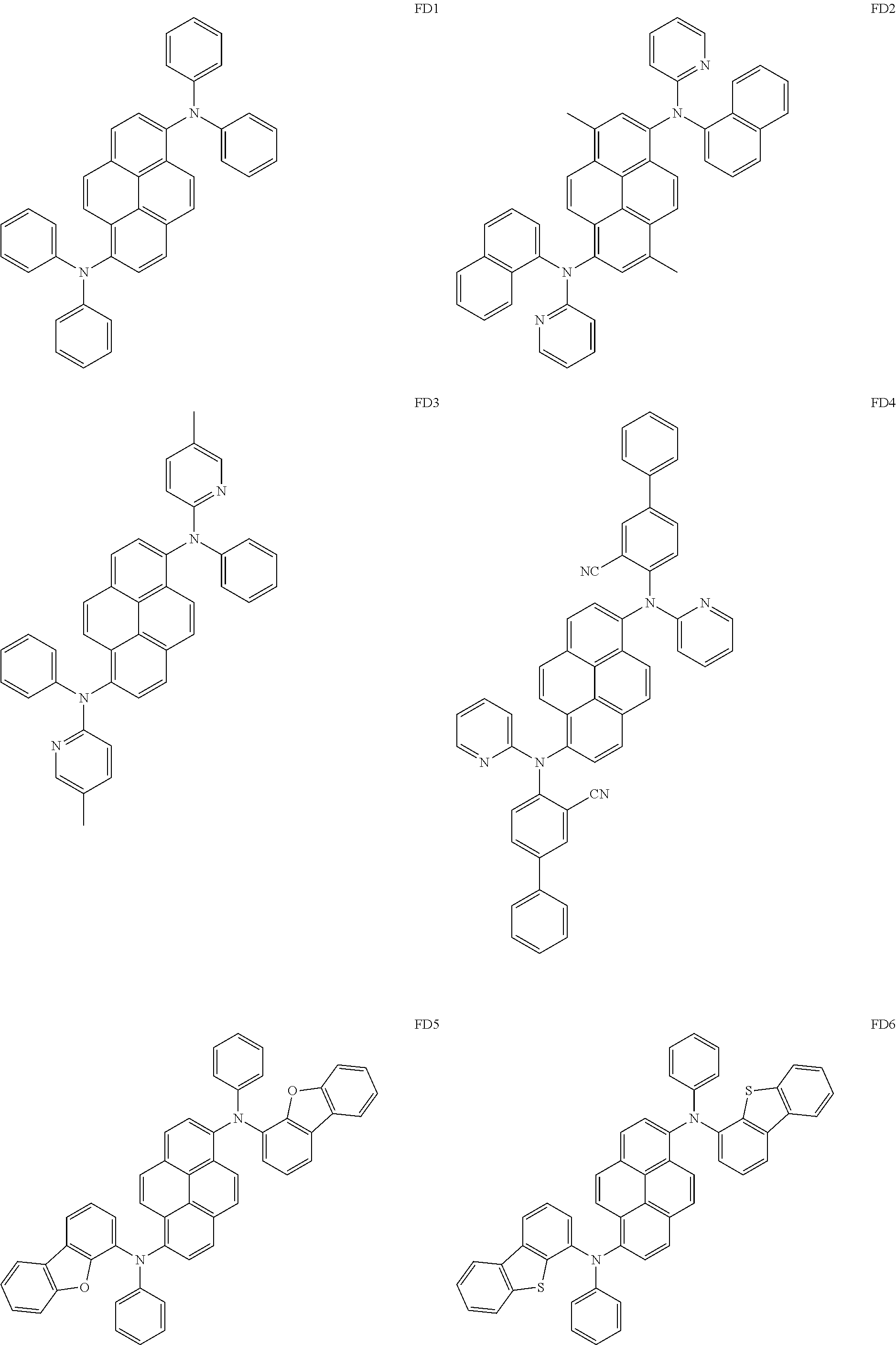

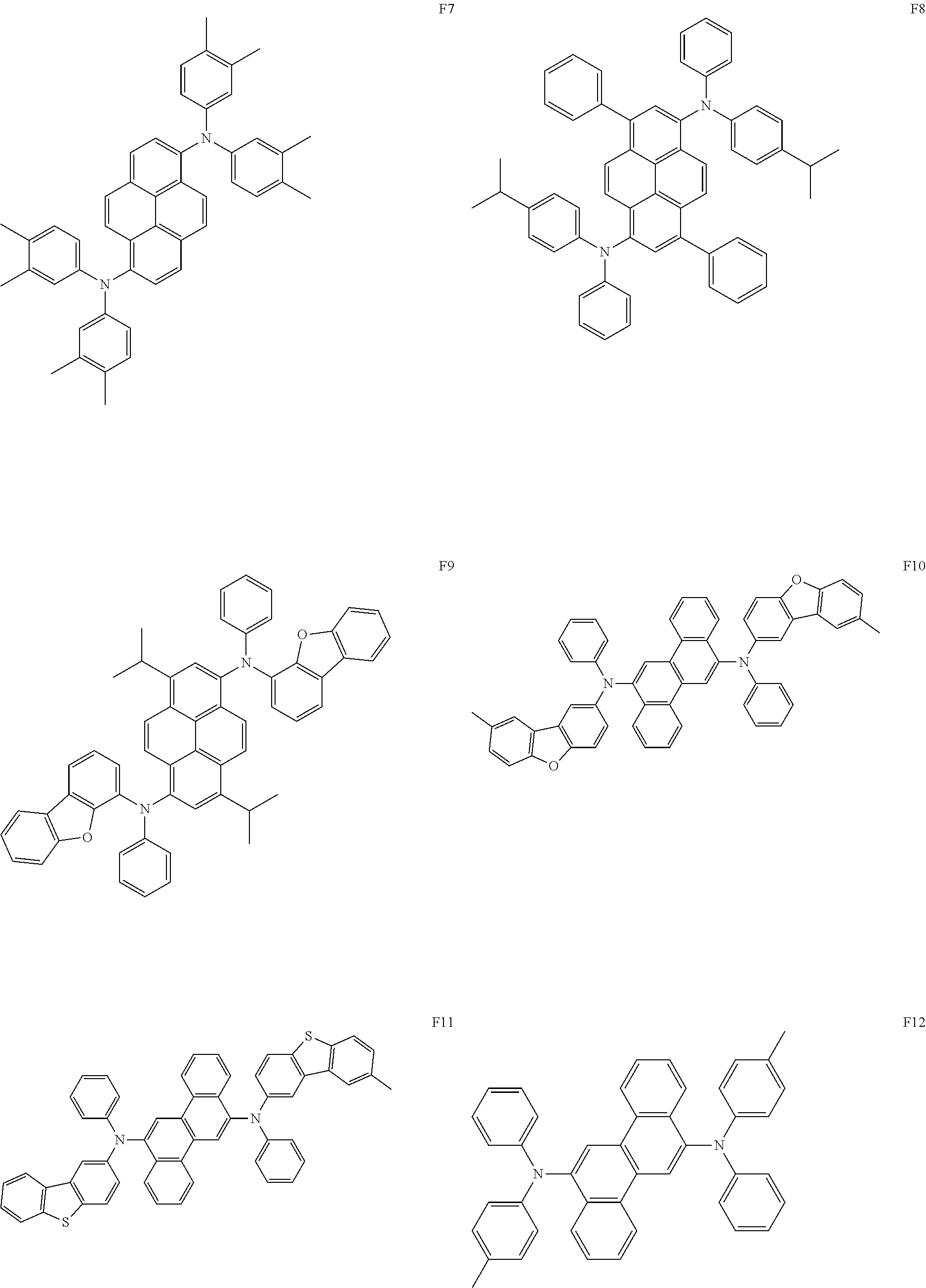

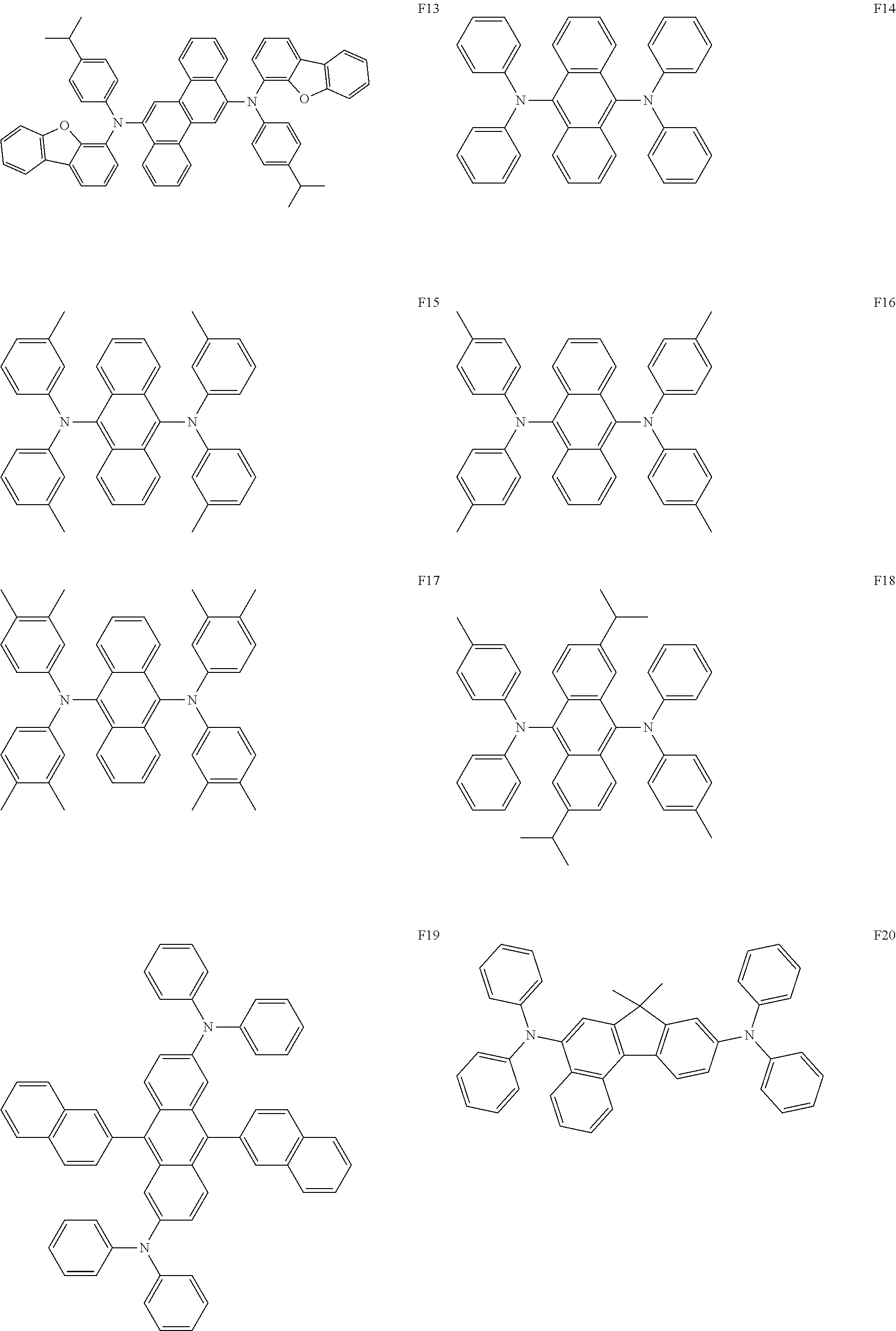

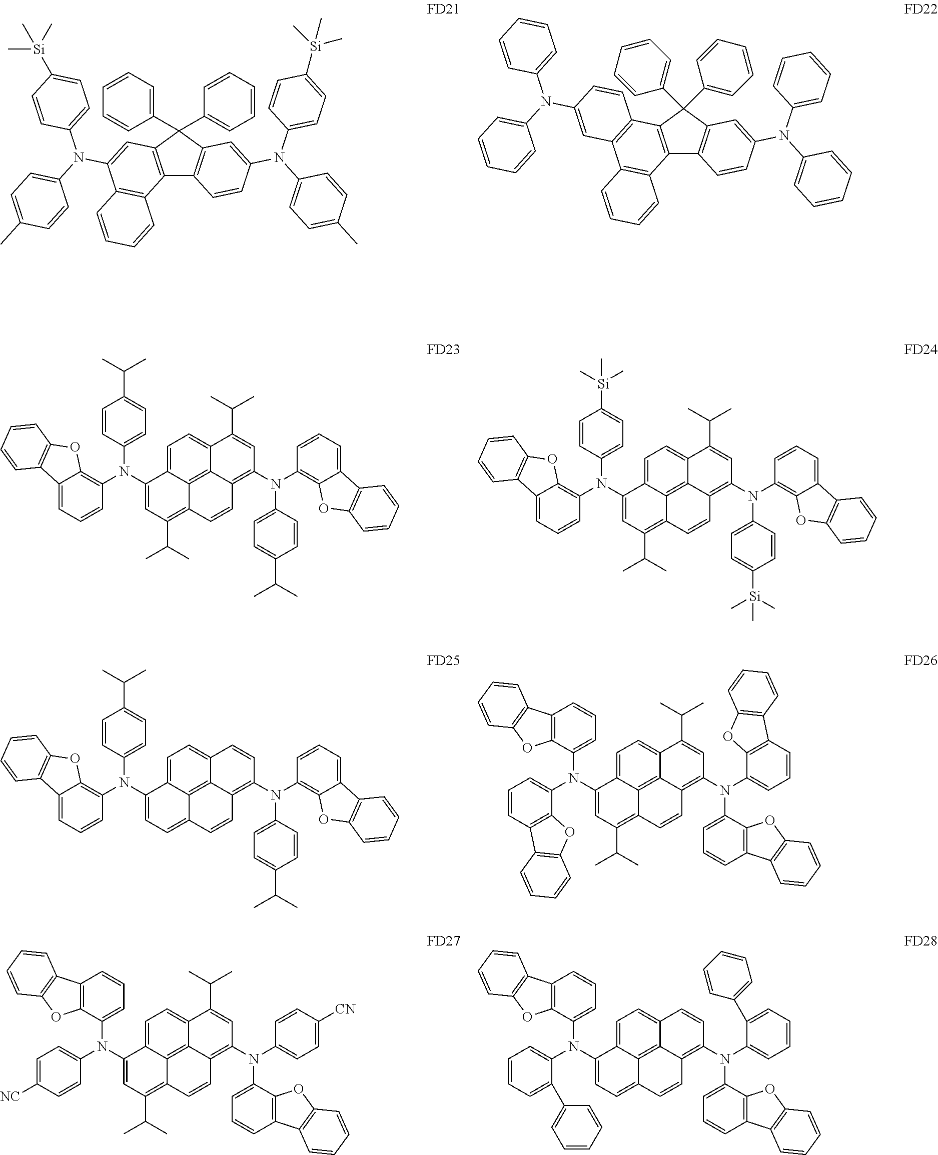

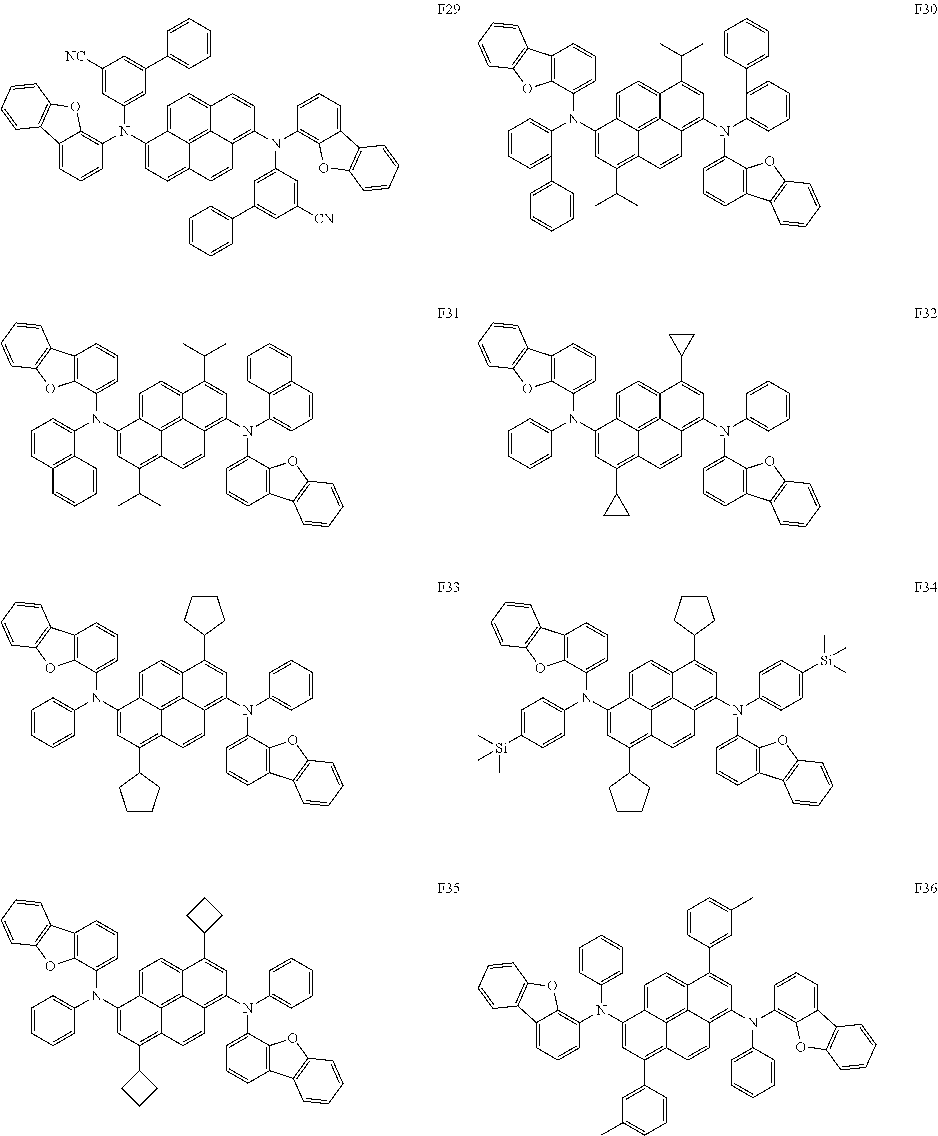

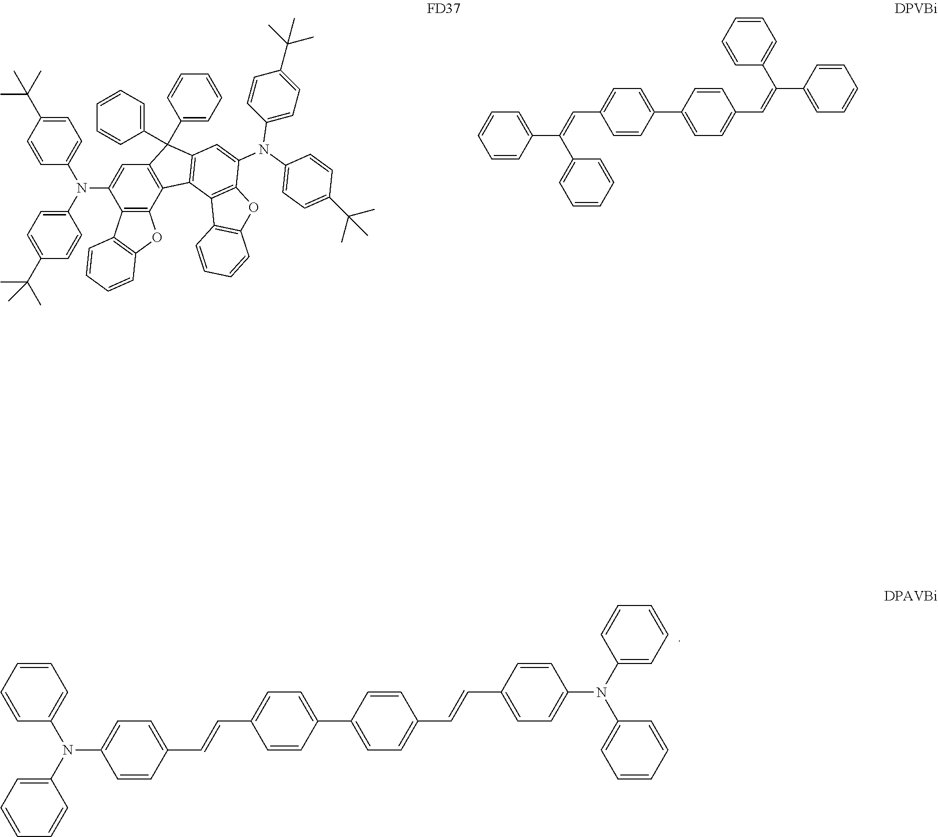

### Delayed Fluorescence Material

The emission layer 130 may include a delayed fluorescence material.

Herein, the delayed fluorescence material may be selected from among compounds capable of emitting delayed fluorescence based on a delayed fluorescence emission mechanism.

The delayed fluorescence material included in the emission layer 130 may act as a host or a dopant, depending on the type or kind of other materials included in the emission layer 130.

In one or more embodiments, a difference between a triplet energy level (eV) of the delayed fluorescence material and a singlet energy level (eV) of the delayed fluorescence material may be at least 0 eV but not more than about 0.5 eV. If (e.g., when) the difference between the triplet energy level (eV) of the delayed fluorescence material and the singlet energy level (eV) of the delayed fluorescence material is within the foregoing range, up-conversion from the triplet state to the singlet state of the delayed fluorescence material may effectively or suitably occur, and thus, the light-emitting device 10 may have improved and enhanced luminescence efficiency.

In one or more embodiments, the delayed fluorescence material may include i) a material including at least one electron donor (e.g., a π electron-rich C₃-C₆₀ cyclic group, such as a carbazole group, and/or the like) and at least one electron acceptor (e.g., a sulfoxide group, a cyano group, a Ir electron-deficient nitrogen-containing C₁-C₆₀ heterocyclic group, and/or the like), ii) a material including a C₈-C₆₀ polycyclic group in which two or more cyclic groups are condensed while sharing boron (B), and/or the like.

Examples of the delayed fluorescence material may include at least one selected from among Compounds DF1 to DF14:

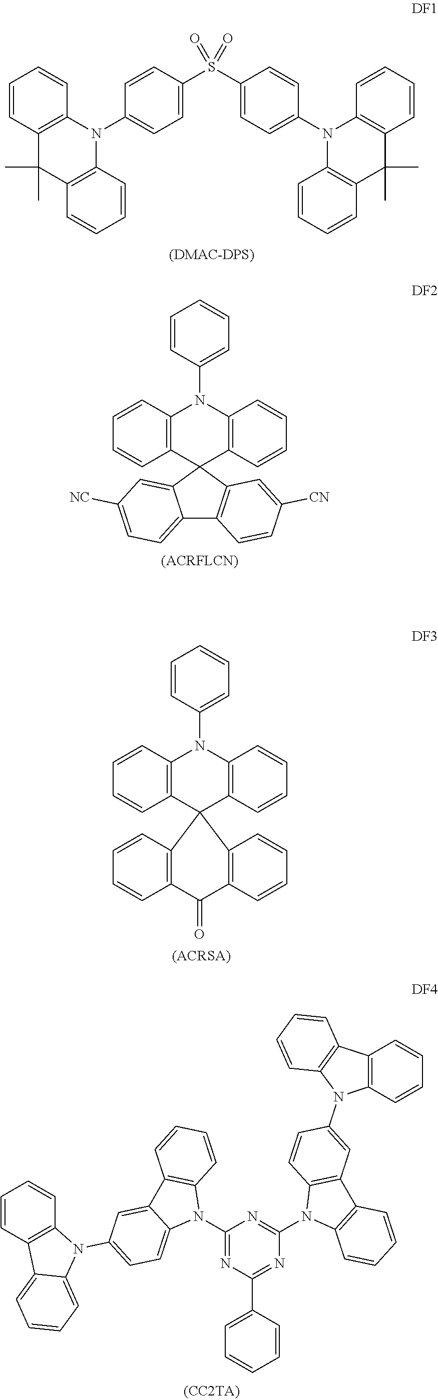

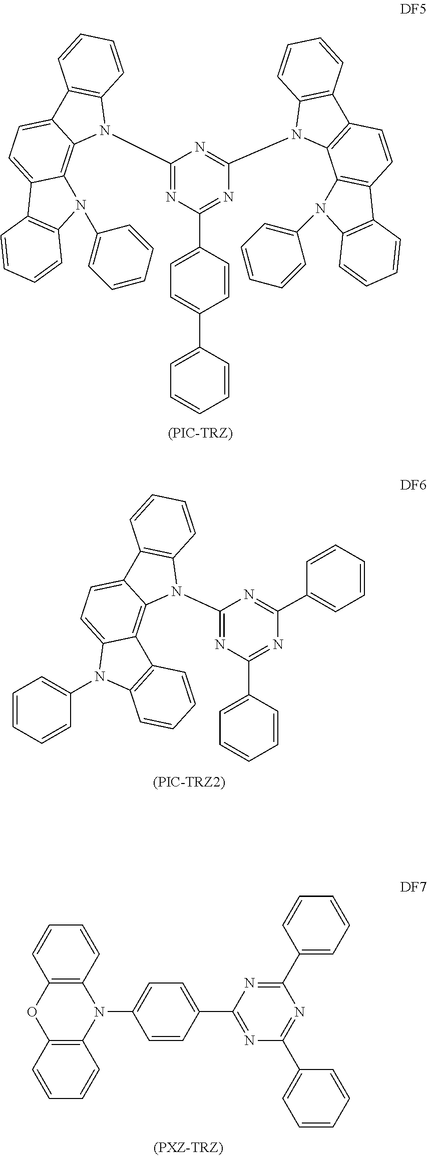 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-c3ccc(N4c5ccccc5Oc5ccccc54)cc3)n2)cc1]

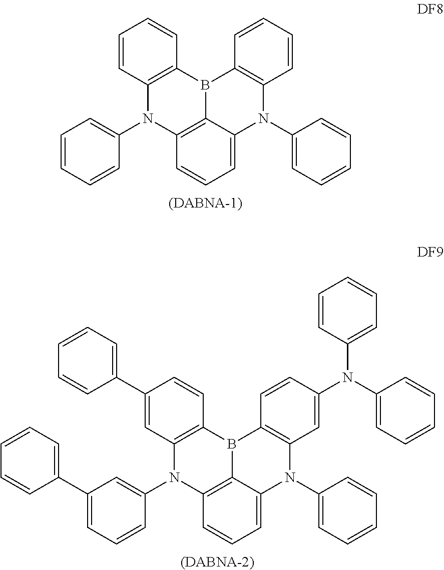

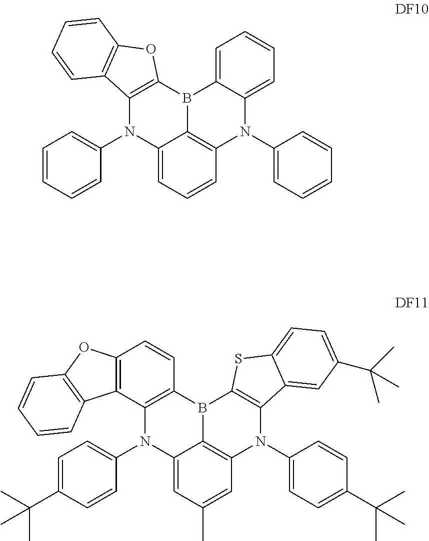 [SMILES: c1ccc(N2c3ccccc3B3c4oc5ccccc5c4N(c4ccccc4)c4cccc2c43)cc1 ; Cc1cc2c3c(c1)N(c1ccc(C(C)(C)C)cc1)c1c(ccc4oc5ccccc5c14)B3c1sc3ccc(C(C)(C)C)cc3c1N2c1ccc(C(C)(C)C)cc1]

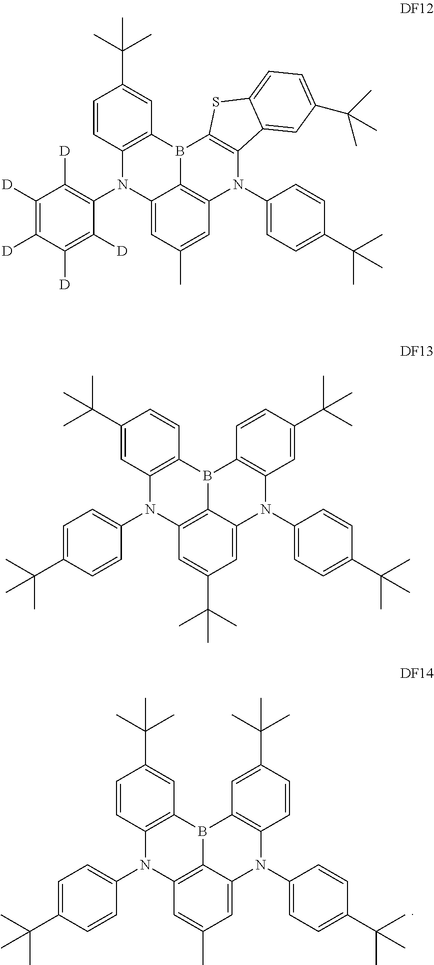

### Quantum Dots

The emission layer 130 may include quantum dots.

The term “quantum dots” as used herein refers to crystals of a semiconductor compound and may include any suitable material capable of emitting light of one or more emission wavelengths according to the size of the crystals.

The diameter of the quantum dots may be, for example, in a range of about 1 nm to about 10 nm.

The quantum dots may be synthesized by a wet chemical process, a metal organic chemical vapor deposition process, a molecular beam epitaxy process, or any process similar thereto.

The wet chemical process may be a method including mixing a precursor material with an organic solvent and then growing quantum dot particle crystals. If (e.g., when) the crystals grow, the organic solvent naturally acts as a dispersant coordinated on the surface of the quantum dot crystals and controls the growth of the crystals so that the growth of quantum dot particles may be controlled through a process which costs lower and is easier than vapor deposition methods, such as metal organic chemical vapor deposition (MOCVD) and/or molecular beam epitaxy (MBE).

The quantum dots may include: a Group II-VI semiconductor compound; a Group III-V semiconductor compound; a Group III-VI semiconductor compound; a Group I-III-VI semiconductor compound; a Group IV-VI semiconductor compound; a Group IV element or compound; or any combination thereof.

Examples of the Group II-VI semiconductor compound may include: a binary compound, such as CdS, CdSe, CdTe, ZnS, ZnSe, ZnTe, ZnO, HgS, HgSe, HgTe, MgSe, and/or MgS; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and/or MgZnS; a quaternary compound, such as CdZnSeS, CdZnSeTe, CdZnSTe, CdHgSeS, CdHgSeTe, CdHgSTe, HgZnSeS, HgZnSeTe, and/or HgZnSTe; or any combination thereof.

Examples of the Group III-V semiconductor compound may include: a binary compound, such as GaN, GaP, GaAs, GaSb, AlN, AlP, AlAs, AlSb, InN, InP, InAs, and/or InSb; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, and/or InPSb; a quaternary compound, such as GaAlNP, GaAlNAs, GaAlNSb, GaAlPAs, GaAlPSb, GalnNP, GalnNAs, GalnNSb, GalnPAs, GalnPSb, InAlNP, InAlNAs, InAlNSb, InAlPAs, and/or InAlPSb; or any combination thereof. In one or more embodiments, the Group III-V semiconductor compound may further include a Group II element. Examples of the Group III-V semiconductor compound further including a Group II element may include InZnP, InGaZnP, InAlZnP, and/or the like.

Examples of the Group III-VI semiconductor compound may include: a binary compound, such as GaS, GaSe, GazSes, GaTe, InS, InSe, In₂S₃, In₂Se₃, and/or InTe; a ternary compound, such as InGaS₂ and/or InGaSe₃; or any combination thereof.

Examples of the Group I-III-VI semiconductor compound may include: a ternary compound, such as AgInS, AgInS₂, CuInS, CuInS₂, CuGaO₂, AgGaO₂, and/or AgAlO₂; a quaternary compound, such as AgInGaS, AgInGaS₂, AgInGaSe, AgInGaSe₂, CuInGaS, and/or CuInGaS₂; or any combination thereof.

Examples of the Group IV-VI semiconductor compound may include: a binary compound, such as SnS, SnSe, SnTe, PbS, PbSe, and/or PbTe; a ternary compound, such as SnSeS, SnSeTe, SnSTe, PbSeS, PbSeTe, PbSTe, SnPbS, SnPbSe, and/or SnPbTe; a quaternary compound, such as SnPbSSe, SnPbSeTe, and/or SnPbSTe; or any combination thereof.

Examples of the Group IV element or compound may include: a single element, such as Si and/or Ge; a binary compound, such as SiC and/or SiGe; or any combination thereof.

Each element included in a multi-element compound, such as the binary compound, the ternary compound, and the quaternary compound, may be present at a uniform (e.g., substantially uniform) concentration or non-uniform concentration in a particle.

In one or more embodiments, the quantum dots may have a single structure in which the concentration of each element in the quantum dots is uniform (e.g., substantially uniform), or a core-shell dual structure. For example, a material included in the core and a material included in the shell may be different from each other.

The shell of the quantum dots may act as a protective layer that prevents chemical degeneration (or reduces a degree or occurrence of chemical degeneration) of the core to maintain semiconductor characteristics, and/or as a charging layer that imparts or increases electrophoretic characteristics to the quantum dots. The shell may be a single layer or a multi-layer. The interface between the core and the shell may have a concentration gradient in which the concentration of an element that exists in the shell decreases toward the center of the core.

Examples of the shell of the quantum dots may include: an oxide of metal, metalloid, or non-metal; a semiconductor compound; or any combination thereof. Examples of the oxide of metal, metalloid, or non-metal may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO; a ternary compound, such as MgAl₂O₄, CoFe₂O₄, NiFe₂O₄, and/or CoMn₂O₄; or any combination thereof. Examples of the semiconductor compound may include, as described in one or more embodiments: a Group II-VI semiconductor compound; a Group III-V semiconductor compound; a Group III-VI semiconductor compound; a Group I-III-VI semiconductor compound; a Group IV-VI semiconductor compound; or any combination thereof. For example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

The quantum dots may have a full width at half maximum (FWHM) of an emission wavelength spectrum of about 45 nm or less, about 40 nm or less, or for example, about 30 nm or less. If (e.g., when) the FWHM of the quantum dots is within the foregoing ranges, the quantum dots may have improved or enhanced color purity and/or improved or enhanced color reproducibility. In one or more embodiments, because light emitted through the quantum dots is emitted in all directions, the wide viewing angle may be improved or enhanced.

In one or more embodiments, the quantum dots may be in the form of a spherical particle (e.g., a substantially spherical particle), a pyramidal particle (e.g., a substantially pyramidal particle), a multi-arm particle (e.g., a substantially multi-arm particle), a cubic nanoparticle (e.g., a substantially cubic nanoparticle), a nanotube particle (e.g., a substantially nanotube particle), a nanowire particle (e.g., a substantially nanowire particle), a nanofiber particle (e.g., a substantially nanofiber particle), a nanoplate particle (e.g., a substantially nanoplate particle), and/or the like.

Because the energy band gap may be adjusted by controlling the size of the quantum dots, light having one or more wavelength bands may be obtained from the quantum dot-containing emission layer. In one or more embodiments, by using quantum dots of different sizes, a light-emitting device that emits light of one or more wavelengths may be implemented. In more detail, the size of the quantum dots may be selected to emit red light, green light, and/or blue light. In one or more embodiments, the size of the quantum dot may be configured (e.g., controlled or adjusted) to emit white light by combination of light of one or more suitable colors.

### Electron Transport Region 140

The electron transport region 140 may have i) a single-layer structure consisting of (e.g., including) a single layer consisting of (e.g., including) a single material, ii) a single-layer structure consisting of (e.g., including) a single layer including a plurality of different materials, or iii) a multi-layer structure including a plurality of layers including a plurality of different materials.

The electron transport region 140 may include a buffer layer, a hole-blocking layer, an electron control layer, an electron transport layer, an electron injection layer, or any combination thereof.

In one or more embodiments, the electron transport region 140 may have an electron transport layer/electron injection layer structure, a hole-blocking layer/electron transport layer/electron injection layer structure, an electron control layer/electron transport layer/electron injection layer structure, or a buffer layer/electron transport layer/electron injection layer structure, wherein the constituent layers of each structure are stacked sequentially from the emission layer 130.

The electron transport region 140 (e.g., the buffer layer, the hole-blocking layer, the electron control layer, or the electron transport layer in the electron transport region 140) may include a metal-free compound including at least one π electron-deficient nitrogen-containing C₁-C₆₀ heterocyclic group.

In one or more embodiments, the electron transport region 140 may include a compound represented by Formula 601:

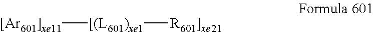

wherein, in Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each be the same as defined with respect to Q₁, xe21 may be 1, 2, 3, 4, or 5, and
at least one selected from among Ar₆₀₁, L₆₀₁, and R₆₀₁ may each independently be a π electron-deficient nitrogen-containing C₁-C₆₀ heterocyclic group unsubstituted or substituted with at least one R₁₀ₐ.

In one or more embodiments, if (e.g., when) xe11 in Formula 601 is 2 or more, two or more of Ar₆₀₁ may be linked to each other via a single bond (e.g., a single covalent bond).

In one or more embodiments, Ar₆₀₁ in Formula 601 may be an anthracene group unsubstituted or substituted with at least one R₁₀ₐ.

In one or more embodiments, the electron transport region 140 may include a compound represented by Formula 601-1:

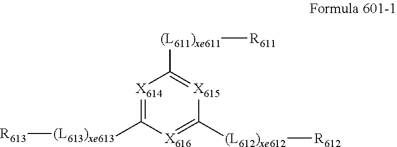

wherein, in Formula 601-1,
X₆₁₄ may be N or C(R₆₁₄), X₆₁₅ may be N or C(R₆₁₅), X₆₁₆ may be N or C(R₆₁₆), and at least one selected from among X₆₁₄ to X₆₁₆ may be N,
L₆₁₁ to L₆₁₃ may each be the same as defined with respect to L₆₀₁, xe611 to xe613 may each be the same as defined with respect to xe1,
R₆₁₁ to R₆₁₃ may each be the same as defined with respect to R₆₀₁, and R₆₁₄ to R₆₁₆ may each independently be hydrogen, deuterium, —F, —Cl, —Br, —I,
a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

In one or more embodiments, xe1 and xe611 to xe613 in Formulae 601 and 601-1 may each independently be 0, 1, or 2.

The electron transport region 140 may include: one selected from among Compounds ET1 to ET45; 2,9-dimethyl-4,7-diphenyl-1,10-phenanthroline (BCP); 4,7-diphenyl-1,10-phenanthroline (Bphen); Alq3; BAlq; TAZ; NTAZ; or any combination thereof:

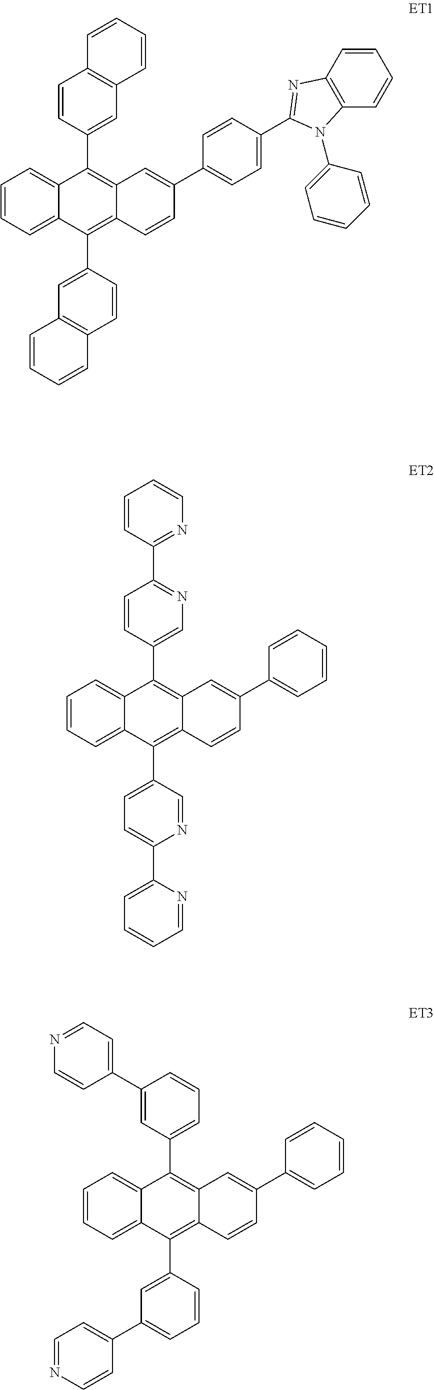 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

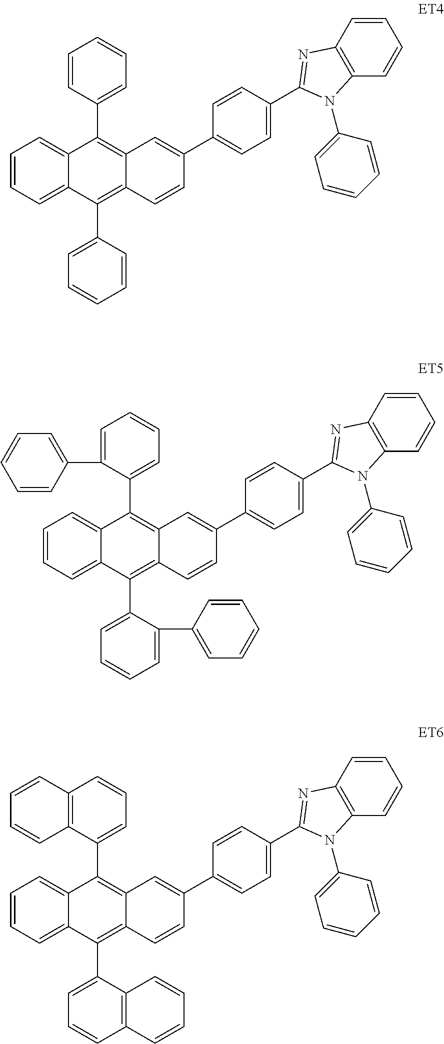 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

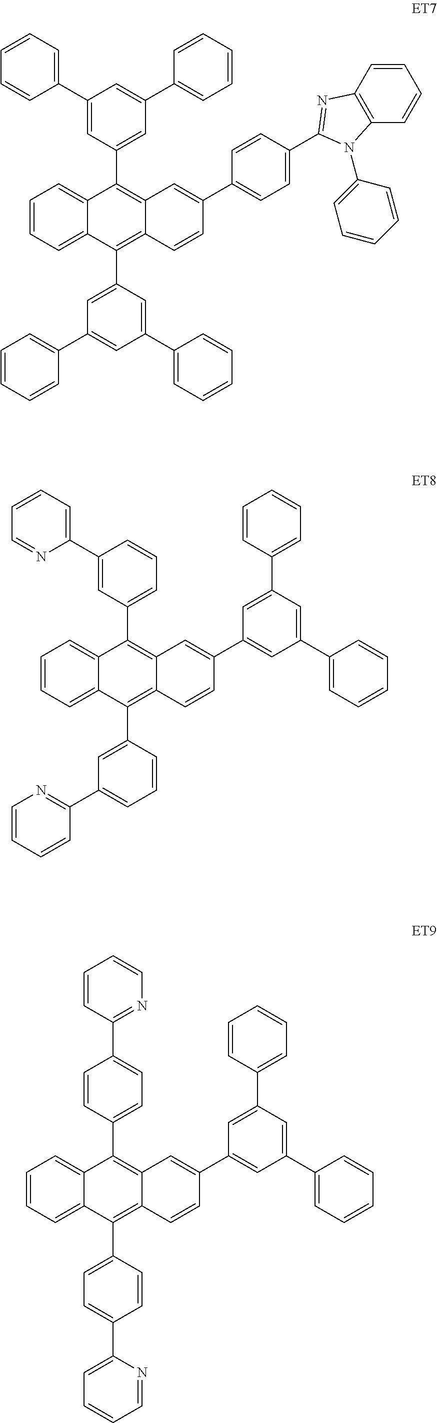 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

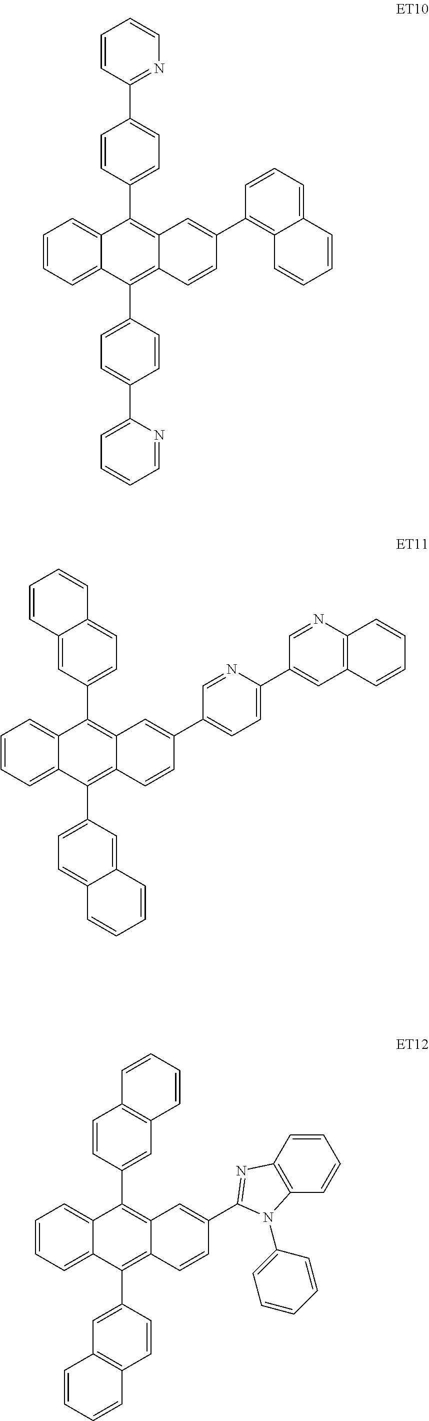 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

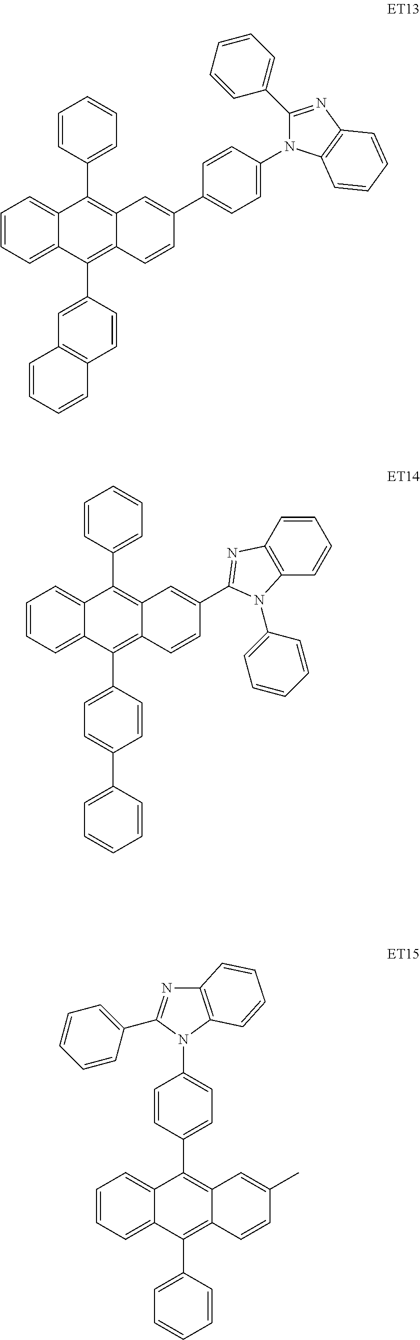 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

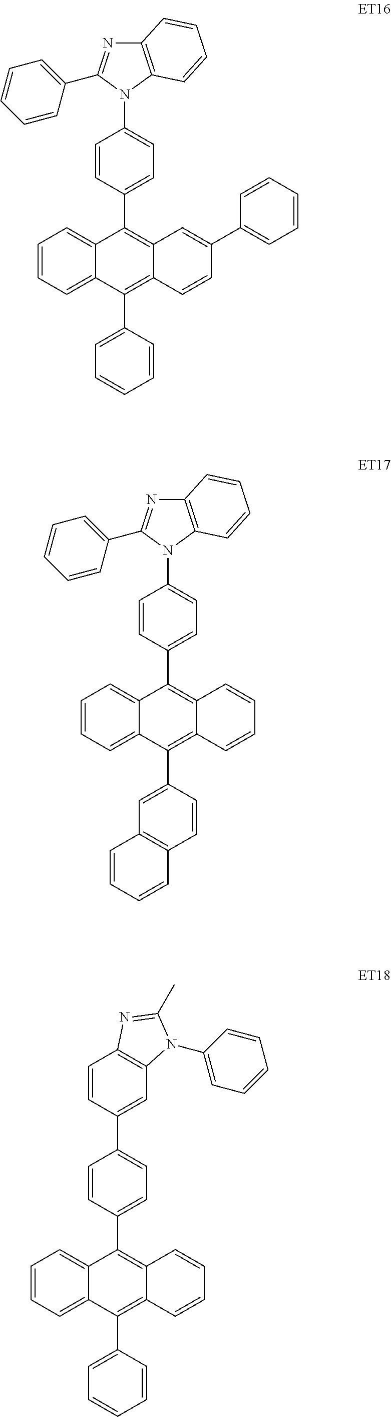 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

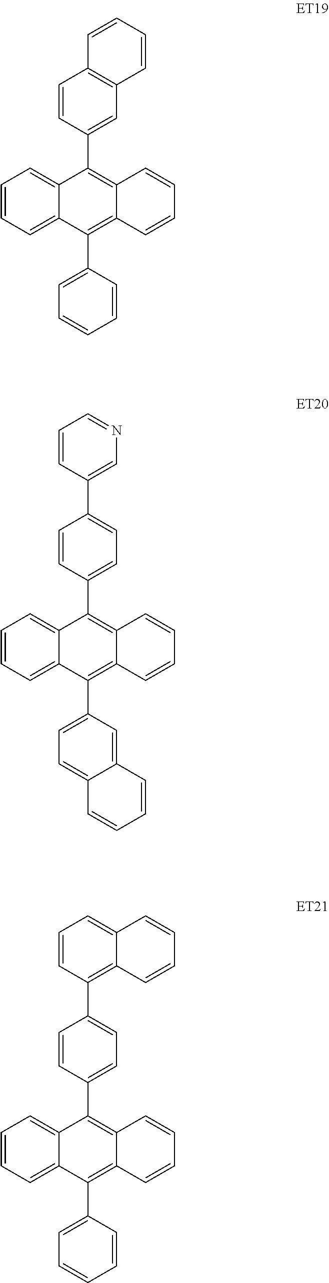

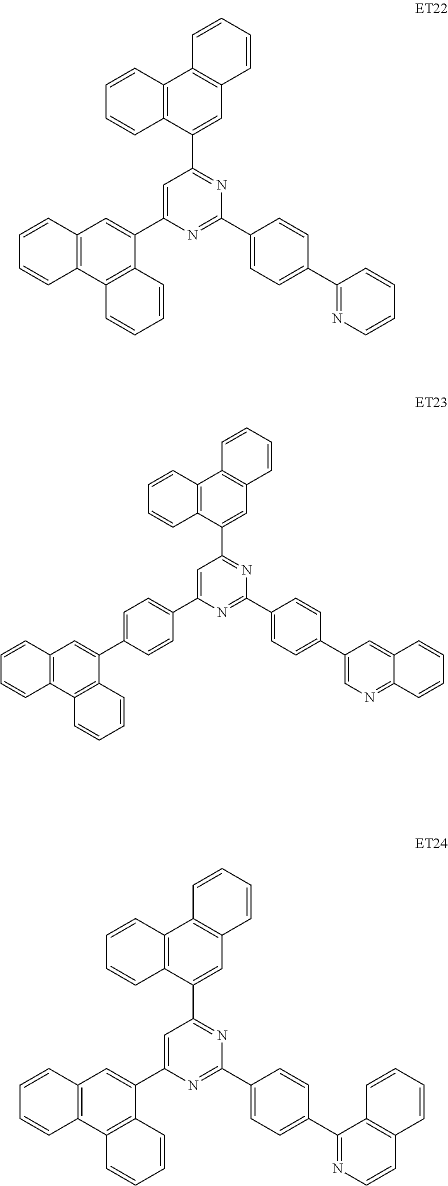 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

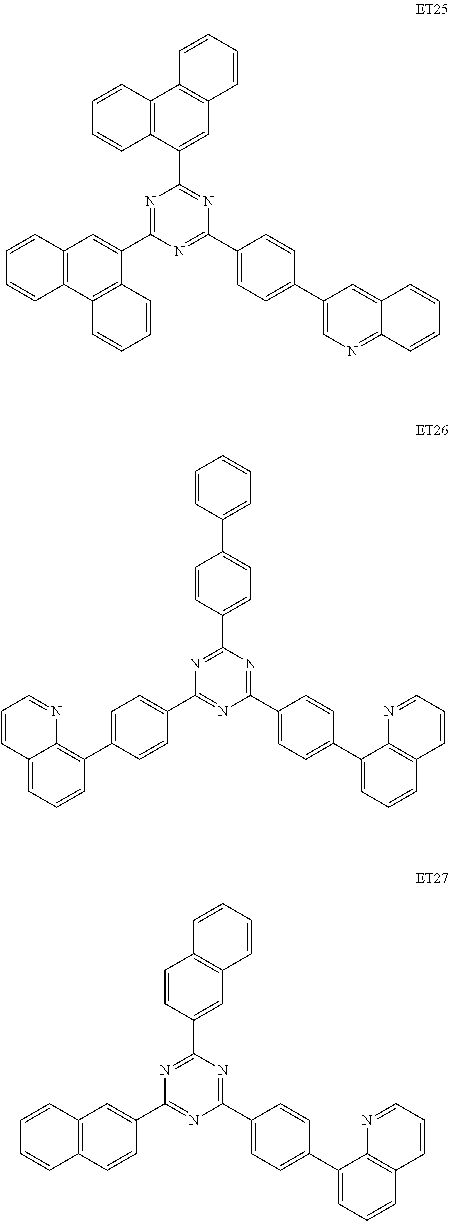 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

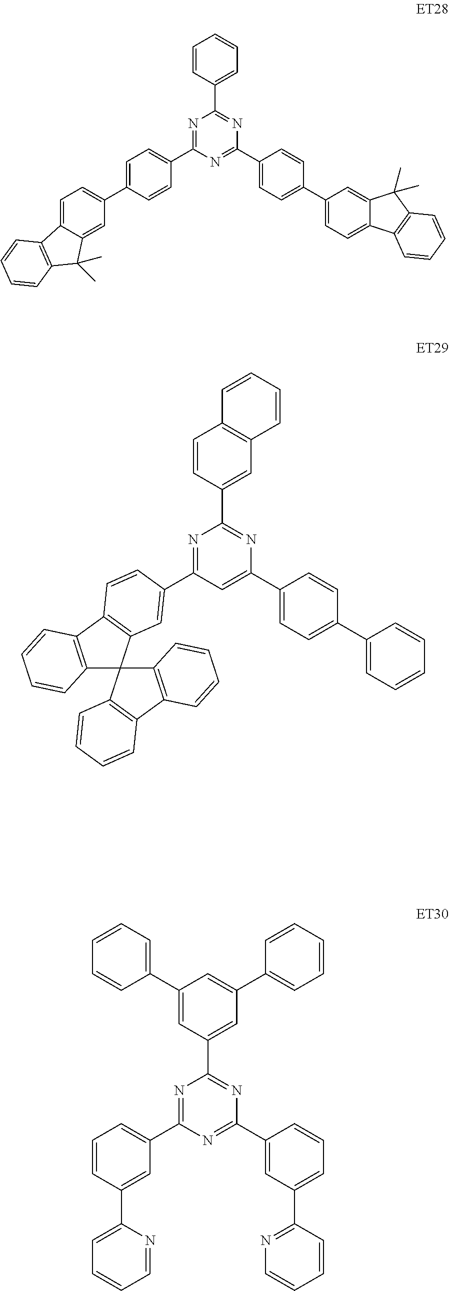 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

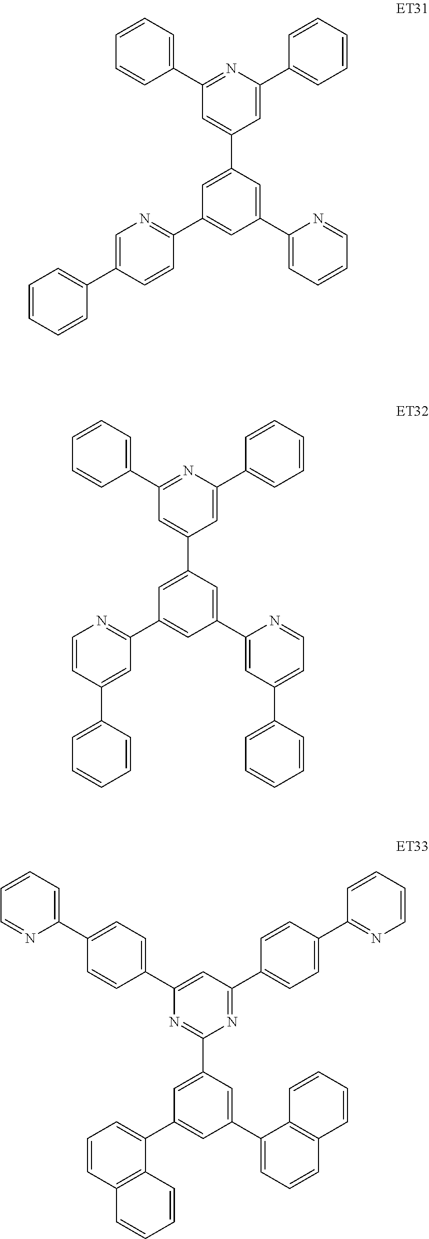 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

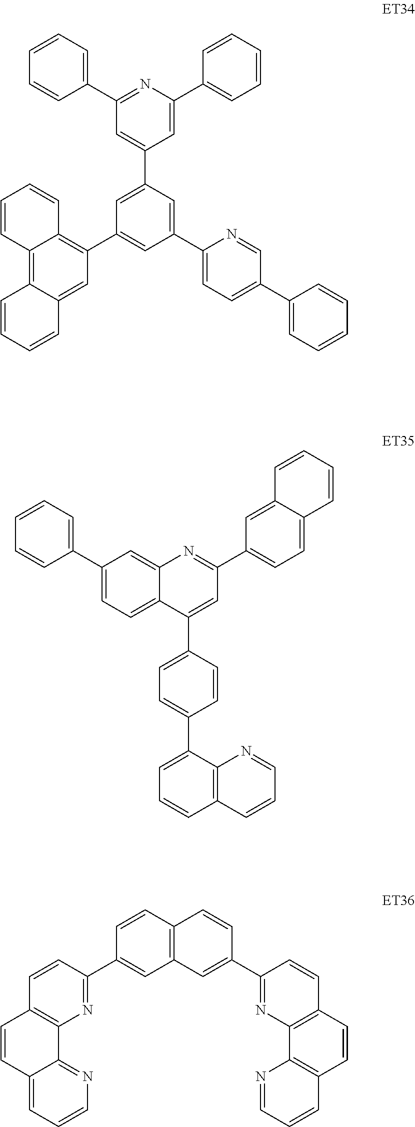 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

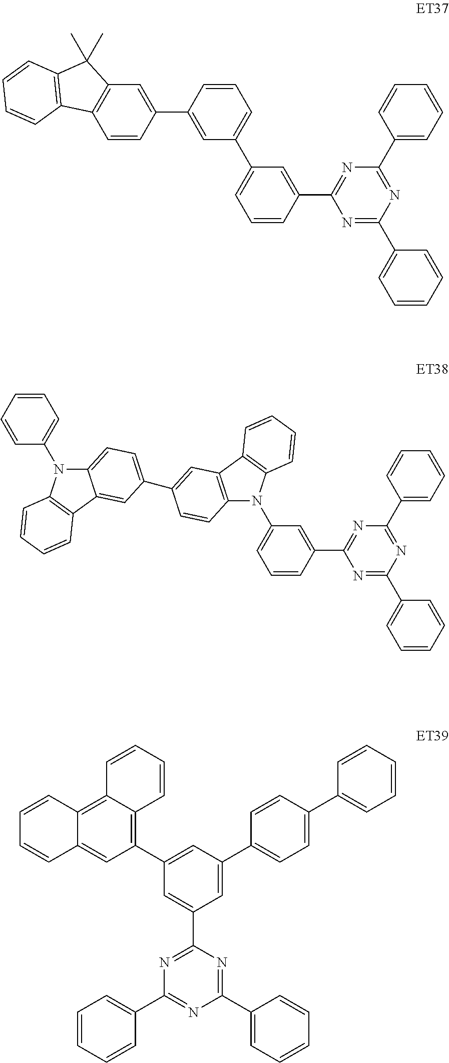 [SMILES: CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1]

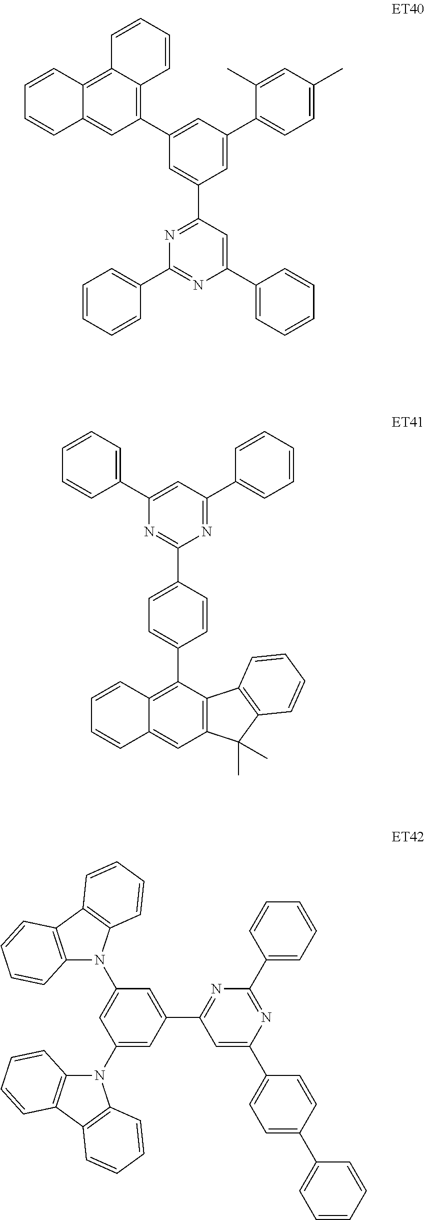 [SMILES: Cc1ccc(-c2cc(-c3cc(-c4ccccc4)nc(-c4ccccc4)n3)cc(-c3cc4ccccc4c4ccccc34)c2)c(C)c1 ; CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

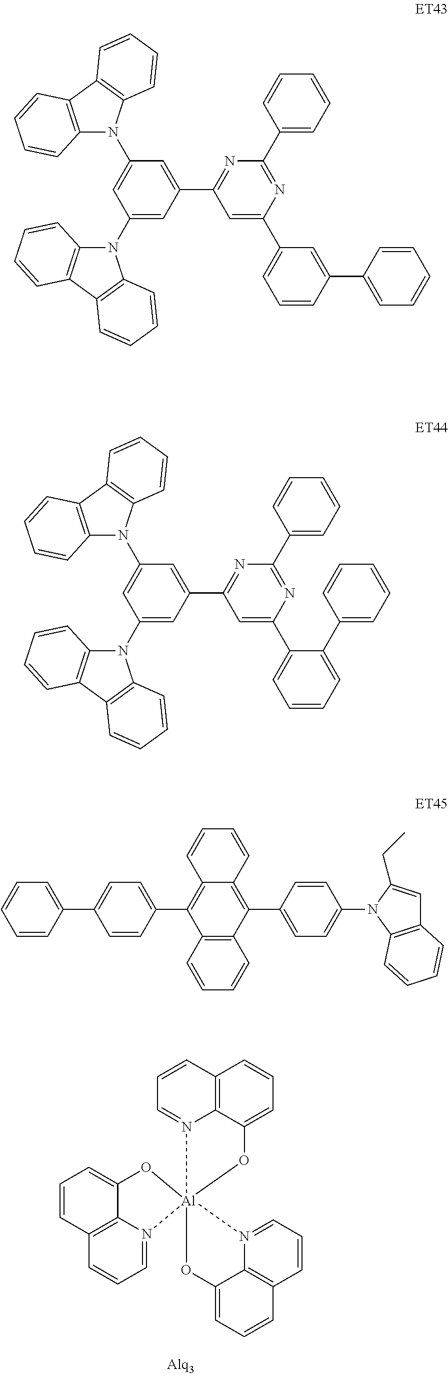

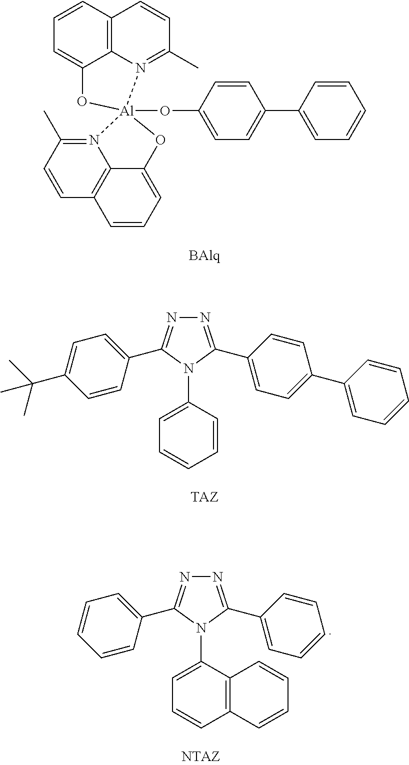

The thickness of the electron transport region 140 may be in a range of about 100 Å to about 5,000 Å, for example, about 160 Å to about 4,000 Å. If (e.g., when) the electron transport region 140 includes a buffer layer, a hole-blocking layer, an electron control layer, an electron transport layer, or any combination thereof, the thickness of the buffer layer, the hole-blocking layer, or the electron control layer may be in a range of about 10 Å to about 1,000 Å, for example, about 30 Å to about 300 Å, and the thickness of the electron transport layer may be in a range of about 100 Å to about 1,000 Å, for example, about 150 Å to about 500 Å. If (e.g., when) the thicknesses of the buffer layer, the hole-blocking layer, the electron control layer, the electron transport layer, and/or the electron transport region 140 are within the foregoing ranges, satisfactory electron-transporting characteristics may be obtained without a substantial increase in driving voltage.

The electron transport region 140 (e.g., the electron transport layer in the electron transport region 140) may further include, in addition to the materials as described in one or more embodiments, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of the alkali metal complex or the alkaline earth-metal complex may include hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenylbenzimidazole, hydroxyphenylbenzothiazole, bipyridine, phenanthroline, cyclopentadiene, or any combination thereof.

In one or more embodiments, the metal-containing material may include a Li complex. The Li complex may include, for example, Compound ET-D1 (LiQ) or ET-D2:

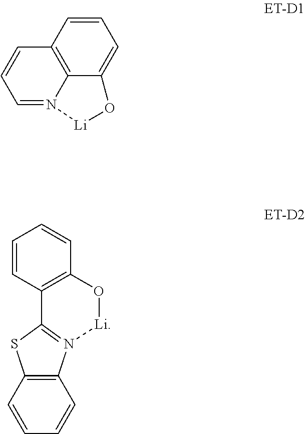

The electron transport region 140 may include an electron injection layer that facilitates the injection of electrons from the second electrode 150. The electron injection layer may directly contact the second electrode 150, but embodiments of the present disclosure are not limited thereto.

The electron injection layer may have i) a single-layer structure consisting of (e.g., including) a single layer consisting of (e.g., including) a single material, ii) a single-layer structure consisting of (e.g., including) a single layer including a plurality of different materials, or iii) a multi-layer structure including a plurality of layers including a plurality of different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (e.g., fluorides, chlorides, bromides, iodides, and/or the like), or tellurides of the alkali metal, the alkaline earth metal, and the rare earth metal, or any combination thereof.

The alkali metal-containing compound may include: an alkali metal oxide, such as Li₂O, Cs₂O, and/or K₂O; an alkali metal halide, such as LiF, NaF, CsF, KF, LiI, NaI, CsI, and/or KI; or any combination thereof. The alkaline earth metal-containing compound may include an alkaline earth metal compound, such as BaO, SrO, CaO, BaₓSr₁₋ₓO (wherein x is a real number satisfying 0<x<1), and/or BaₓCa₁₋ₓO (wherein x is a real number satisfying 0<x<1). The rare earth metal-containing compound may include YbF₃, ScF₃, SC₂O₃, Y₂O₃, Ce₂O₃, GdF₃, TbF₃, YbI₃, ScI₃, TbI₃, or any combination thereof. In one or more embodiments, the rare earth metal-containing compound may include a lanthanide metal telluride. Examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, HO₂Te₃, Er₂Te₃, Tm₂Te₃, Yb₂Te₃, Lu₂Te₃, and/or the like.

The alkali metal complex, the alkaline earth-metal complex, and the rare earth metal complex may include i) one of ions selected from among the alkali metal, the alkaline earth metal, and the rare earth metal and ii) a ligand bonded to the metal ion, for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or any combination thereof.

The electron injection layer may consist of (e.g., include) an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described in one or more embodiments. In one or more embodiments, the electron injection layer may further include an organic material (e.g., a compound represented by Formula 601).

In one or more embodiments, the electron injection layer may consist of (e.g., include) i) an alkali metal-containing compound (e.g., an alkali metal halide), or ii) a) an alkali metal-containing compound (e.g., an alkali metal halide), and b) an alkali metal, an alkaline earth metal, a rare earth metal, or any combination thereof. In one or more embodiments, the electron injection layer may be a KI:Yb co-deposited layer, an RbI:Yb co-deposited layer, a LiF:Yb co-deposited layer, and/or the like.

If (e.g., when) the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, or any combination thereof may be uniformly (e.g., substantially uniformly) or non-uniformly dispersed in a matrix including the organic material.

The thickness of the electron injection layer may be in a range of about 1 Å to about 100 Å, for example, about 3 Å to about 90 Å. If (e.g., when) the thickness of the electron injection layer is within the foregoing ranges, satisfactory electron injection characteristics may be obtained without a substantial increase in driving voltage.

### Second Electrode 150

The second electrode 150 may be on the electron transport region 140. The second electrode 150 may be a cathode, which is an electron injection electrode, and as a material to form or provide the second electrode 150, a metal, an alloy, an electrically conductive compound, or any combination thereof, each having a low-work function, may be used.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a transflective electrode, or a reflective electrode.

The second electrode 150 may have a single-layer structure or a multi-layer structure including a plurality of layers. The thickness of the second electrode 150 may be in a range of about 500 Å to about 3,000 Å.

### Capping Layer

A first capping layer may be arranged or provided outside the first electrode 110, and/or a second capping layer may be arranged or provided outside the second electrode 150.

In one or more embodiments, the light-emitting device 10 may have a structure in which the first capping layer, the first electrode 110, the emission layer 130, and the second electrode 150 are sequentially stacked in the stated order.

In one or more embodiments, the light-emitting device 10 may have a structure in which the first electrode 110, the emission layer 130, the second electrode 150, and the second capping layer are sequentially stacked in the stated order.

In one or more embodiments, the light-emitting device 10 may have a structure in which the first capping layer, the first electrode 110, the emission layer 130, the second electrode 150, and the second capping layer are sequentially stacked in the stated order.

Light generated in the emission layer 130 of the light-emitting device 10 may be extracted toward the outside through the first electrode 110, which is a transflective electrode or a transmissive electrode, and the first capping layer. Light generated in the emission layer 130 of the light-emitting device 10 may be extracted toward the outside through the second electrode 150, which is a transflective electrode or a transmissive electrode, and the second capping layer.

The first capping layer and the second capping layer may increase or enhance external emission efficiency according to the principle of constructive interference. In one or more embodiments, the light extraction efficiency of the light-emitting device 10 may be increased or enhanced, and thus, the luminescence efficiency of the light-emitting device 10 may be improved or enhanced.

Each of the first capping layer and the second capping layer may include a material having a refractive index of about 1.6 or more (at about 520 nm to about 630 nm).

The first capping layer and the second capping layer may each independently be an organic capping layer including an organic material, an inorganic capping layer including an inorganic material, or an organic-inorganic composite capping layer including an organic material and an inorganic material.

At least one selected from the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may optionally be substituted with a substituent including O, N, S, Se, Si, F, Cl, Br, I, or any combination thereof. In one or more embodiments, at least one selected from the first capping layer and the second capping layer may each independently include an amine group-containing compound.

In one or more embodiments, at least one selected from the first capping layer and the second capping layer may each independently include a compound represented by Formula 201, a compound represented by Formula 202, or any combination thereof.

In one or more embodiments, at least one selected from the first capping layer and the second capping layer may each independently include: one selected from among Compounds HT28 to HT33; one selected from among Compounds CP1 to CP6; β-NPB; or any combination thereof:

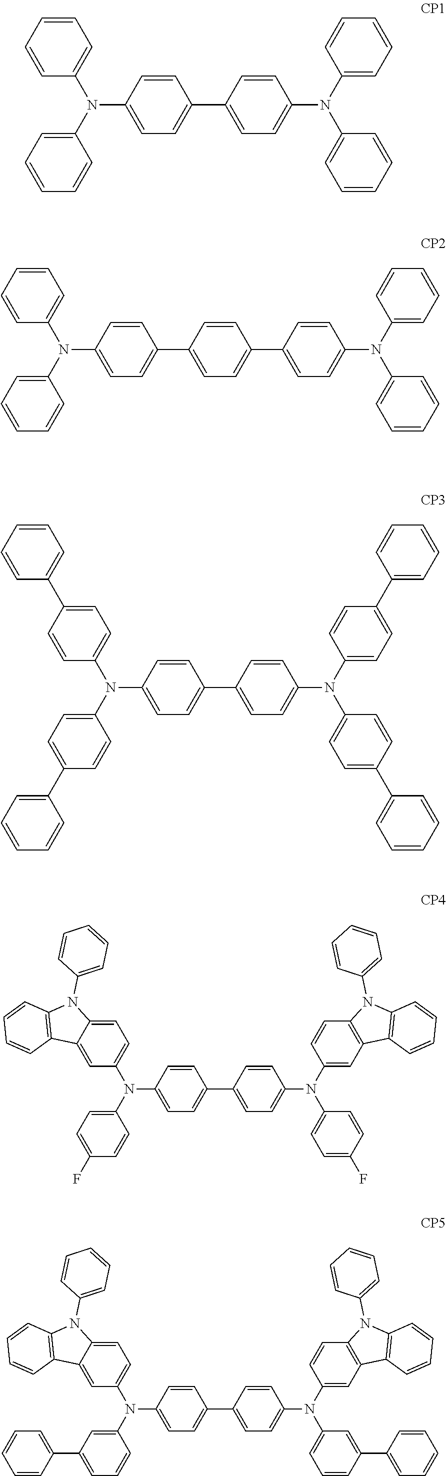 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

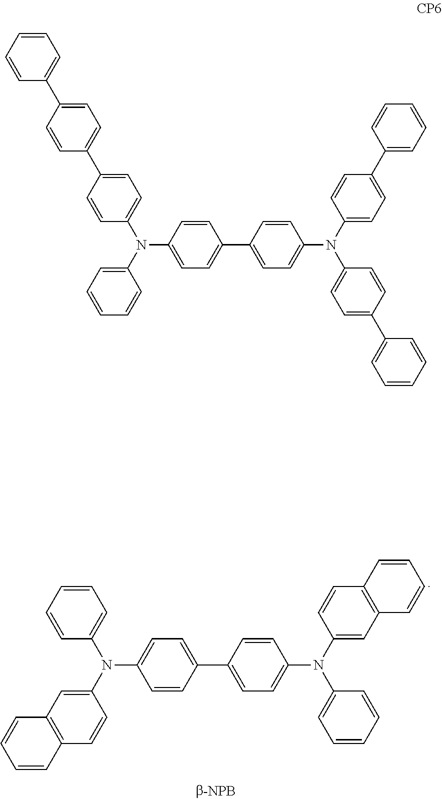 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

### Film

The electronic apparatus may include a film. The film may be, for example, an optical member (or a light control means) (e.g., a color filter, a color conversion member, a capping layer, a light extraction efficiency enhancement layer, a selective light-absorbing layer, a polarizing layer, a quantum dot-containing layer, and/or the like), a light-blocking member (e.g., a light-reflecting layer, a light-absorbing layer, and/or the like), a protective member (e.g., an insulating (e.g., electrically insulating) layer, a dielectric layer, and/or the like), and/or the like.

### Electronic Apparatus

The light-emitting device 10 and the optoelectronic device 30, 31, or 32 may be included in one or more suitable electronic apparatuses.

The electronic apparatus (e.g., a light-emitting apparatus) may further include, in addition to the light-emitting device 10 and the optoelectronic device 30, 31, or 32, i) a color filter, ii) a color conversion layer, or iii) a color filter and a color conversion layer. The color filter and/or the color conversion layer may be arranged or provided in at least one direction in which light emitted from the light-emitting device 10 travels. For example, light emitted from the light-emitting device 10 may be blue light or white light. More details on the light-emitting device 10 may be as described herein. The color conversion layer may include quantum dots. The quantum dots may be, for example, quantum dots as described in one or more embodiments.

The electronic apparatus may include a first substrate. The first substrate may include a plurality of subpixel areas, the color filter may include a plurality of color filter areas that respectively correspond to the subpixel areas, and the color conversion layer may include a plurality of color conversion areas that respectively correspond to the subpixel areas.

A pixel-defining film may be arranged or provided among the subpixel areas to define each of the subpixel areas.

The color filter may further include a plurality of color filter areas and light-shielding patterns arranged or provided among the color filter areas, and the color conversion layer may further include a plurality of color conversion areas and light-shielding patterns arranged or provided among the color conversion areas.

The plurality of color filter areas (or the plurality of color conversion areas) may include: a first area that emits first color light; a second area that emits second color light; and/or a third area that emits third color light, wherein the first color light, the second color light, and/or the third color light may have different maximum emission wavelengths. For example, the first color light may be red light, the second color light may be green light, and the third color light may be blue light. For example, the plurality of color filter areas (or the plurality of color conversion areas) may include quantum dots. In more detail, the first area may include red quantum dots, the second area may include green quantum dots, and the third area may not include quantum dots. More details on the quantum dots may be as described herein. The first area, the second area, and/or the third area may each further include a scatterer (e.g., a light scatterer).

In one or more embodiments, the light-emitting device 10 may emit first light, the first area may absorb the first light to emit first-1 color light, the second area may absorb the first light to emit second-1 color light, and the third area may absorb the first light to emit third-1 color light. In one or more embodiments, the first-1 color light, the second-1 color light, and the third-1 color light may have different maximum emission wavelengths. In more detail, the first light may be blue light, the first-1 color light may be red light, the second-1 color light may be green light, and the third-1 color light may be blue light.

The electronic apparatus may further include a thin-film transistor, in addition to the optoelectronic device 30, 31, or 32 and the light-emitting device 10. The thin-film transistor may include a source electrode, a drain electrode, and an active layer, and any one selected from the source electrode and the drain electrode may be electrically connected to any one selected from the first electrode 110 and the second electrode 150 of the light-emitting device 10.

The thin-film transistor may further include a gate electrode, a gate insulating (e.g., electrically insulating) film, and/or the like.

The active layer may include crystalline silicon, amorphous (e.g., non-crystalline) silicon, an organic semiconductor, an oxide semiconductor, and/or the like.

The electronic apparatus may further include a sealing portion to seal the optoelectronic device 30, 31, or 32 and the light-emitting device 10. The sealing portion may be arranged or provided between the color filter and/or the color conversion layer and the optoelectronic device 30, 31, or 32 and/or the light-emitting device 10. The sealing portion may allow light from the light-emitting device 10 to be extracted to the outside and may concurrently (e.g., simultaneously) prevent ambient air and/or moisture from penetrating (or reduce a degree to or occurrence of which ambient air and/or moisture penetrate) into the optoelectronic device 30, 31, or 32 and the light-emitting device 10. The sealing portion may be a sealing substrate including a transparent (e.g., substantially transparent) glass substrate and/or a plastic substrate. The sealing portion may be a thin-film encapsulation layer including at least one layer of an organic layer and/or an inorganic layer. If (e.g., when) the sealing portion is a thin-film encapsulation layer, the electronic apparatus may be flexible.

One or more suitable functional layers may be additionally arranged or provided on the sealing portion, in addition to the color filter and/or the color conversion layer, according to the use of the electronic apparatus. Examples of the functional layers may include a touch screen layer, a polarizing layer, and/or the like. The touch screen layer may be a pressure-sensitive touch screen layer, a capacitive touch screen layer, and/or an infrared touch screen layer. The authentication apparatus may be, for example, a biometric authentication apparatus that authenticates an individual by using biometric information of a living body (e.g., fingertips, pupils, and/or the like).

The authentication apparatus may further include a biometric information collector, in addition to the optoelectronic device 30, 31, or 32 and the light-emitting device 10.

The electronic apparatus may be applied to one or more suitable displays, light sources, lighting, personal computers (e.g., mobile personal computers), mobile phones, digital cameras, electronic organizers, electronic dictionaries, electronic game machines, medical instruments (e.g., electronic thermometers, sphygmomanometers, blood glucose meters, pulse measurement devices, pulse wave measurement devices, electrocardiogram displays, ultrasonic diagnostic devices, or endoscope displays), fish finders, one or more suitable measuring instruments, meters (e.g., meters for a vehicle, an aircraft, and a vessel), projectors, sensors (e.g. sensors for vehicles and sensors for home), and/or the like.

### Electronic Equipment

The optoelectronic device 30, 31, or 32 may be included in one or more suitable electronic equipment.

For example, the electronic equipment including the optoelectronic device 30, 31, or 32 may be one selected from among a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality display, an augmented reality display, a vehicle, a video wall including a plurality of displays tiled together, a theater screen, a stadium screen, a phototherapy device, a signboard, a sensor for vehicles, a sensor for home, and a solar cell.

Because the optoelectronic device 30, 31, or 32 has excellent or suitable photoelectric characteristics, the electronic equipment including the optoelectronic device 30, 31, or 32 may have the function of an optical sensor, such as a fingerprint recognition sensor.

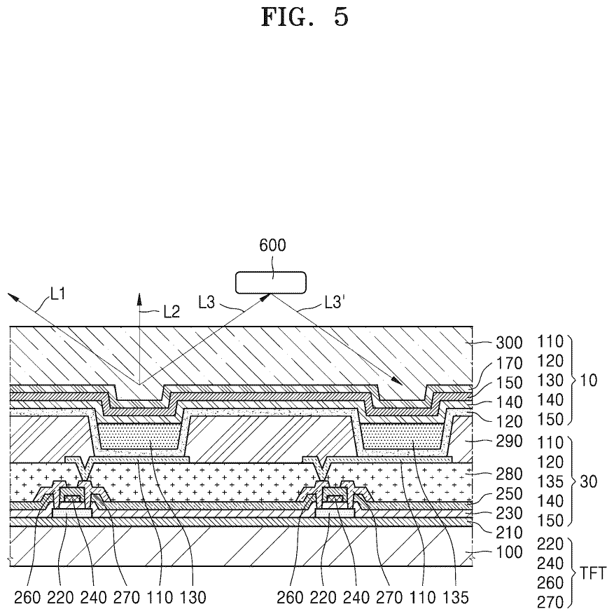

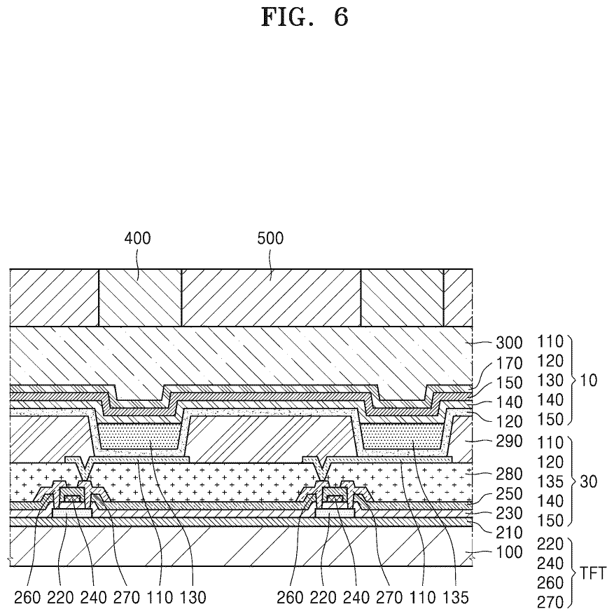

### Descriptions of FIGS. 5 and 6

FIG. 5 is a cross-sectional view of an electronic apparatus according to one or more embodiments.

The electronic apparatus of FIG. 5 may include a substrate 100, a thin-film transistor TFT, a light-emitting device 10, an optoelectronic device 30, and an encapsulation portion 300. The optoelectronic device 30 of FIG. 5 may be the optoelectronic device 30 as described with reference to FIG. 1, but embodiments of the present disclosure are not limited thereto. For example, the optoelectronic device 30 of FIG. 5 may be the optoelectronic device 31 of FIG. 2 or the optoelectronic device 32 of FIG. 3.

The substrate 100 may be a flexible substrate, a glass substrate, or a metal substrate. A buffer layer 210 may be on the substrate 100. The buffer layer 210 may prevent penetration (or reduce a degree or occurrence of penetration) of impurities through the substrate 100 and may provide a flat surface (e.g., a substantially flat surface) on the substrate 100.

The thin-film transistor TFT may be on the buffer layer 210. The thin-film transistor TFT may include an active layer 220, a gate electrode 240, a source electrode 260, and a drain electrode 270.

The active layer 220 may include an inorganic semiconductor, such as silicon and/or polysilicon, an organic semiconductor, and/or an oxide semiconductor and may include a source region, a drain region, and a channel region.

A gate insulating film 230 to insulate (e.g., to electrically insulate) the active layer 220 from the gate electrode 240 may be on the active layer 220, and the gate electrode 240 may be on the gate insulating film 230.

An interlayer insulating film 250 may be on the gate electrode 240. The interlayer insulating film 250 may be between the gate electrode 240 and the source electrode 260 to insulate the gate electrode 240 from the source electrode 260 and between the gate electrode 240 and the drain electrode 270 to insulate the gate electrode 240 from the drain electrode 270.

The source electrode 260 and the drain electrode 270 may be on the interlayer insulating film 250. The interlayer insulating film 250 and the gate insulating film 230 may be formed or provided to expose the source region and the drain region of the active layer 220, and the source electrode 260 and the drain electrode 270 may be arranged or provided in contact with the exposed portions of the source region and the drain region of the active layer 220.

The light-emitting device 10 and the optoelectronic device 30 may be on the thin-film transistor TFT.

The thin-film transistor TFT electrically connected to the light-emitting device 10 may transmit an electrical signal to drive the light-emitting device 10. The thin-film transistor TFT electrically connected to the optoelectronic device 30 may transmit an electrical signal generated by the optoelectronic device 30. The thin-film transistor TFT may be covered and protected by a passivation layer 280. The passivation layer 280 may include an inorganic insulating (e.g., electrically insulating) film, an organic insulating (e.g., electrically insulating) film, or any combination thereof. The light-emitting device 10 and the optoelectronic device 30 may be provided on the passivation layer 280.

The light-emitting device 10 may include a first electrode 110, a hole transport region 120, an emission layer 130, an electron transport region 140, and a second electrode 150. The optoelectronic device 30 may include a first electrode 110, a hole transport region 120, a photoactive layer 135, an electron transport region 140, and a second electrode 150. The first electrode 110 may be on the passivation layer 280. The passivation layer 280 may be arranged or provided to expose certain (e.g., set or predetermined) regions of the source electrode 260 and the drain electrode 270 without fully covering the source electrode 260 and the drain electrode 270, and the first electrode 110 may be arranged or provided to be connected to the exposed regions of the source electrode 260 and the drain electrode 270.

A pixel-defining film 290 including an insulating (e.g., electrically insulating) material may be on the first electrode 110. The pixel-defining film 290 may expose a certain (e.g., set or predetermined) region of the first electrode 110. The pixel-defining film 290 may be a polyimide-based organic film and/or a polyacrylic organic film.

The hole transport region 120 may be on the pixel-defining film 290. The hole transport region 120 included in the light-emitting device 10 and the hole transport region 120 included in the optoelectronic device 30 may be integrally formed or provided as a single body. The hole transport region 120 included in the light-emitting device 10 and the hole transport region 120 included in the optoelectronic device 30 may be on the pixel-defining film 290, may be connected to each other, may include substantially the same material, and may be formed or provided substantially at the same time (e.g., concurrently).

Each of the emission layer 130 and the photoactive layer 135 may be on the hole transport region 120. Each of the emission layer 130 and the photoactive layer 135 may overlap the certain (e.g., set or predetermined) region of the first electrode 110, which is exposed by the pixel-defining film 290.

The electron transport region 140 may be on the emission layer 130 and the photoactive layer 135. The electron transport region 140 included in the light-emitting device 10 and the electron transport region 140 included in the optoelectronic device 30 may be integrally formed or provided as a single body. The electron transport region 140 included in the light-emitting device 10 and the electron transport region 140 included in the optoelectronic device 30 may be on the pixel-defining film 290, may be connected to each other, may include substantially the same material, and may be formed or provided substantially at the same time (e.g., concurrently).

The second electrode 150 may be on the electron transport region 140. The second electrode 150 included in the light-emitting device 10 and the second electrode 150 included in the optoelectronic device 30 may be integrally formed or provided as a single body. The second electrode 150 included in the light-emitting device 10 and the second electrode 150 included in the optoelectronic device 30 may be on the pixel-defining film 290, may be connected to each other, may include substantially the same material, and may be formed or provided substantially at the same time (e.g., concurrently).

A capping layer 170 may be additionally formed or provided on the second electrode 150. The capping layer 170 may be formed or provided to cover the second electrode 150.

The encapsulation portion 300 may be on the capping layer 170. The encapsulation portion 300 may be on the light-emitting device 10 and the optoelectronic device 30 to protect the light-emitting device 10 and the optoelectronic device 30 from moisture and/or oxygen. The encapsulation portion 300 may include: an inorganic film including silicon nitride (e.g., Si₃N₄ or SiNₓ, wherein 0<x≤2), silicon oxide (e.g., SiOₓ, wherein 0<x≤2; e.g., SiO₂), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (e.g., polymethyl methacrylate, polyacrylic acid, and/or the like), an epoxy-based resin (e.g., aliphatic glycidyl ether (AGE) and/or the like), or any combination thereof; or any combination of the inorganic films and the organic films.

The light-emitting device 10 may emit lights L1, L2, and L3. For example, the lights L1, L2, and L3 may each be red light, green light, blue light, or near-infrared light.

The light L3 of the lights L1, L2, and L3 that have been emitted may be incident on an object 600 outside the electronic apparatus. For example, the object 600 may be a finger of a user of the electronic apparatus. A light L3′ reflected by the object 600 may be incident on the optoelectronic device 30.

The photoactive layer 135 may absorb the light L3′ that is incident on the optoelectronic device 30 to form or provide excitons. The excitons may generate holes and electrons. For example, the photoactive layer 135 may absorb light to generate an electric signal. In more detail, the first compound included in the photoactive layer 135 may serve as a donor to supply electrons, and the second compound included in the photoactive layer 135 may serve as an acceptor to receive electrons. For example, the optoelectronic device 30 may detect energy of the light L3′ and convert the detected energy into an electrical signal. In one or more embodiments, the optoelectronic device 30 may recognize the object 600 that has come into contact with (or approached) the electronic apparatus. In one or more embodiments, the optoelectronic device 30 including the photoactive layer 135 may serve as an optical sensor (e.g., a fingerprint recognition sensor).

FIG. 6 is a cross-sectional view of an electronic apparatus according to one or more embodiments.

The electronic apparatus of FIG. 6 is substantially the same as the electronic apparatus of FIG. 5, except that a light-shielding pattern 500 and a functional region 400 are additionally arranged or provided on the encapsulation portion 300. The functional region 400 may be i) a color filter area, ii) a color conversion area, or iii) a combination of the color filter area and the color conversion area. In one or more embodiments, the light-emitting device included in the electronic apparatus of FIG. 6 may be a tandem light-emitting device.

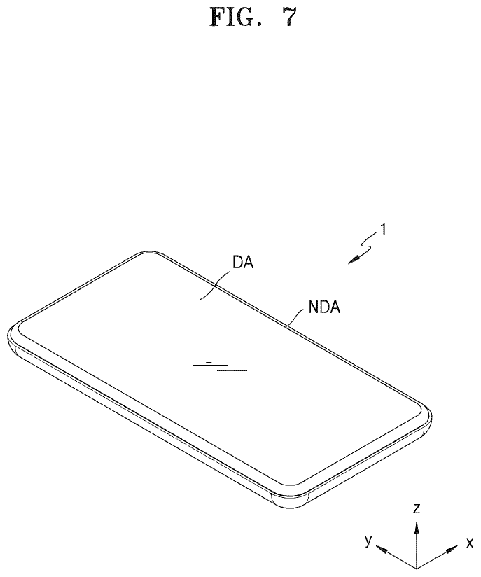

### Description of FIG. 7

FIG. 7 is a schematic perspective view of electronic equipment 1 including an optoelectronic device according to one or more embodiments. The electronic equipment 1 may be, as an apparatus that displays a moving image and/or a still image, portable electronic equipment, such as a mobile phone, a smartphone, a tablet personal computer (PC), a mobile communication terminal, an electronic notebook, an electronic book, a portable multimedia player (PMP), a navigation, and/or an ultra-mobile PC(UMPC), as well as one or more suitable products, such as a television, a laptop, a monitor, a billboard, and/or an Internet of things (IoT) device. The electronic equipment 1 may be such a product as described in one or more embodiments or a part thereof. In one or more embodiments, the electronic equipment 1 may be a wearable device, such as a smart watch, a watch phone, a glasses-type or kind display, and/or a head mounted display (HMD), or a part of the wearable device. However, embodiments of the present disclosure are not limited thereto. For example, the electronic equipment 1 may be a center information display (CID) arranged or provided on an instrument panel and a center fascia or dashboard of a vehicle, a room mirror display instead of a side mirror of a vehicle, an entertainment display for a rear seat of a vehicle, a display arranged or provided on the back of a front seat, a head up display (HUD) installed in the front of a vehicle or projected on a front window glass, or a computer generated hologram augmented reality head up display (CGH AR HUD). FIG. 7 illustrates one or more embodiments in which the electronic equipment 1 is a smartphone for convenience of explanation.

The electronic equipment 1 may include a display area DA and a non-display area NDA outside the display area DA. A display apparatus may implement an image through an array of a plurality of pixels that are two-dimensionally arranged or provided in the display area DA.

The non-display area NDA may be an area that does not display an image and may be entirely around (e.g., entirely surround) the display area DA. On the non-display area NDA, a driver to provide electrical signals or power to display devices arranged or provided on the display area DA may be arranged or provided. On the non-display area NDA, a pad, which is an area to which an electronic element or a printed circuit board may be electrically connected, may be arranged or provided.

In the electronic equipment 1, the length in an x-axis direction and the length in a y-axis direction may be different from each other. For example, as shown in FIG. 7, the length in the x-axis direction may be less than the length in the y-axis direction. In one or more embodiments, the length in the x-axis direction may be substantially the same as the length in the y-axis direction. In one or more embodiments, the length in the x-axis direction may be greater than the length in the y-axis direction.

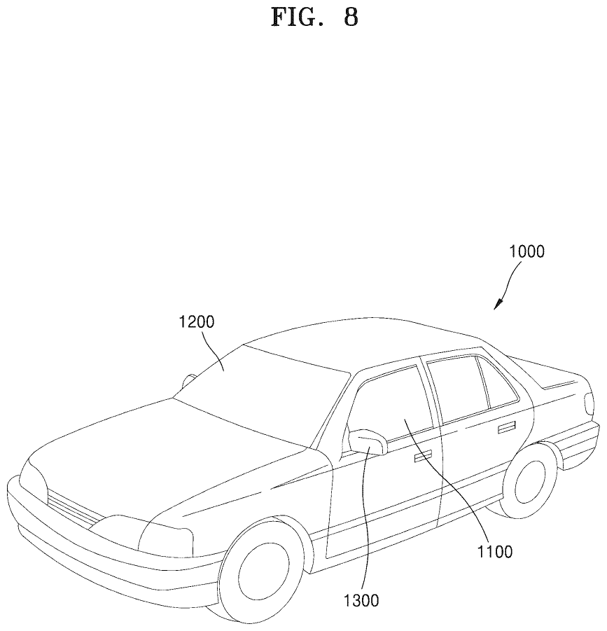

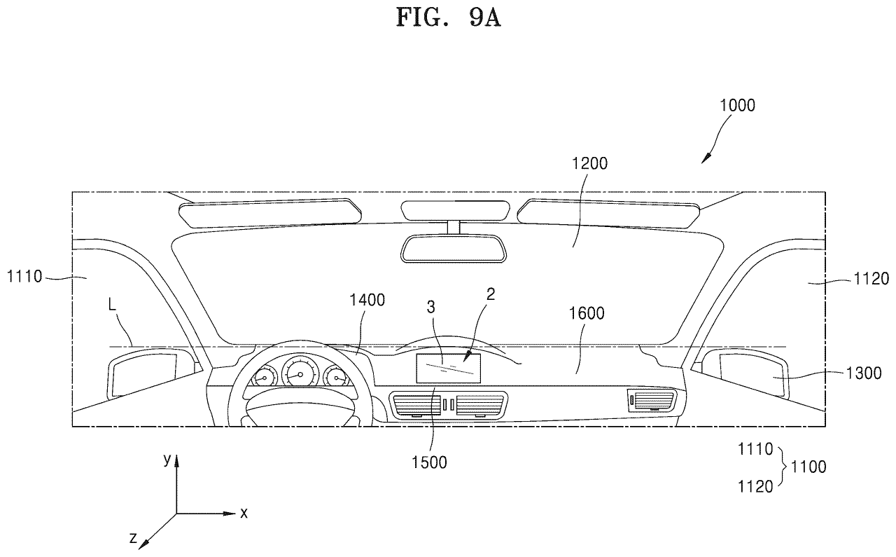

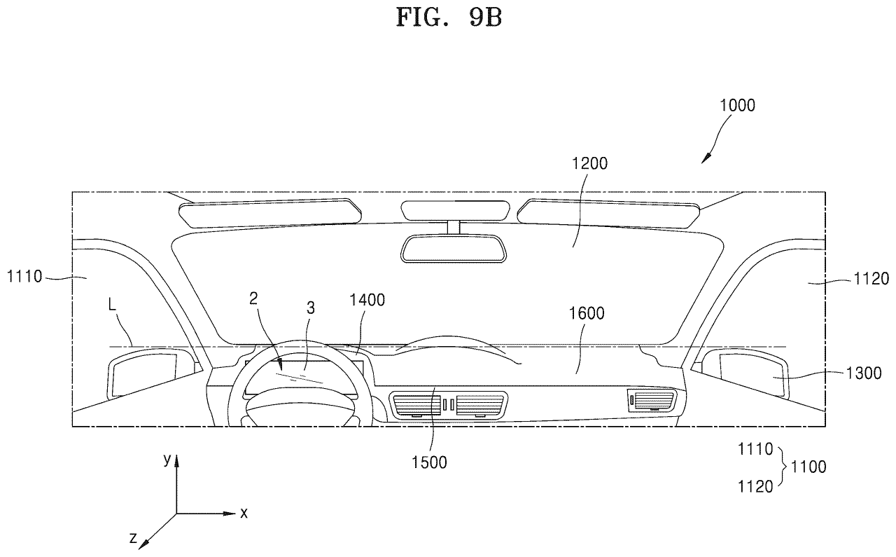

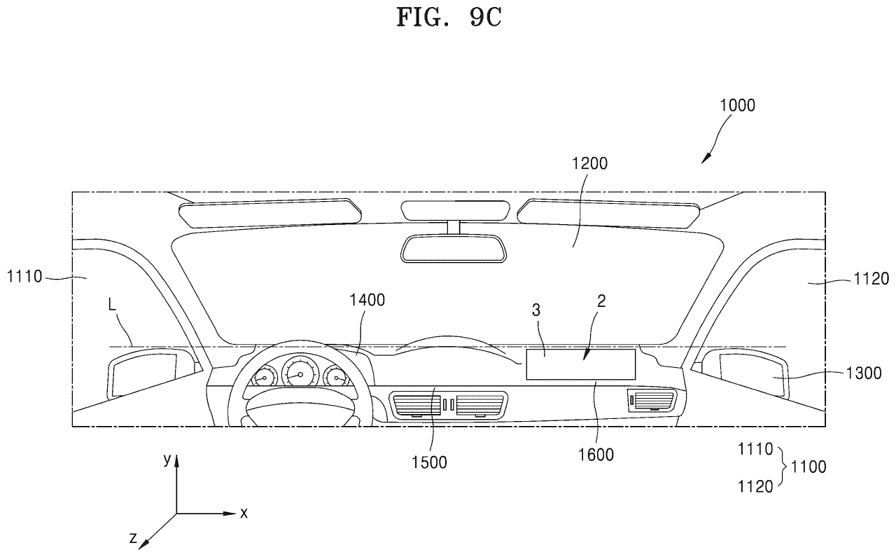

### Descriptions of FIGS. 8 and 9A to 9C

FIG. 8 is a schematic view of the exterior of a vehicle 1000 as electronic equipment including an optoelectronic device according to one or more embodiments. FIGS. 9A to 9C are each a schematic view of the interior of the vehicle 1000 according to one or more embodiments.

Referring to FIGS. 8, 9A, 9B, and 9C, the vehicle 1000 may refer to one or more suitable apparatuses to move a subject to be transported, such as a human, an object, and/or an animal, from a departure point to a destination point. The vehicle 1000 may include a vehicle that travels on a road or a track, a vessel that moves over the sea or river, an airplane that flies in the sky using the action of air, and/or the like.

The vehicle 1000 may travel on a road or a track. The vehicle 1000 may move in a certain (e.g., set or predetermined) direction according to rotation of at least one wheel. For example, the vehicle 1000 may include a three-wheeled or four-wheeled vehicle, a construction machine, a two-wheeled vehicle, a prime mover device, a bicycle, and a train that runs on a track.

The vehicle 1000 may include a body having an interior and an exterior, and a chassis in which mechanical apparatuses desired or necessary to drive are installed as other parts except for the body of the vehicle 1000. The exterior of the body of the vehicle 1000 may include a front panel, a bonnet, a roof panel, a rear panel, a trunk, a pillar provided at a boundary between doors, and/or the like. The chassis of the vehicle 1000 may include a power generating device, a power transmitting device, a driving device, a steering device, a braking device, a suspension device, a transmission device, a fuel device, front and rear left and right wheels, and/or the like.

The vehicle 1000 may include a side window glass 1100, a front window glass 1200, a side mirror 1300, a cluster 1400, a center fascia 1500, a passenger seat dashboard 1600, and a display apparatus 2.

The side window glass 1100 and the front window glass 1200 may be partitioned by a pillar arranged or provided between the side window glass 1100 and the front window glass 1200.

The side window glass 1100 may be installed on the side of the vehicle 1000. In one or more embodiments, the side window glass 1100 may be installed on a door of the vehicle 1000. A plurality of side window glasses 1100 may be provided and may be opposite to (e.g., face) each other. In one or more embodiments, the side window glass 1100 may include a first side window glass 1110 and a second side window glass 1120. In one or more embodiments, the first side window glass 1110 may be arranged or provided adjacent to the cluster 1400. The second side window glass 1120 may be arranged or provided adjacent to the passenger seat dashboard 1600.

In one or more embodiments, the side window glasses 1100 may be spaced and/or apart (e.g., spaced apart or separated) from each other in an x-direction or a −x-direction. For example, the first side window glass 1110 and the second side window glass 1120 may be spaced and/or apart (e.g., spaced apart or separated) from each other in the x-direction or the −x-direction. For example, an imaginary straight line L that connects the side window glasses 1100 may extend in the x-direction or the −x-direction. For example, an imaginary straight line L that connects the first side window glass 1110 and the second side window glass 1120 to each other may extend in the x-direction or the −x-direction.

The front window glass 1200 may be installed in the front of the vehicle 1000. The front window glass 1200 may be arranged or provided between the side window glasses 1100 that are opposite to (e.g., face) each other.

The side mirror 1300 may provide a rear view of the vehicle 1000. The side mirror 1300 may be installed on the exterior of the body of the vehicle 1000. In one or more embodiments, a plurality of side mirrors 1300 may be provided. Any one selected from among the plurality of side mirrors 1300 may be arranged or provided outside the first side window glass 1110. Another of the plurality of side mirrors 1300 may be arranged or provided outside the second side window glass 1120.

The cluster 1400 may be arranged or provided in front of a steering wheel. The cluster 1400 may include a tachometer, a speedometer, a coolant thermometer, a fuel gauge, a turn signal indicator, a high beam indicator, a warning light, a seat belt warning light, an odometer, a tachograph, an automatic shift selector indicator, a door open warning light, an engine oil warning light, and/or a low fuel warning light.

The center fascia 1500 may include a control panel on which a plurality of buttons to adjust an audio device, an air conditioning device, and a seat heater are arranged or provided. The center fascia 1500 may be arranged or provided on one side of the cluster 1400.

The passenger seat dashboard 1600 may be spaced and/or apart (e.g., spaced apart or separated) from the cluster 1400, and the center fascia 1500 may be arranged or provided between the cluster 1400 and the passenger seat dashboard 1600. In one or more embodiments, the cluster 1400 may be arranged or provided to correspond to a driver seat, and the passenger seat dashboard 1600 may be arranged or provided to correspond to a passenger seat. In one or more embodiments, the cluster 1400 may be adjacent to the first side window glass 1110, and the passenger seat dashboard 1600 may be adjacent to the second side window glass 1120.

In one or more embodiments, the display apparatus 2 may include a display panel 3, and the display panel 3 may display an image. The display apparatus 2 may be arranged or provided inside the vehicle 1000. In one or more embodiments, the display apparatus 2 may be arranged or provided between the side window glasses 1100 that are opposite to (e.g., face) each other. The display apparatus 2 may be arranged or provided on at least one selected from among the cluster 1400, the center fascia 1500, and the passenger seat dashboard 1600.

The display apparatus 2 may include an organic light-emitting display apparatus, an inorganic light-emitting display apparatus, a quantum dot display apparatus, and/or the like. Hereinafter, as the display apparatus 2 according to one or more embodiments, an organic light-emitting display apparatus including the optoelectronic device according to one or more embodiments will be described in more detail as an example, but one or more suitable types or kinds of display apparatuses as described herein may be used in one or more embodiments.

Referring to FIG. 9A, the display apparatus 2 may be arranged or provided on the center fascia 1500. In one or more embodiments, the display apparatus 2 may display navigation information. In one or more embodiments, the display apparatus 2 may display information with respect to audio settings, video setting, and/or vehicle settings.

Referring to FIG. 9B, the display apparatus 2 may be arranged or provided on the cluster 1400. In one or more embodiments, the cluster 1400 may display driving information and/or the like through the display apparatus 2. For example, the cluster 1400 may digitally implement driving information and/or the like. The cluster 1400 may digitally display vehicle information and driving information as images. For example, a needle and a gauge of a tachometer and one or more suitable warning light icons may be displayed by digital signals.

Referring to FIG. 9C, the display apparatus 2 may be arranged or provided on the passenger seat dashboard 1600. The display apparatus 2 may be embedded in the passenger seat dashboard 1600 or arranged or provided on the passenger seat dashboard 1600. In one or more embodiments, the display apparatus 2 arranged or provided on the passenger seat dashboard 1600 may display an image related to information displayed on the cluster 1400 and/or information displayed on the center fascia 1500. In one or more embodiments, the display apparatus 2 arranged or provided on the passenger seat dashboard 1600 may display information different from information displayed on the cluster 1400 and/or information displayed on the center fascia 1500.

### Manufacturing Method

Respective layers included in the hole transport region 120, the emission layer 130, respective layers included in the photoactive layer 135, and/or respective layers included in the electron transport region 140 may be formed or provided in a certain (e.g., set or predetermined) region by using one or more suitable methods, such as vacuum deposition, spin coating, casting, Langmuir-Blodgett (LB) deposition, inkjet printing, laser printing, laser-induced thermal imaging (LITI), and/or the like. In one or more embodiments, both (e.g., simultaneously) the emission layer 130 and the photoactive layer 135 may be formed or provided by vacuum deposition.

If (e.g., when) respective layers included in the hole transport region 120, the emission layer 130, the photoactive layer 135, and/or respective layers included in the electron transport region 140 are formed or provided by vacuum deposition, the deposition may be performed at a deposition temperature of about 100° C. to about 500° C., a vacuum degree of about 10⁻⁸ torr to about 10⁻³ torr, and a deposition speed of about 0.01 Å/sec to about 100 Å/sec, depending on a material to be included in a layer to be formed or provided and the structure of a layer to be formed or provided.

### Definition of Terms

The term “C₃-C₆₀ carbocyclic group” as used herein refers to a cyclic group consisting of (e.g., including) carbon atoms as the only ring-forming atoms and having 3 to 60 carbon atoms. The term “C₁-C₆₀ heterocyclic group” as used herein refers to a cyclic group that has 1 to 60 carbon atoms and further has, in addition to carbon atoms, a heteroatom as a ring-forming atom. The C₃-C₆₀ carbocyclic group and the C₁-C₆₀ heterocyclic group may each be a monocyclic group consisting of (e.g., including) one ring or a polycyclic group in which two or more rings are condensed with each other. For example, the number of ring-forming atoms of the C₁-C₆₀ heterocyclic group may be from 3 to 61.

The term “cyclic group” as used herein may include both (e.g., simultaneously) the C₃-C₆₀ carbocyclic group and the C₁-C₆₀ heterocyclic group.

The term “π electron-rich C₃-C₆₀ cyclic group” as used herein refers to a cyclic group that has 3 to 60 carbon atoms and does not include *—N═*′ as a ring-forming moiety.

The term “π electron-deficient nitrogen-containing C₁-C₆₀ heterocyclic group” as used herein refers to a heterocyclic group that has 1 to 60 carbon atoms and includes *—N═*′ as a ring-forming moiety.

For example,
the C₃-C₆₀ carbocyclic group may be i) Group T1 or ii) a condensed cyclic group in which two or more of Group T1 are condensed with each other (e.g., a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
the C₁-C₆₀ heterocyclic group may be i) Group T2, ii) a condensed cyclic group in which two or more of Group T2 are condensed with each other, or iii) a condensed cyclic group in which at least one Group T2 and at least one Group T1 are condensed with each other (e.g., a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),
the π electron-rich C₃-C₆₀ cyclic group may be i) Group T1, ii) a condensed cyclic group in which two or more of Group T1 are condensed with each other, iii) Group T3, iv) a condensed cyclic group in which two or more of Group T3 are condensed with each other, or v) a condensed cyclic group in which at least one Group T3 and at least one Group T1 are condensed with each other (e.g., the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, and/or the like), and
the π electron-deficient nitrogen-containing C₁-C₆₀ heterocyclic group may be i) Group T4, ii) a condensed cyclic group in which two or more of Group T4 are condensed with each other, iii) a condensed cyclic group in which at least one Group T4 and at least one Group T1 are condensed with each other, iv) a condensed cyclic group in which at least one Group T4 and at least one Group T3 are condensed with each other, or v) a condensed cyclic group in which at least one Group T4, at least one Group T1, and at least one Group T3 are condensed with one another (e.g., a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like).

Group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group.

Group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group.

Group T3 may be a furan group, a thiophene group, a 1H-pyrrole group, a silole group, or a borole group.

Group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “cyclic group,” “C₃-C₆₀ carbocyclic group,” “C₁-C₆₀ heterocyclic group,” “π electron-rich C₃-C₆₀ cyclic group,” and “π electron-deficient nitrogen-containing C₁-C₆₀ heterocyclic group” as used herein each refer to a group condensed to any cyclic group, a monovalent group, or a polyvalent group (e.g., a divalent group, a trivalent group, a tetravalent group, and/or the like) according to the structure of a formula for which the corresponding term is used.

For example, the “benzene group” may be a benzo group, a phenyl group, a phenylene group, and/or the like, which may be easily understood by one of ordinary skill in the art according to the structure of a formula including the “benzene group.”

Examples of the monovalent C₃-C₆₀ carbocyclic group and the monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

Examples of the divalent C₃-C₆₀ carbocyclic group and the divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein refers to a linear or branched aliphatic hydrocarbon monovalent group that has 1 to 60 carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, and/or the like.

The term “C₁-C₆₀ alkylene group” as used herein refers to a divalent group having the same structure as the C₁-C₆₀ alkyl group. For example, the term “C₁alkylene group” refers to —CH₂—.

The term “C₂-C₆₀ alkenyl group” as used herein refers to a monovalent hydrocarbon group having at least one carbon-carbon double bond in the middle or at the terminus of the C₂-C₆₀ alkyl group, and examples thereof may include an ethenyl group, a propenyl group, a butenyl group, and/or the like.

The term “C₂-C₆₀ alkenylene group” as used herein refers to a divalent group having the same structure as the C₂-C₆₀ alkenyl group.

The term “C₂-C₆₀ alkynyl group” as used herein refers to a monovalent hydrocarbon group having at least one carbon-carbon triple bond in the middle or at the terminus of the C₂-C₆₀ alkyl group, and examples thereof may include an ethynyl group, a propynyl group, and/or the like.

The term “C₂-C₆₀ alkynylene group” as used herein refers to a divalent group having the same structure as the C₂-C₆₀ alkynyl group.

The term “C₁-C₆₀ alkoxy group” as used herein refers to a monovalent group represented by —OA₁₀₁ (wherein A₁₀₁ is the C₁-C₆₀ alkyl group), and examples thereof may include a methoxy group, an ethoxy group, an isopropyloxy group, and/or the like.

The term “C₃-C₁₀ cycloalkyl group” as used herein refers to a monovalent saturated hydrocarbon cyclic group having 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, a bicyclo[2.2.2]octyl group, and/or the like.

The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent cyclic group of 1 to 10 carbon atoms, further including, in addition to carbon atoms, at least one heteroatom as ring-forming atoms, and examples thereof may include a 1,2,3,4-oxatriazolidinyl group, a tetrahydrofuranyl group, a tetrahydrothiophenyl group, and/or the like.

The term “C₁-C₁₀ heterocycloalkylene group” as used herein refers to a divalent group having the same structure as the C₁-C₁₀ heterocycloalkyl group.

The term “C₃-C₁₀ cycloalkenyl group” as used herein refers to a monovalent cyclic group that has 3 to 10 carbon atoms, at least one carbon-carbon double bond in the ring thereof, and no aromaticity, and examples thereof may include a cyclopentenyl group, a cyclohexenyl group, a cycloheptenyl group, and/or the like.

The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent cyclic group of 1 to 10 carbon atoms, further including, in addition to carbon atoms, at least one heteroatom as ring-forming atoms and at least one double bond in the ring thereof. Examples of the C₁-C₁₀ heterocycloalkenyl group may include a 4,5-dihydro-1,2,3,4-oxatriazolyl group, a 2,3-dihydrofuranyl group, a 2,3-dihydrothiophenyl group, and/or the like.

The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system of 6 to 60 carbon atoms.

The term “C₆-C₆₀ arylene group” as used herein refers to a divalent group having a carbocyclic aromatic system of 6 to 60 carbon atoms.

Examples of the C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and/or the like.

If (e.g., when) the C₆-C₆₀ aryl group and the C₆-C₆₀ arylene group each include two or more rings, the two or more rings may be condensed with each other.

The term “C₁-C₆₀ heteroaryl group” as used herein refers to a monovalent group having a heterocyclic aromatic system of 1 to 60 carbon atoms, further including, in addition to carbon atoms, at least one heteroatom as ring-forming atoms.

The term “C₁-C₆₀ heteroarylene group” as used herein refers to a divalent group having a heterocyclic aromatic system of 1 to 60 carbon atoms, further including, in addition to carbon atoms, at least one heteroatom as ring-forming atoms.

Examples of the C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and/or the like.

If (e.g., when) the C₁-C₆₀ heteroaryl group and the C₁-C₆₀ heteroarylene group each include two or more rings, the two or more rings may be condensed with each other.

The term “monovalent non-aromatic condensed polycyclic group” as used herein refers to a monovalent group (e.g., having 8 to 60 carbon atoms) having two or more rings condensed to each other, only carbon atoms as ring-forming atoms, and no aromaticity in its entire molecular structure. Examples of the monovalent non-aromatic condensed polycyclic group may include an indenyl group, a fluorenyl group, a spiro-bifluorenyl group, a benzofluorenyl group, an indenophenanthrenyl group, an indenoanthracenyl group, and/or the like.

The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group (e.g., having 1 to 60 carbon atoms) having two or more rings condensed to each other, further including, in addition to carbon atoms, at least one heteroatom as ring-forming atoms, and having no aromaticity in its entire molecular structure. Examples of the monovalent non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, a benzothienodibenzothiophenyl group, and/or the like.

The term “divalent non-aromatic condensed heteropolycyclic group” as used herein refers to a divalent group having the same structure as the monovalent non-aromatic condensed heteropolycyclic group.

The term “C₆-C₆₀ aryloxy group” as used herein refers to —OA₁₀₂ (wherein A₁₀₂ is the C₆-C₆₀ aryl group).

The term “C₆-C₆₀ arylthio group” as used herein refers to —SA₁₀₃ (wherein A₁₀₃ is the C₆-C₆₀ aryl group).

The term “C₇-C₆₀ arylalkyl group” as used herein refers to -A₁₀₄A₁₀₅ (wherein A₁₀₄ is a C₁-C₅₄ alkylene group, and A₁₀₅ is a C₆-C₅₉ aryl group).

The term “C₂-C₆₀ heteroarylalkyl group” as used herein refers to -A₁₀₆A₁₀₇ (wherein A₁₀₆ is a C₁-C₅₉ alkylene group, and A₁₀₇ is a C₁-C₅₉ heteroaryl group).

The term “R₁₀ₐ” as used herein may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each being unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each being unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).
Q₁ to Q₃, Q₁₁ to Q₁₃, Q₂₁ to Q₂₃, and Q₃₁ to Q₃₃ used herein may each independently be:
hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, or a C₁-C₆₀ alkoxy group; or
a C₃-C₆₀ carbocyclic group, a C₁-C₆₀ heterocyclic group, a C₇-C₆₀ arylalkyl group, or a C₂-C₆₀ heteroarylalkyl group, each being unsubstituted or substituted with deuterium, —F, a cyano group, a C₁-C₆₀ alkyl group, a C₁-C₆₀ alkoxy group, a phenyl group, a biphenyl group, or any combination thereof.

The term “heteroatom” as used herein refers to an atom other than a carbon atom and a hydrogen atom. Examples of the heteroatom may include O, S, N, P, Si, B, Ge, Se, or any combination thereof.

The term “transition metal” as used herein may include hafnium (Hf), tantalum (Ta), tungsten (W), rhenium (Re), osmium (Os), iridium (Ir), platinum (Pt), gold (Au), and/or the like.

“Ph” as used herein refers to a phenyl group, “Me” as used herein refers to a methyl group, “Et” as used herein refers to an ethyl group, “tert-Bu” or “But” as used herein refers to a tert-butyl group, and “OMe” as used herein refers to a methoxy group.

The term “biphenyl group” as used herein refers to “a phenyl group substituted with a phenyl group.” For example, the “biphenyl group” may be a substituted phenyl group having a C₆-C₆₀ aryl group as a substituent.

The term “terphenyl group” as used herein refers to “a phenyl group substituted with a biphenyl group.” For example, the “terphenyl group” may be a substituted phenyl group having, as a substituent, a C₆-C₆₀ aryl group substituted with a C₆-C₆₀ aryl group.
* and *′ as used herein, unless defined otherwise, each refer to a binding site to a neighboring atom in a corresponding formula or moiety.

The terms “x-axis,” “y-axis,” and “z-axis” as used herein are not limited to three axes in an orthogonal coordinate system, and may be interpreted in a broader sense than the aforementioned three axes in an orthogonal coordinate system. For example, the x-axis, y-axis, and z-axis may describe axes that are orthogonal to each other, or may describe axes that are in different directions that are not orthogonal to each other.

Hereinafter, compounds according to one or more embodiments and optoelectronic devices according to one or more embodiments will be described in more detail with reference to Synthesis Examples and Examples. The wording “B was used instead of A” used in describing Synthesis Examples refers to that an identical molar equivalent of B was used in place of A.

### Synthesis Example 1 (Synthesis of Compound F1)

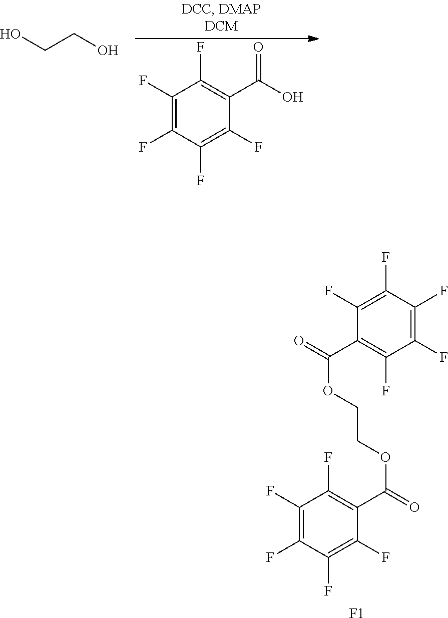

1. A mixture of 2,3,4,5,6-pentafluorobenzoic acid (1 g, 4.72 mmol) and ethylene glycol (0.13 g, 2.12 mmol) was dissolved in anhydrous dichloromethane (DCM, 100 mL) by stirring at room temperature.

2. 4-Dimethylaminopyridine (DMAP) (57 mg, 0.47 mmol) was added to the solution and stirred for 30 minutes.

3. The reaction mixture was cooled to 0° C., and N,N′-Dicyclohexylcarbodiimide (DCC) (1M, 5.2 mL, 5.2 mmol) was added thereto in a nitrogen atmosphere.

4. The mixture was stirred for 12 hours.

5. After water was added to the reaction mixture, an extraction process was performed thereon by using dichloromethane.

6. The extracted organic layer was concentrated under reduced pressure to obtain a crude product.

7. The crude product was purified by silica gel column chromatography by using ethyl acetate/n-hexane (1:10) as an eluent.

8. Compound F1 was obtained as a colorless solid (0.68 g, 71.1%).

### Synthesis Example 2 (Synthesis of Compound F2)

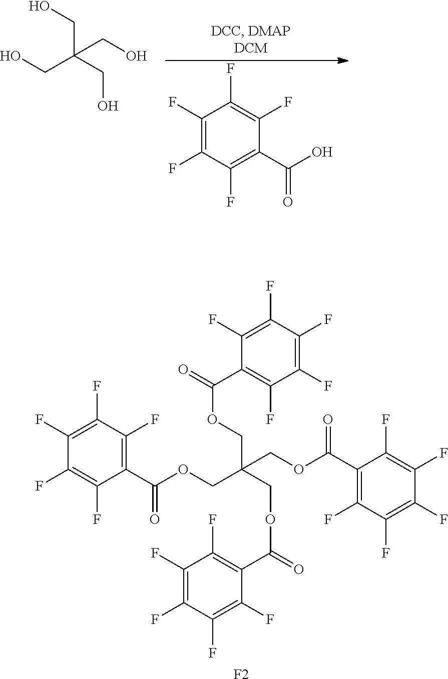

1. A mixture of 2,3,4,5,6-pentafluorobenzoic acid (1 g, 4.72 mmol) and pentaerythritol (0.12 g, 0.94 mmol) was dissolved in anhydrous dichloromethane (DCM, 100 mL) by stirring at room temperature.

2. DMAP (57 mg, 0.47 mmol) was added to the solution and stirred for 30 minutes.

3. The reaction mixture was cooled to 0° C., and N,N′-Dicyclohexylcarbodiimide (DCC) (1M, 5.2 mL, 5.2 mmol) was added thereto in a nitrogen atmosphere.

4. The mixture was stirred for 12 hours.

5. After water was added to the reaction mixture, an extraction process was performed thereon by using dichloromethane.

6. The extracted organic layer was concentrated under reduced pressure to obtain a crude product.

7. The crude product was purified by silica gel column chromatography by using ethyl acetate/n-hexane (1:10) as an eluent.

8. Compound F2 was obtained as a colorless solid (0.21 g, 24.4%).

### Synthesis Example 3 (Synthesis of Compound F3)

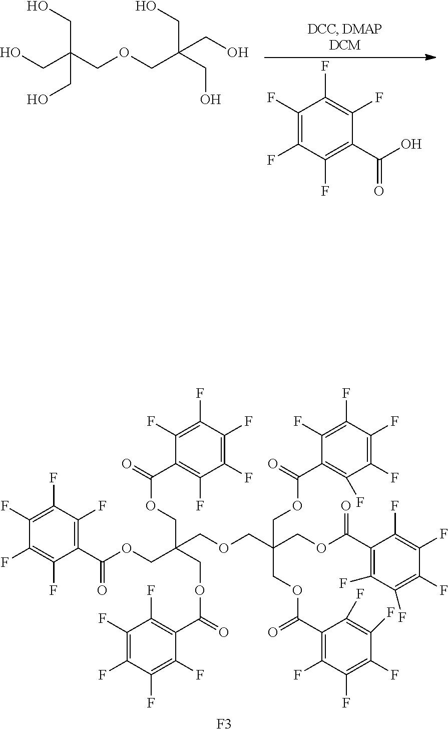 [SMILES: OCC(CO)(CO)COCC(CO)(CO)CO ; O=C(O)c1c(F)c(F)c(F)c(F)c1F ; O=C(OCC(COCC(COC(=O)c1c(F)c(F)c(F)c(F)c1F)(COC(=O)c1c(F)c(F)c(F)c(F)c1F)COC(=O)c1c(F)c(F)c(F)c(F)c1F)(COC(=O)c1c(F)c(F)c(F)c(F)c1F)COC(=O)c1c(F)c(F)c(F)c(F)c1F)c1c(F)c(F)c(F)c(F)c1F ; "F3"]

1. A mixture of 2,3,4,5,6-pentafluorobenzoic acid (1 g, 4.72 mmol) and dipentaerythritol (0.14 g, 0.56 mmol) was dissolved in anhydrous dichloromethane (DCM, 100 mL) by stirring at room temperature.

2. DMAP (57 mg, 0.47 mmol) was added to the solution and stirred for 30 minutes.

3. The reaction mixture was cooled to 0° C., and N,N′-Dicyclohexylcarbodiimide (DCC) (1M, 5.2 mL, 5.2 mmol) was added thereto in a nitrogen atmosphere.

4. The mixture was stirred for 12 hours.

5. After water was added to the reaction mixture, an extraction process was performed thereon by using dichloromethane.

6. The extracted organic layer was concentrated under reduced pressure to obtain a crude product.

7. The crude product was purified by silica gel column chromatography by using ethyl acetate/n-hexane (1:5) as an eluent.

8. Compound F3 was obtained as a colorless solid (0.15 g, 18.6%).

### Synthesis Example 4 (Synthesis of Compound F4)

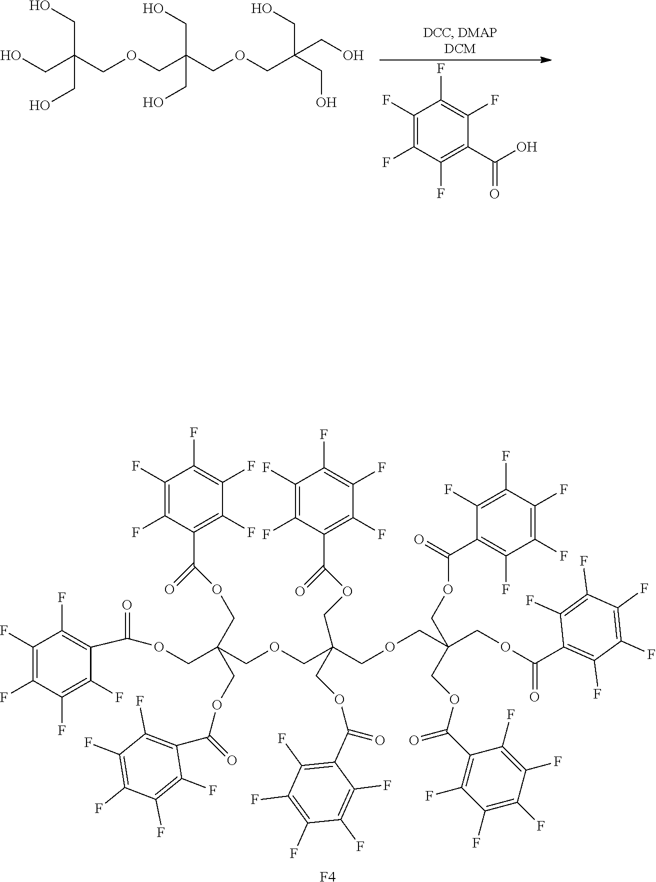

1. A mixture of 2,3,4,5,6-pentafluorobenzoic acid (1 g, 4.72 mmol) and tripentaerythritol (0.17 g, 0.47 mmol) was dissolved in anhydrous dichloromethane (DCM, 100 mL) by stirring at room temperature.

2. DMAP (57 mg, 0.47 mmol) was added to the solution and stirred for 30 minutes.

3. The reaction mixture was cooled to 0° C., and N,N′-Dicyclohexylcarbodiimide (DCC) (1M, 5.2 mL, 5.2 mmol) was added thereto in a nitrogen atmosphere.

4. The mixture was stirred for 12 hours.

5. After water was added to the reaction mixture, an extraction process was performed thereon by using dichloromethane.

6. The extracted organic layer was concentrated under reduced pressure to obtain a crude product.

7. The crude product was purified by silica gel column chromatography by using ethyl acetate/n-hexane (1:5) as an eluent.

8. Compound F4 was obtained as a colorless solid (0.14 g, 15.4%).

1H NMR measurement results for the compounds synthesized according to Synthesis Examples 1 to 4 are shown in Table 1. Synthesis methods of compounds other than the compounds of Synthesis Examples 1 to 4 may be easily recognized by those skilled in the art by referring to the synthesis paths and source materials.

TABLE 1

| Com- | |
|---|---|
| pound | ¹H NMR (CDCl₃, 400 MHz) |
| F1 | ¹H NMR (400 MHz, CDCl₃): δ = 4.61 (s, 8H). |
| | ¹⁹F NMR (376.5 MHz, CDCl₃): δ = 137.40 to 137.51 |
| | (m), 146.21 to 146.35 (m), 159.31 to 159.46 (m). |
| F2 | ¹H NMR (400 MHz, CDCl₃): δ = 4.61 (s, 8H). |
| | ¹⁹F NMR (376.5 MHz, CDCl₃): δ = 137.40 to 137.51 |
| | (m), 146.21 to 146.35 (m), 159.31 to 159.46 (m). |
| F3 | ¹H NMR (400 MHz, CDCl₃): δ = 3.65 (s, 4H), 4.53 (s, 12H). |
| | ¹⁹F NMR (376.5 MHz, CDCl₃): δ = 137.78 to 137.90 |
| | (m), 146.64 to 146.78 (m), 159.67 to 159.83 (m). |
| F4 | ¹H NMR (400 MHz, CDCl₃): δ = 3.58 (s, 4H), 3.62 (s, 4H), |
| | 4.53 (s, 12H), 4.61 (s, 4H). |
| | ¹⁹F NMR (376.5 MHz, CDCl₃): δ = 137.93 to 138.03 (m), |
| | 146.79 to 146.97 (m), 159.75 to 159.91 (m). |

### Comparative Example 1

As an anode, a glass substrate (product of Corning Inc.) with a 15 Ω/cm² (1,200 Å) ITO formed or provided thereon was cut to a size of 50 mm×50 mm×0.7 mm, sonicated by using isopropyl alcohol and pure water each for 5 minutes, washed by irradiation of ultraviolet rays and exposure of ozone thereto for 30 minutes, and then mounted on a vacuum deposition apparatus.

A p-dopant was vacuum-deposited on the anode to form or provide a hole injection layer, and 4,4′-bis[N-(1-naphthyl)-N-phenylamino]biphenyl (hereinafter referred to as NPB) was vacuum-deposited on the hole injection layer to form or provide a hole transport layer.

The first compound (donor) as described herein was vacuum-deposited on the hole transport layer to form or provide a first layer, and the second compound (acceptor) as described herein was vacuum-deposited on the first layer to form or provide a second layer, thereby forming or providing a photoactive layer. Alq₃ was vacuum-deposited on the photoactive layer to form or provide a buffer layer, and LiF was vacuum-deposited on the buffer layer to form or provide an electron transport layer. Al was vacuum-deposited on the electron transport layer to form or provide a cathode, thereby completing the manufacture of an optoelectronic device.

### Examples 1 to 3

Optoelectronic devices were manufactured in substantially the same manner as in Comparative Example 1, except that, in forming or providing the photoactive layer, Compound F2 was vacuum-deposited on the first layer to form or provide a fluorine layer having a thickness as shown in Table 2, and then, the second layer was formed or provided on the fluorine layer.

### Examples 4 to 6

Optoelectronic devices were manufactured in substantially the same manner as in Comparative Example 1, except that, in forming or providing the photoactive layer, Compound F3 was vacuum-deposited on the first layer to form or provide a fluorine layer having a thickness as shown in Table 2, and then, the second layer was formed or provided on the fluorine layer.

### Examples 7 and 8

Optoelectronic devices were manufactured in substantially the same manner as in Comparative Example 1, except that, in forming or providing the photoactive layer, Compound F4 was vacuum-deposited on the first layer to form or provide a fluorine layer having a thickness as shown in Table 2, and then, the second layer was formed or provided on the fluorine layer.

### Evaluation Example 1

For the optoelectronic devices manufactured in Comparative Example 1 and Examples 1 to 8, the external quantum efficiency (EQE) measurement results and the deposition temperature during the formation or arrangement of the photoactive layer are shown in Table 2. EQE refers to the ratio of electrical energy generated from energy of irradiated light.

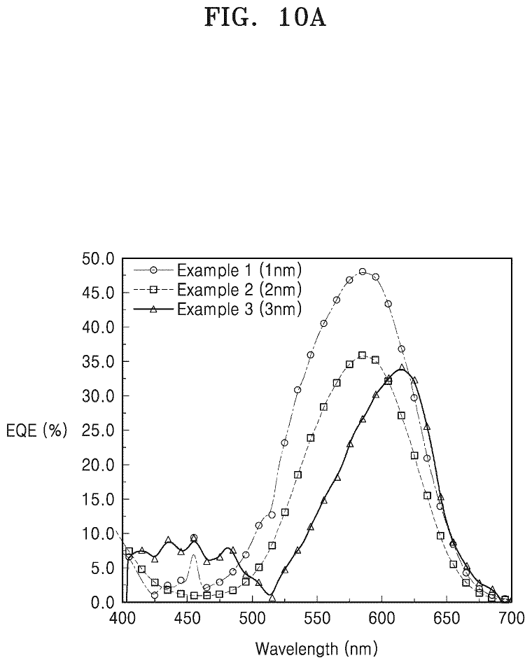

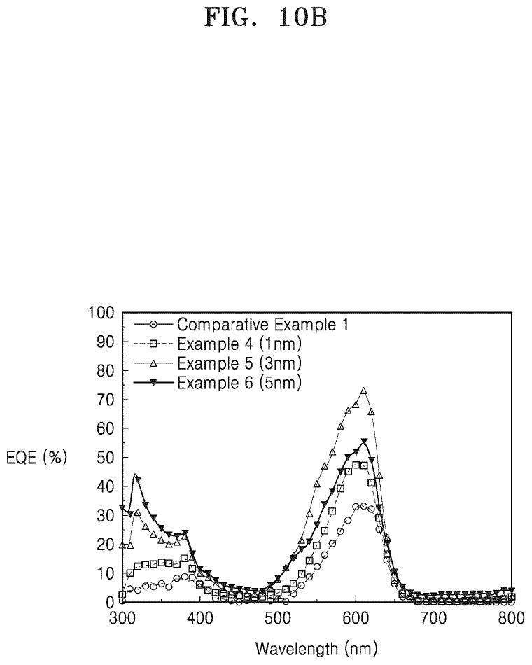

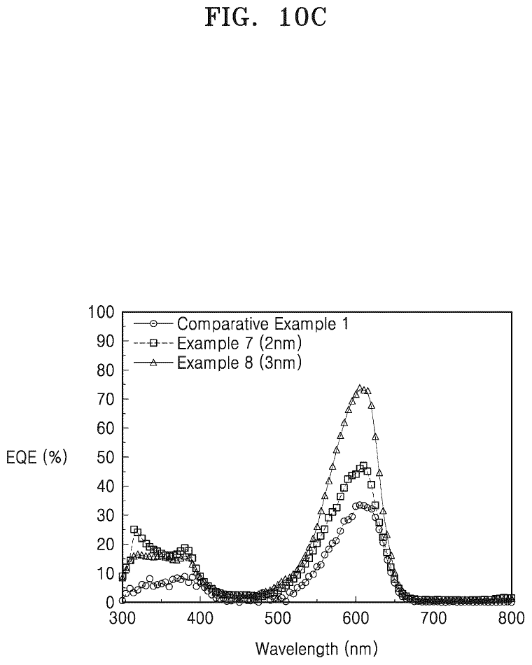

Light was irradiated to an optoelectronic device by using a Xenon Lamp, and the EQE was measured by using an EQE meter (K3100, McScience, Korea). The current converted during the light irradiation was measured by using an ammeter (Keithley, Tektronix, USA). The EQE according to wavelength was calculated by using the irradiated light and the measured current, and the results are shown in FIGS. 10A to 10C. The EQE at the maximum peak is shown in Table 2.

In more detail, the EQE was calculated according to Equation 1 using photoreactivity, which was calculated according to Equation 2:

$$EQE = \frac{hc}{q} \times \frac{R}{λ} \qquad Equation 1$$

$$R = \frac{{i}_{ph} - {i}_{d}}{P} \qquad Equation 2$$

wherein, in Equation 1, EQE indicates external quantum efficiency, h indicates the Planck constant, c indicates the speed of light in vacuum, q indicates the basic amount of charge, R indicates photoreactivity, and λ indicates the wavelength of incident light, and
in Equation 2, R indicates photoreactivity, iₚₕ indicates the current during light irradiation, i_{d} indicates dark current, and P indicates the power of incident light.

TABLE 2

| | | Thickness of | Deposition | |
|---|---|---|---|---|
| | Fluorine-based | fluorine | temperature | EQE (%, |
| No. | compound | layer (nm) | (° C.) | at −3 V) |
| Comparative | — | — | — | 33.1 |
| Example 1 | | | | |
| Example 1 | F2 | 1 | 309 | 48.1 |
| Example 2 | F2 | 2 | 309 | 34.6 |
| Example 3 | F2 | 3 | 309 | 34.2 |
| Example 4 | F3 | 1 | 329 | 47.1 |
| Example 5 | F3 | 3 | 329 | 73.1 |
| Example 6 | F3 | 5 | 329 | 55.4 |
| Example 7 | F4 | 2 | 338 | 47.0 |
| Example 8 | F4 | 3 | 338 | 73.1 |

Referring to Table 2 and FIGS. 10A to 10C, it was confirmed that the optoelectronic devices according to Examples 1 to 8, which included Compounds F2 to F4 as the fluorine-based compound represented by Formula F as described herein, effectively had increased EQE compared to the optoelectronic device according to Comparative Example 1, which did not include the fluorine-based compound.

An optoelectronic device may have increased or enhanced exciton separation efficiency. The amount of charge that is generated by separation of excitons and reaches an electrode through a thick organic layer may be increased even under a low voltage. For example, the optoelectronic device may have improved or enhanced EQE.

In one or more embodiments, because the fluorine-based compound as represented by Formula F has an appropriate or suitable deposition temperature, an optoelectronic device including the fluorine-based compound may be easily manufactured without a decrease in the lifespan of the optoelectronic device.

It should be understood that embodiments described herein should be considered in a descriptive sense only and not for purposes of limitation. Descriptions of features or aspects within each embodiment should typically be considered as available for other similar features or aspects in other embodiments. While the subject matter of the present disclosure has been described with reference to the figures, it will be understood by those of ordinary skill in the art that one or more suitable changes in form and more details may be made therein without departing from the spirit and scope as defined by the following claims and equivalents thereof.

What is claimed is:

1. An optoelectronic device, comprising:
a first electrode;
a second electrode opposite to the first electrode;
a photoactive layer between the first electrode and the second electrode; and
a fluorine-based compound represented by Formula F: 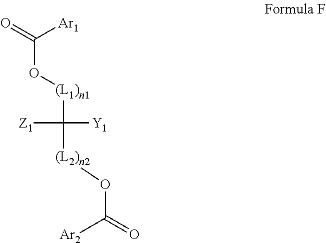
wherein, in Formula F,
Y₁ is selected from among a group represented by Formula F-Y, hydrogen, deuterium, —F, a C₁-C₆₀ alkyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, and a C₁-C₆₀ heterocyclic group unsubstituted or substituted with at least one R₁₀ₐ, and
Z₁ is selected from among a group represented by Formula F-Z, hydrogen, deuterium, —F, a C₁-C₆₀ alkyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, and a C₁-C₆₀ heterocyclic group unsubstituted or substituted with at least one R₁₀ₐ, 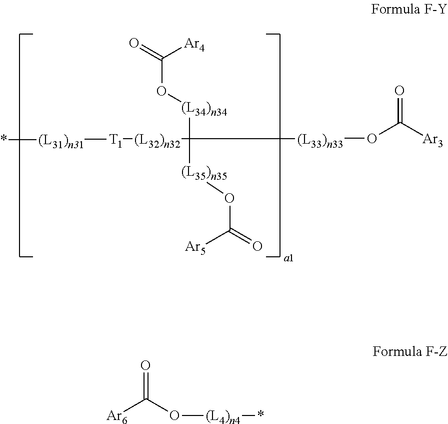
wherein, in Formulae F, F-Y, and F-Z,
Ar₁ to Ars are each independently selected from among a C₆-C₆₀ aryl group substituted with at least two-F and a C₂-C₆₀ heteroarylalkyl group substituted with at least two —F,
L₁, L₂, L₃₁ to L₃₅, and La are each independently a C₁-C₂₀ alkylene group unsubstituted or substituted with at least one R₁₀ₐ,
n1, n2, n31 to n35, and n4 are each independently 0 or 1,
T₁ is O or S,
a1 is an integer of 0 to 10,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each being unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each being unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁₁ to Q₁₃, Q₂₁ to Q₂₃, and Q₃₁ to Q₃₃ are each independently:
hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, or a C₁-C₆₀ alkoxy group; or
a C₃-C₆₀ carbocyclic group, a C₁-C₆₀ heterocyclic group, a C₇-C₆₀ arylalkyl group, or a C₂-C₆₀ heteroarylalkyl group, each being unsubstituted or substituted with deuterium, —F, a cyano group, a C₁-C₆₀ alkyl group, a C₁-C₆₀ alkoxy group, a phenyl group, a biphenyl group, or any combination thereof, and
* indicates a binding site to a neighboring atom.

2. The optoelectronic device as claimed in claim 1, wherein the photoactive layer comprises the fluorine-based compound.

3. The optoelectronic device as claimed in claim 1, further comprising a first compound that is different from the fluorine-based compound and absorbs light having a wavelength in a range of about 400 nm to about 1,000 nm.

4. The optoelectronic device as claimed in claim 3, wherein the photoactive layer comprises: a fluorine layer; and a first layer between the first electrode and the fluorine layer,
wherein the fluorine layer comprises the fluorine-based compound, and
the first layer comprises the first compound.

5. The optoelectronic device as claimed in claim 4, wherein a thickness of the fluorine layer is less than a thickness of the first layer.

6. The optoelectronic device as claimed in claim 1, further comprising a second compound that is different from the fluorine-based compound and is not a fullerene-based compound.

7. The optoelectronic device as claimed in claim 6, wherein the photoactive layer comprises: a second layer; and a fluorine layer between the first electrode and the second layer,
wherein the fluorine layer comprises the fluorine-based compound, and
the second layer comprises the second compound.

8. The optoelectronic device as claimed in claim 7, wherein a thickness of the fluorine layer is less than a thickness of the second layer.

9. The optoelectronic device as claimed in claim 1, wherein the fluorine-based compound does not comprise any one selected from among —Cl, —Br, —I, and a cyano group.

10. The optoelectronic device as claimed in claim 1, wherein, in Formulae F, F-Y, and F-Z, Ar₁ to Ars are each independently selected from among a C₆-C₆₀ aryl group substituted with at least five —F and a C₂-C₆₀ heteroarylalkyl group substituted with at least five —F.

11. The optoelectronic device as claimed in claim 1, wherein, in Formulae F, F-Y, and F-Z, Ar₁ to Ar₆ are each independently: a phenyl group; a naphthyl group; an anthracenyl group; a phenanthrenyl group; a tetracenyl group; a chrysenyl group; a pyrenyl group; a pyridinyl group; a pyrimidinyl group; a triazinyl group; a pyrazinyl group; a quinolinyl group; an isoquinolinyl group; a quinazolinyl group; or a quinoxalinyl group, each being substituted with at least two-F.

12. The optoelectronic device as claimed in claim 1, wherein, in Formulae F, F-Y, and F-Z, n1, n2, n31 to n35, and n4 are each 1.

13. The optoelectronic device as claimed in claim 1, wherein, in Formula F-Y, T₁ is O.

14. The optoelectronic device as claimed in claim 1, wherein, in Formula F-Y, a1 is an integer of 0 to 3.

15. The optoelectronic device as claimed in claim 1, wherein the fluorine-based compound is one selected from among Compounds F1 to F4:

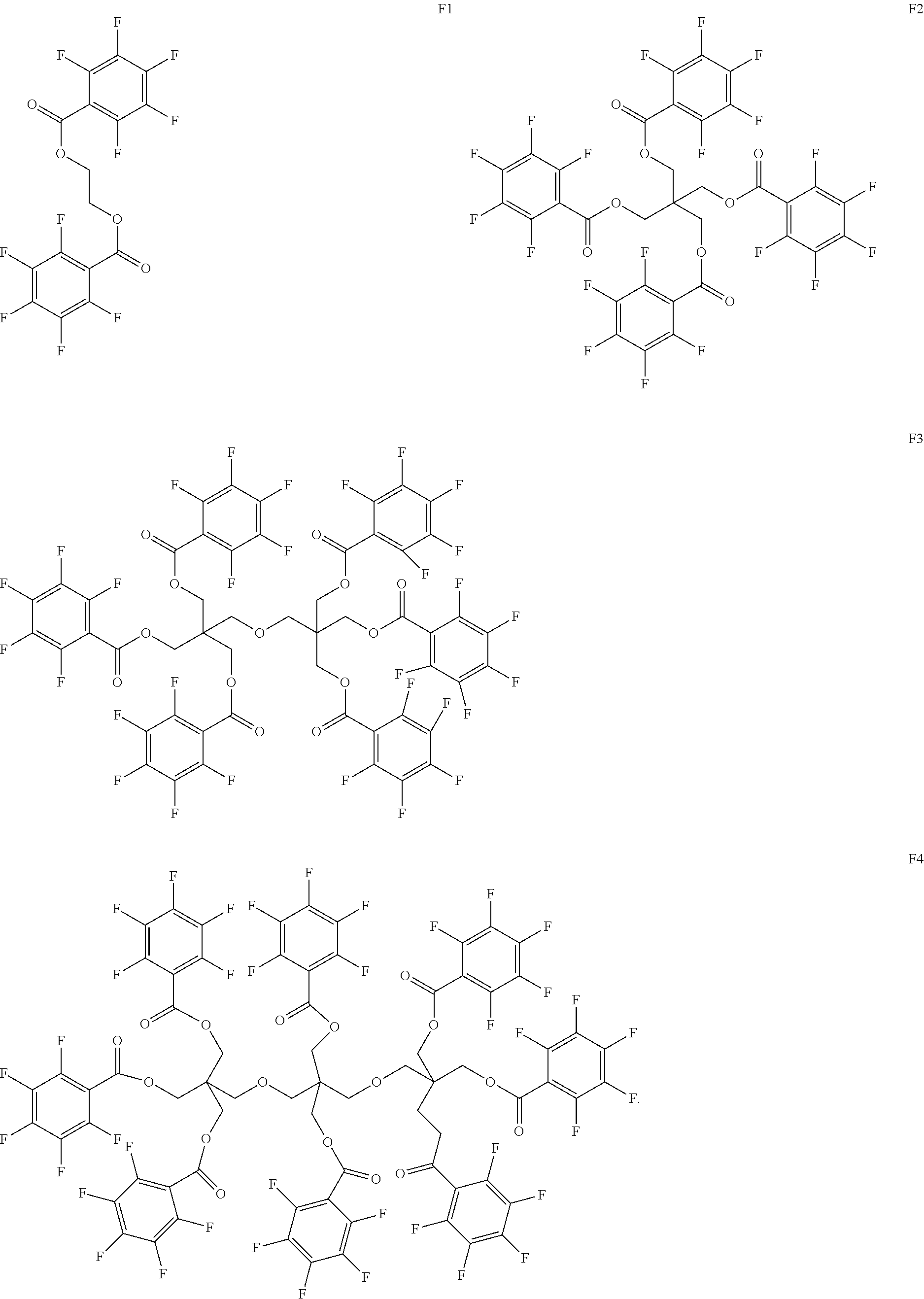

16. An electronic apparatus comprising the optoelectronic device as claimed in claim 1.

17. The electronic apparatus as claimed in claim 16, further comprising a light-emitting device comprising an emission layer that is between the first electrode and the second electrode and that does not overlap the photoactive layer.

18. The electronic apparatus as claimed in claim 17, wherein the optoelectronic device further comprises: a first hole transport region between the first electrode and the photoactive layer; and a first electron transport region between the photoactive layer and the second electrode, and
the light-emitting device further comprises: a second hole transport region between the first electrode and the emission layer; and a second electron transport region between the emission layer and the second electrode.

19. The electronic apparatus as claimed in claim 18, wherein the first hole transport region and the second hole transport region are a common layer, and
the first electron transport region and the second electron transport region are another common layer.

20. An electronic equipment comprising the electronic apparatus as claimed in claim 16, wherein the electronic equipment is one selected from among a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality display, an augmented reality display, a vehicle, a video wall comprising a plurality of displays tiled together, a theater screen, a stadium screen, a phototherapy device, a signboard, a sensor for vehicles, a sensor for home, and a solar cell.
